(19) United States
(12) Patent Application Publication
(10) Pub. No.: US 2024/0030204 A1
(43) Pub. Date: Jan. 25, 2024

(54) MULTI-DIE PANEL-LEVEL HIGH PERFORMANCE COMPUTING COMPONENTS

(71) Applicant: Intel Corporation, Santa Clara, CA (US)

(72) Inventors: Gang Duan, Chandler, AZ (US); Hamid R. Azimi, Paradise Valley, AZ (US); Rahul Manepalli, Chandler, AZ (US); Srinivas V. Pietambaram, Chandler, AZ (US)

(73) Assignee: Intel Corporation, Santa Clara, CA (US)

(21) Appl. No.: 17/871,413

(22) Filed: Jul. 22, 2022

(51) Int. Cl. H01L 25/16; H01L 23/427; H01L 23/538; G02B 6/12

(52) U.S. Cl. CPC H01L 25/167; H01L 23/427; H01L 23/5381; H01L 23/5383; H01L 23/5386; G02B 6/12004

(57) ABSTRACT

Panel-level high performance computing (HPC) computing architectures and methods for making the same are disclosed. Panel architectures with and without glass cores comprise dielectric layers with interconnect structures (vias, conductive traces) to translate die-level pinouts arranged at a fine pitch to panel-level pinouts arranged at a coarser pitch. Local interconnects and local interconnect components provide for electrical communication between integrated circuit dies in a panel. Coreless panel architectures can comprise a glass reinforcement layer to provide additional mechanical stiffness. The glass reinforcement layer can have interconnect structures and a local interconnect component. Panel embodiments with a glass core or glass reinforcement layer can comprise waveguides and channel a liquid coolant therethrough, and can further comprise photonic integrated circuits. Panel-level manufacturing techniques can enable panels having dimensions larger (e.g., greater than 300 mm) than components fabricated using wafer-level manufacturing techniques.

### BACKGROUND

As the technological challenges of high-performance computing (HPC) continue to rise, heterogeneous integration scaling has become an important performance enabler. Heterogeneous integration scaling can include components having an increased amount of die, increased interconnect density, increased bandwidth, and improved power efficiency. Accordingly, many different advanced packaging architecture solutions have been deployed.

### BRIEF DESCRIPTION OF THE DRAWINGS

FIG. 1 illustrates an example HPC package in which panel architecture is implemented, in accordance with various embodiments.

FIG. 2 is a simplified cross-sectional illustration of an example multi-die architecture providing a reference for proposed embodiments.

FIG. 3 is a simplified cross-sectional illustration of an example panel architecture having a glass reinforcement layer, in accordance with various embodiments.

FIG. 4A is a simplified cross-sectional illustration of a first example local interconnect component.

FIG. 4B is a simplified cross-sectional illustration of a second example local interconnect component.

FIG. 4C is a simplified cross-sectional illustration of a third example local interconnect component.

FIG. 4D is a simplified top illustration of the third example local interconnect component.

FIG. 5 is a simplified cross-sectional illustration of a panel architecture with a photonic integrated circuit implemented in a glass reinforcement layer, in accordance with various embodiments.

FIG. 6 is a simplified cross-sectional illustration of a panel architecture with micro-channels implemented in a glass reinforcement layer, in accordance with various embodiments.

FIG. 7 is a simplified cross-sectional illustration of example conductive contacts, as may be implemented in various embodiments.

FIGS. 8-9 are simplified cross-sectional illustrations showing a process flow for manufacturing a panel-level HPC system using the panel architecture, in accordance with various embodiments.

FIG. 10 is a first example method of forming a panel.

FIG. 11 is a second example method of forming a panel.

FIG. 12 is a third example method of forming a panel.

FIG. 13 is a simplified cross-sectional illustration of an example panel substrate portion comprising a glass core.

FIG. 14 is a simplified cross-sectional illustration of an example panel assembly comprising a panel comprising a glass core and a local interconnect component located in a set of dielectric layers of the panel.

FIG. 15 is a simplified cross-sectional illustration of an example panel comprising a glass core with a local interconnect component located in the glass core.

FIG. 16 is a simplified cross-sectional illustration of an example panel comprising a glass core and photonic integrated circuits.

FIG. 17 is a simplified cross-sectional illustration of an example panel comprising a glass core, photonic integrated circuits, and a local interconnect component located in dielectric layers.

FIG. 18 is a simplified cross-sectional illustration of an example panel comprising a glass core, photonic integrated circuits, and a local interconnect component located in the glass core.

FIG. 19 is a simplified cross-sectional illustration of an example panel comprising a glass core with micro-channels and photonic integrated circuits.

FIG. 20 is a simplified cross-sectional illustration of an example panel comprising a glass core with micro-channels, photonic integrated circuits, and a local interconnect component located in dielectric layers.

FIG. 21 is a simplified cross-sectional illustration of an example panel comprising a glass core with micro-channels, photonic integrated circuits, and a local interconnect component located in the glass core.

FIG. 22 is a simplified cross-sectional illustration of an example coreless panel.

FIG. 23 is a simplified cross-sectional illustration of an example coreless panel comprising a local interconnect component.

FIG. 24 is a simplified cross-sectional illustration of an example coreless panel comprising a photonics integrated circuit.

FIG. 25 is a simplified cross-sectional illustration of an example coreless panel comprising a photonics integrated circuit and a local interconnect component.

FIG. 26 is a fourth example method of forming a panel.

FIG. 27 is a top view of a wafer and dies that may be included in a microelectronic assembly, in accordance with any of the embodiments disclosed herein.

FIG. 28 is a simplified cross-sectional side view showing an implementation of an integrated circuit on a die that may be included in various embodiments, in accordance with any of the embodiments disclosed herein.

FIG. 29 is a cross-sectional side view of a microelectronic assembly that may include any of the embodiments disclosed herein.

FIG. 30 is a block diagram of an example electrical device that may include any of the embodiments disclosed herein.

### DETAILED DESCRIPTION

As the technological challenges of high-performance computing (HPC) continue to rise, heterogeneous integration scaling has become an important performance enabler. Heterogeneous integration scaling can include increased interconnect density, increased number of integrated circuit dies per package, increased bandwidth, and improved power efficiency. Accordingly, many different advanced packaging architecture solutions have been deployed to increase planar and three-dimensional (3D) input/output (I/O) wire and area density for higher data bandwidth requirements, and to enable more effective die disaggregation and heterogeneous integration to shorten the time to market. Other technical solutions to the challenges of HPC include 2.5D/3D advanced packaging technologies, such as die embedding and/or employing local interconnect components to provide interconnects between dies (e.g., silicon (Si) interposers or bridges) to enable significantly higher packaged integrated circuit die and I/O counts and density to meet the HPC segment market demands and product performance needs.

Applications that depend on extremely high-performance computing include those that are expected to perform on the order of one zettaflops (10²¹ floating point operations per second). These applications may be referred to as zettascale performance applications. Non-limiting examples of zettascale performance applications include supercomputing, autonomous driving, and machine learning. Realizing platforms capable of zettascale performance presents technological challenges and packaging and system-level architecture innovations are expected to be developed to realize this level of performance. Proposed technical solutions include system-level heterogeneous integration of compute, I/O, memory, power management, and thermal management components. Some available high-performance computing solutions include implementing system-level architectures on a wafer (also referred to as wafer-level system integration, or a wafer-level solution). However, wafer-level system integration incurs several technical challenges. As may be appreciated, wafer-level system integration has packages that are limited in size by the diameter of a wafer. In addition, wafer-level system integration puts one entire system on one wafer; therefore, resolving yield issues for wafer-level solutions may become very challenging.

Embodiments disclosed herein propose a technical solution to the above-described technical problems, in the form of panel-level components (referred to herein individually as a “panel”) and systems comprising the panels or panel-level components. Embodiments of a panel may comprise multiple components (e.g., integrated circuit components) assembled using panel-level manufacturing techniques. As used herein, the term “panel-level” manufacturing techniques refer to manufacturing techniques in which integrated circuit dies are assembled and interconnections between them are formed on a single substrate and/or carrier, creating an overall structure. If the overall structure comprises multiple panels, the overall structure is singulated into individual panels. The overall structure can be packaged (by, for example, overmolding) before singulation or individual panels can be packaged after singulation. In an application, one or more of the panels may be assembled to create a multi-panel structure or panel assembly, as is described in more detail below. Individual panels (as well as multi-panel structures or components) may have an area that is less than, equal to, or larger than, the area of a wafer upon which any of the individual integrated circuit dies of a panel may have been formed.

Embodiments include various panel architectures. The panel architectures comprise interconnect structures (e.g., conductive traces, vias) to route die-level signals to package-level signals and local interconnects to route signals between integrated circuit dies. Some panel architectures comprise a glass layer (or glass core) with dielectric layers located on one or both sides of the glass layer. Other panel architectures do not contain a glass layer. The dielectric layers (along with the glass layer in some embodiments) comprise the interconnects structures. Panel architectures containing and not containing a glass layer can be referred to herein as “core” and “coreless” architectures, respectively. Some panel architectures, including coreless architectures, are assembled upon a glass carrier that provides mechanical stiffness and a flat surface upon which a panel can be fabricated. One benefit of the mechanical stiffness that a glass carrier (or glass reinforcement layer) can provide is limiting the amount of warpage that a panel can undergo during manufacture or in the field. Some panel architectures assembled on a glass carrier can comprise a layer of glass (also referred to herein as a glass reinforcement layer) to provide additional mechanical stiffness to the panel. The thickness of the glass reinforcement layer can be thinner that the glass layer used in core panel architectures. Thus, panels manufactured on a glass carrier and having a glass reinforcement layer can be thinner than other panels having a glass layer and not manufactured using a glass carrier.

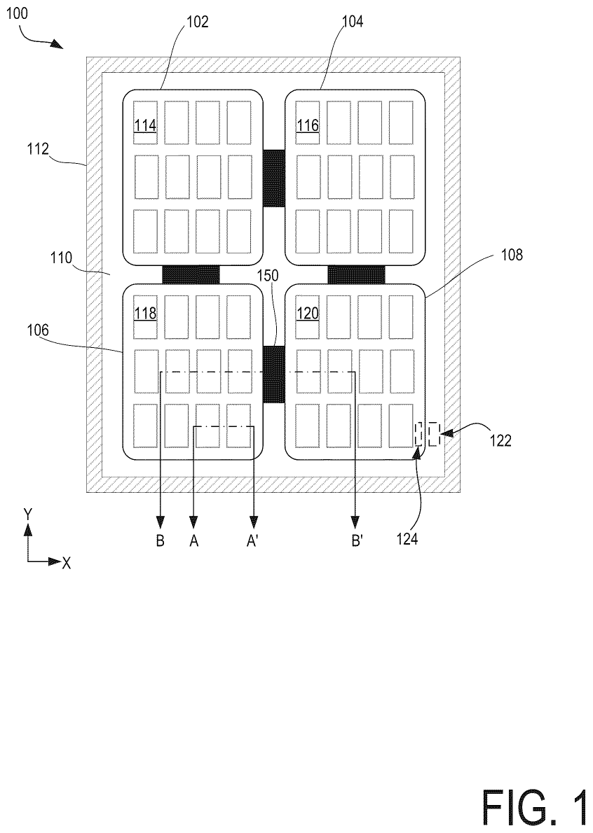

The provided panel architectures offer several technological and economic advantages, a first being design support for a panel-level solution with a larger area than available wafer-level (300 mm in diameter wafer-size) solutions; whereas wafer-level integration may limit a packaged HPC solution to an area of about 215 millimeters (mm)×215 mm, in some embodiments, individual panels disclosed herein can reach an area in a range of about 250 mm×250 mm to about 600 mm×600 mm, and in other embodiments, individual panels can exceed an area of 600 mm by 600 mm. Additionally, a single panel can provide a panel-level HPC solution; however, in other embodiments, the individual panels can further be assembled into a larger HPC solution, such as that illustrated in FIG. 1.

Other non-limiting examples of advantages of the provided panel architectures include support for design redundancy (by creating a multi-die structure by assembling smaller known good dies (KGDs)), additional mechanical stiffness and capacity for fine pitch geometries supported by the glass reinforcement layer, interconnect structures for die-to-die or chiplet-to-chiplet communication within panels, cavities in the glass reinforcement layer to accommodate discrete device integration (e.g., discrete devices such as deep trench capacitors, capacitors, transistors, magnetic inductor arrays (MIAs), inductors, etc.), flexible thermal management, and flexibility for vertical integration of integrated circuit dies and other components into the panel. Additionally, embodiments may use a glass carrier to provide improved flatness and mechanical stiffness to panels during manufacture and assembly. These concepts are developed in more detail below.

Example embodiments will hereinafter be described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Terms modified by the word “substantially” include arrangements, orientations, spacings, or positions that vary slightly from the meaning of the unmodified term. For example, the portion of a first layer or feature that is substantially perpendicular to a second layer or feature can include a first layer or feature that is +/−20 degrees from a second layer or feature, a first surface that is substantially parallel to a second surface can include a first surface that is within several degrees of parallel from the second surface. The amount of variation covered by a term modified by the term “substantially” is indicated throughout for certain arrangements, orientations, spacing, positions, etc. Values modified by the word “about” include values with +/−10% of the described values and values listed as being within a range include those within a range from 10% less than the described lower range limit and 10% greater than the described higher range limit.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

Embodiments of the provided panel architecture are directed to solving technical issues faced by providing applications with HPC or zettascale performance using panels. In some embodiments, an HPC solution can comprise a single panel of the provided architecture. In other examples, such as illustrated in FIG. 1, an HPC solution is achieved with a panel assembly 100 comprising multiple panels of the provided panel architecture assembled.

In the non-limiting example in FIG. 1, panel assembly 100 comprises four panels (panel 102, panel 104, panel 106, and panel 108) assembled, the individual panels may be referred to as “sub-panels,” or “panel quads” or “quarter-panels,” in the case where four panels are assembled to form the panel assembly 100. However, the panel assembly 100 may comprise more or less than four panels and panels arranged in any fashion (e.g., square (e.g., 2×2, 4×4, 6×6), rectangular (e.g., 2×4, 3×5, 4×7)). The panels of the panel assembly 100 may be attached to a panel-level substrate 112. The panel-level substrate 112 may comprise a printed circuit board, thin-film substrate, or another suitable substrate. In various embodiments and HPC solutions, either an individual panel or the entire panel assembly 100 can be overmolded with an encapsulant 110. The encapsulant 110 can comprise molding compound, dielectric materials, metal, ceramic, plastic, or a combination thereof.

In various embodiments, individual panels of the panel assembly 100 may have an area (e.g., a top-down x-y area with reference to the directional axes illustrated in FIG. 1), in a range of about 250-300 millimeters×250-300 millimeters. In other embodiments, individual panels of the panel assembly 100 may have an area in a range of about 450-600 millimeters×450-600 millimeters, or greater. That is, a lateral dimension of a panel (a dimension of the panel orthogonal to the panel's thickness) can be 250-300 mm in some embodiments and 450-600 mm in other embodiments. The individual panels may be smaller or larger in other embodiments. For example, in some embodiments, the lateral dimension of a panel is greater than 250 mm.

Blocks drawn inside each of the panels indicate separate unpackaged integrated circuit dies (e.g., die 114, die 116, die 118, and die 120). The unpackaged integrated circuit dies (die 114, die 116, die 118, and die 120) may also be referred to as chips, chiplets, chip complexes, or chiplet complexes. While the terms die, chip, and chiplet may be used interchangeably, the term chiplet is sometimes used to refer to an integrated circuit die that implements a subset of the functionality of a larger integrated circuit component, the larger integrated circuit component formed using one or more chiplets connected by inter-die interconnects (e.g., interposers, bridges, local interconnect components, local silicon interconnects). The use of chiplets in integrated circuit components has become attractive as feature sizes have reduced and the demand for high-performance larger integrated circuit components has increased. The approach of assembling multiple known-good dies (chiplets) to form a larger integrated circuit component results in improved manufacturing efficiencies as the overall yield of an integrated circuit component assembled from multiple small chiplets is better than that of an integrated circuit component in which the functionality of the chiplets is implemented on a single large integrated circuit die. Any integrated circuit die, chip, or chiplet can implement any portion of the functionality of any processor unit described or referenced herein.

Although the illustration depicts the chiplets within and among the panels as having uniform dimensions, in practice, chiplet dimensions (lateral dimensions and thickness) and shape can vary among chiplets within a panel and across panels; moreover, the chiplets on a given panel may vary by type/functionality (e.g., compute, memory, I/O, power management (controlling the delivery of power and/or providing power to components)). In the non-limiting example, each of the panels includes 12 dies arranged in an array of 4×3, however other numbers of dies per panel, and other arrangements of dies within a panel are supported. Additionally, the integrated circuit component die area and die height within a given panel may vary. Furthermore, a panel can have any shape, such as a substantially non-circular shape (e.g., substantially square shape, substantially rectangular shape (such as panels 102, 104, 106, 108)) or substantially circular shape.

As is described in more detail below, in some embodiments, the panel assembly 100 may be co-packaged with other electronic components or optical interconnects or waveguides and may support a photonic integrated circuit (PIC) attached or connected to a panel therein. In some embodiments, the other electronic components or PICs may be located external to a panel, such as indicated by location 122. In other embodiments, a panel of the panel assembly may have its substrate etched with waveguides and may further include one or more other electronic components or PICs in a keep-out zone of the panel, for example, such as indicated by location 124 of panel 108.

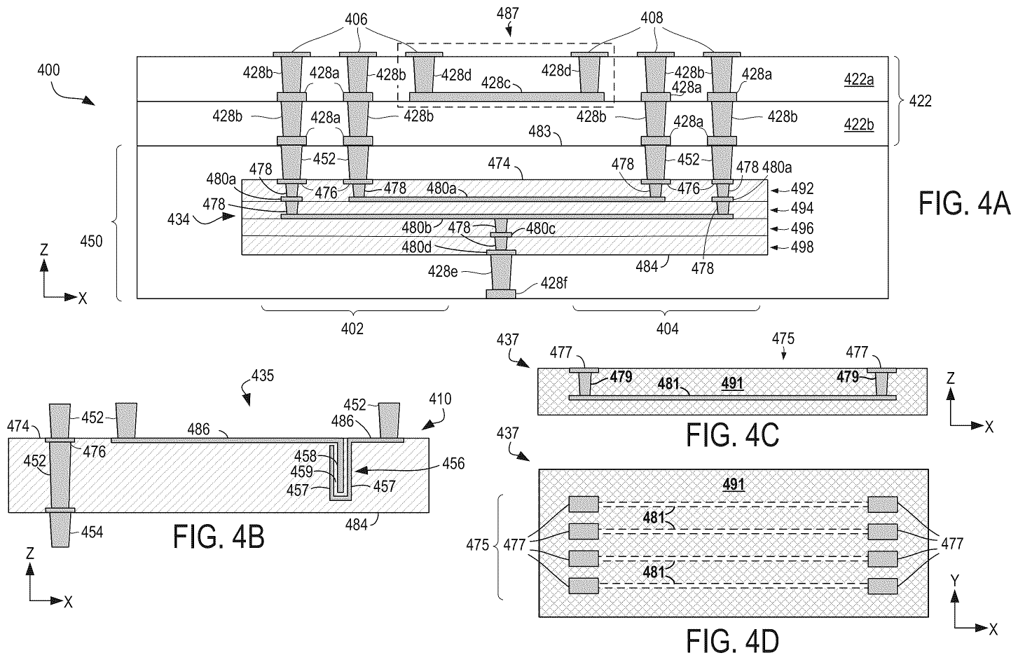

A panel may take the form of a populated or unpopulated panel substrate. Both populated and unpopulated panel substrates are configured (e.g., with appropriate pinouts) to communicatively couple associated integrated circuit die to each other (e.g., via fine pitch redistribution layer, conductive traces, or a local interconnect component, such as a bridge illustrated in FIG. 4A).

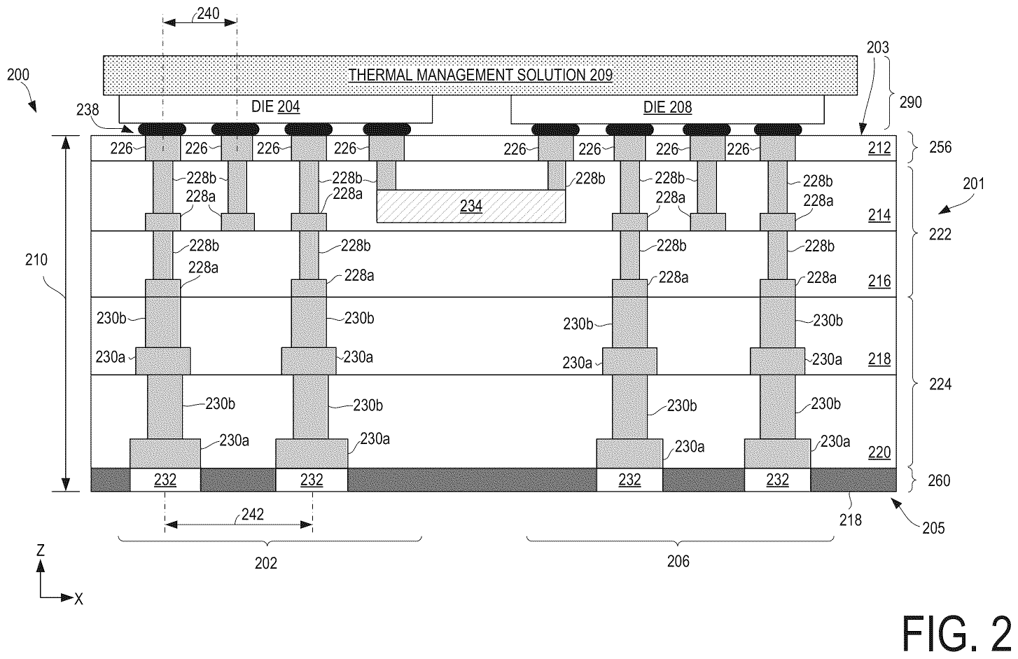

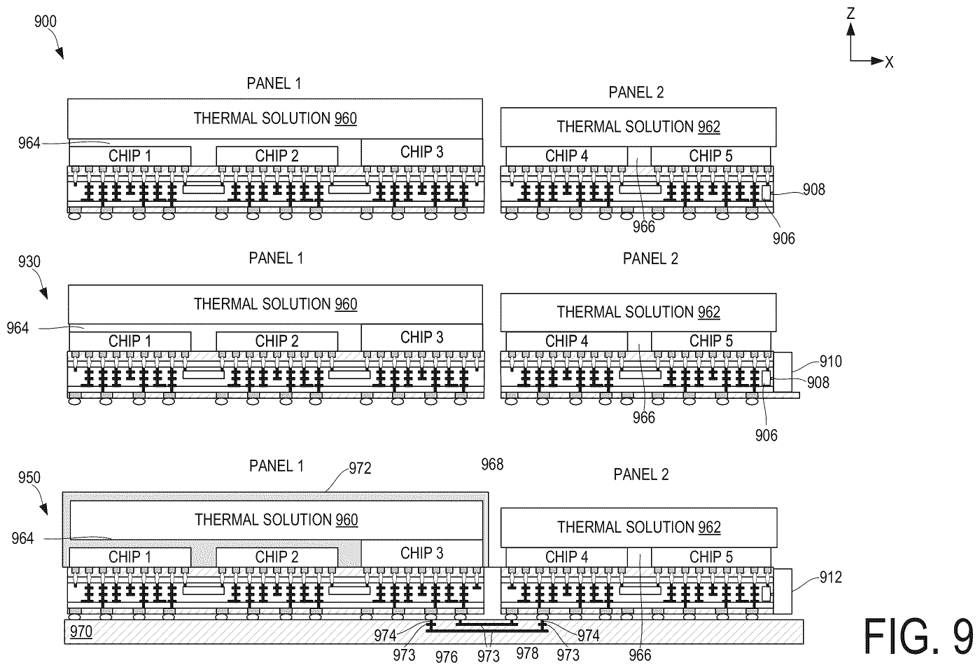

Cutout line A-A′ provides a reference for intra-panel (i.e., within a panel) architecture discussions in connection with FIGS. 2, 3, 5, 6, and 13-25. Cutout line B-B′ provides a reference for inter-panel (i.e., between panels) architecture discussions, such as creating a panel assembly, referenced again in FIG. 9.

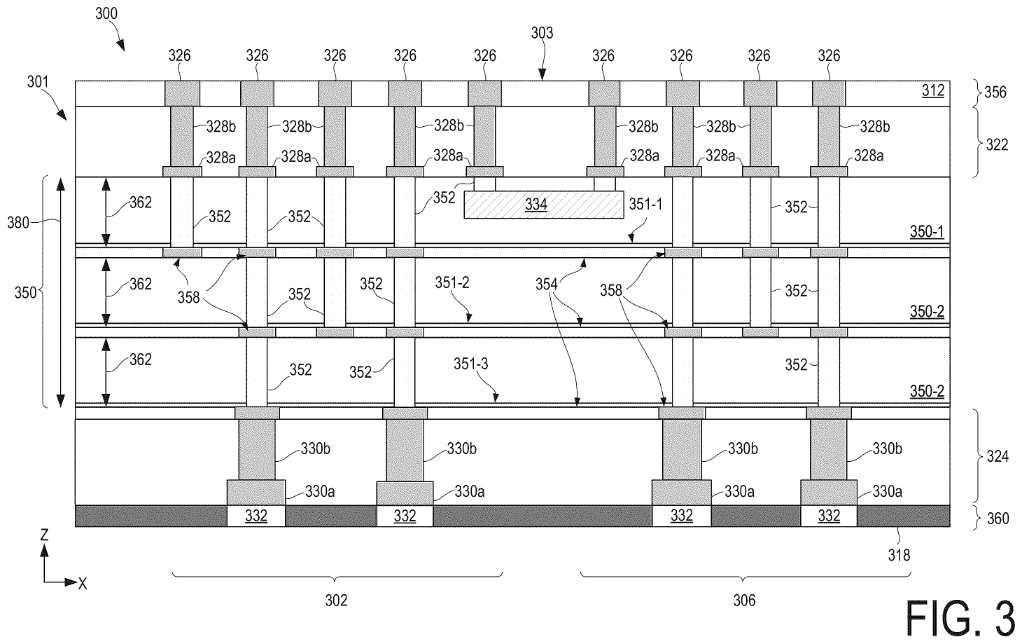

FIG. 2 provides a simplified cross-sectional illustration of a portion 200 of a panel as a reference for a general panel architecture discussion, and embodiments illustrated in FIGS. 3-9 and 13-25 provide technological improvements to the general panel architecture of FIG. 2, with additional and/or alternative features. Accordingly, many of the components from FIG. 2 are reproduced in FIGS. 3-9 and 13-25 as is observable with a comparison of shapes, locations, and context.

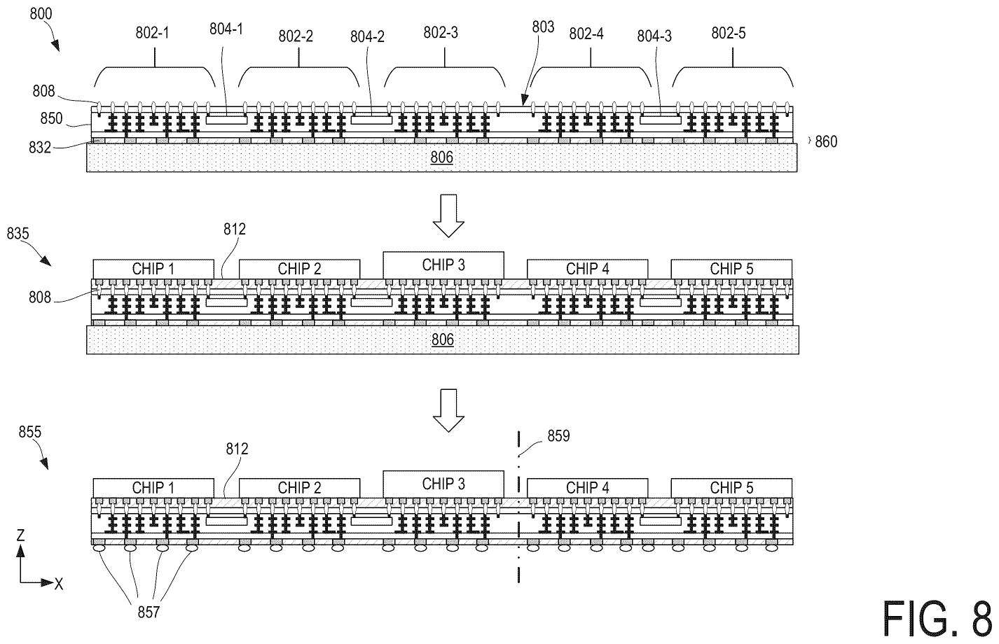

For example, interconnect structures (vias, conductive traces) 228, 328, 428, 528, 628, 728, 828, 1328, 2228, etc. are analogous; build-up layers (or, alternatively, redistribution layers (RDL) or dielectric layers) 222, 322, 422, 522, 622, 722, 822, 1322, 2222, etc. are analogous; build-up, dielectric or redistribution layers 224, 324, 424, 524, 624, 724, 824, 1324, 2224, etc. are analogous; conductive pads (or contacts) 232, 332, 532, 632, 1332, 2232, etc. are analogous; conductive contacts 226, 326, 526, 626, 1326, 2226, etc. are analogous; upper surface contact layers 256, 356, 1356, 2256 are analogous; lower surface contact layers 260, 360, 1360, 2260 are analogous; thermal management solutions 209, 960, 962, 1409, 1509, 2309, are analogous; glass reinforcement layers 350, 550, 650, etc. are analogous; glass cores 1351, 1451, 1551, etc. are analogous; interconnect structures in the form of through-glass vias 352, 552, 652, 1352, etc. are analogous, solder resist or dielectric materials 212, 312, 512, 612, 1312, 2212, etc. are analogous; solder resist or dielectric material 218, 318, 518, 618, 1318, 2218, etc. are analogous; micro-channels 668, 1968, 2068, etc., are analogous; local interconnect components 234, 334, 434, 534, 634, 1434, 2334, 2434, etc., are analogous; waveguides 564, 1664, 2464, etc. are analogous, photonic integrated circuits 562, 1662a, 1662b, 1762a, 1762b, 2462, 2562, etc. are analogous, FAUs 1621a, 1621b, 1721a, 172b, 2421, and 2521 etc. are analogous, and so on. Further, persons with skill in the art will appreciate that, although some object numbers are omitted in some figures to simplify clutter, objects sharing a same shape, location, and/or context with labeled objects in other figures are analogous (e.g., comprise a same material, have a same dimension, possess a same property). FIGS. 3-7 and 13-25 focus on (intra-panel) panel architectures for unpopulated panels and FIGS. 8-9 describe populating and packaging the panels.

As used herein, “pitch” means the physical distance at which a feature is repeated (e.g., the space from the center of one instance of a feature to the center of an adjacent instance of the feature). For example, on surface 203, conductive contacts 226 have a pitch 240 and on surface 205, conductive pads 232 have a pitch 242.

As used herein “fine pitch” generally means a die-scale pitch, as indicated on surface 203, and “coarse pitch” generally means a package-level pitch, as indicated on surface 205. Fine pitch dimensions may include a range of about 0.001 mm to about 0.3 mm. In some embodiments, features having a fine pitch have dimensions of about 1 μm (micron) or less. In other embodiments, features having a fine pitch may have dimensions of about 0.5 μm or less. In addition to the conductive contacts that are used to attach integrated circuit dies to a panel, other features in a panel that can have a fine pitch include the vias in one or more RDLs adjacent to the pinouts for integrated circuit dies. Fine pitch geometries are smaller than “coarse pitch” geometries.

As indicated on surface 205, “coarse pitch” 242 generally refers to geometries associated with package-level conductive pads 332 (or contacts 332); the coarse pitch may be a ball grid array (BGA) pitch or a land grid array (LGA) pitch. In various embodiments, a BGA pitch is in a range of about 0.1 mm to about 1 mm, and LGA pitch is in a range of about 0.1 mm to about 1 mm. Additionally, as is generally represented in the Figures, the thickness of conductive traces of RDLs adjacent to the package-level conductive contacts or conductive pads 332 at surface 205 may be thicker than the conductive traces in RDLs adjacent to the pinout for integrated circuit dies at surface 203.

In some embodiments, the pitch at surface 203 is smaller than the pitch at surface 205, and in some embodiments, the pitch at surface 203 is the same as the pitch at surface 205. Conductive contacts 226 and conductive pads 232 can comprise solder, copper, or another suitable metal or other material.

Build-up layers or redistribution layers (RDLs) (e.g., 222, 322, 422, 522, 622, 722, and 822) are referred to herein. Although the figures illustrate two RDL 222 sub-layers and two RDL 224 sub-layers, in practice, there can be any number of RDL sub-layers. For example, in server applications, an RDL can comprise up to 10 sub-layers. In various embodiments, an RDL comprises a dielectric material and may include a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, an RDL comprises a photo-imagable dielectric (PID). In some embodiments, an RDL comprises an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties of the RDLs (e.g., the dielectric constant (Dk), and/or dissipation factor (insertion loss) (Df)).

In some embodiments, it is advantageous for the RDLs to have a CTE that matches that of integrated circuit dies (e.g., match the CTE of silicon) attached to a panel substrate. In some embodiments, the dielectric material of an RDL can have a CTE that is close (e.g., within 10%) to that of silicon. In other embodiments, the dielectric material of an RDL can be any type of epoxy molding compound. RDLs or build-up layers may include a metal layer comprising conductive traces (or metal lines), metals used for interconnect metals in the RDL include copper or other suitable metal.

Local interconnect components and interconnect structures are referred to herein. As used herein, local interconnect components refer to separately manufactured components that route signals between dies within a panel. In comparison, an external interconnect component could be used to route signals between panels. As used herein, “interconnect structures” can comprise one or more conductive traces, one or more vias, or a combination thereof. The term conductive trace can refer to via contacts, which can be metal lines to which vias connect to and do not comprise a lateral signal routing portion. Interconnect structures can be present in various RDLs, dielectric layers, build-up layers, or glass layers, and can span multiple such layers. Interconnect structures may collectively provide an electrically conductive path from a feature on a first surface 203 of a panel substrate 201 to a feature on a second surface 205 of the panel substrate. In various embodiments, an interconnect structure in a first dielectric layer is attached to an interconnect structure in a second dielectric layer, thereby providing an electrically conductive path through the substrate.

Portion 200 relates to cutout line A-A′ and includes a substrate 201. The substrate 201 may have a thickness 210 that is in a range of substantially 0.05 mm to substantially 3 mm, wherein substantially equals +/−10%), and may comprise one or more build-up or redistribution layers 214, 216, 218, and 220. Region 202, a column on the left of the page, provides signal communication and translation routing (e.g., translating the fine pitch die-level signals to coarser pitch panel-level signals) for die or chiplet 204 attached at an upper surface 203, and on the right, region 206 provides signal communication and translation routing for die or chiplet 208 attached at the upper surface 203. A solder resist or other dielectric material 212 on the upper substrate surface may be patterned with a respective pinout (physical arrangement of conductive contacts 226 at a respective pitch) for individual of one or more chiplets that are part of the portion 200. The respective pinouts may comprise individual conductive contacts 226 arranged as conductive contacts for individual chiplet or die (e.g., die 204 and die 208). In some embodiments, the conductive contacts 226 are arranged in an upper surface contact layer 256 as two distinguishable sets with the same pitch (e.g., a die pitch, or fine pitch), however, in other embodiments, the conductive contacts 226 are arranged as two sets that do not have the same die pitch or fine pitch. Further, the conductive contacts associated with one die may be arranged with more than one pitch. Some signal routing may occur from at least one conductive contact of the first set of conductive contacts 226 (e.g., die 204) to at least one conductive contact of the second set of conductive contacts 226 (e.g., die 208), via the local interconnect component 234. Some of the vias 228b can be arranged with a fine pitch to match the pitch of the conductive contacts 226.

In various embodiments, RDL 222 comprises features (e.g., interconnect structures comprising metal lines and vias) having a finer pitch than the pitch of features in RDL 224. Thus, RDLs 222 and 224 can be considered to translate the tighter pitch of the die pads (that match the pitch of conductive pads 226) to the greater pitch of the panel pads (that match the pitch of the conductive pads 232). Although RDL 222 is depicted as comprising two layers, RDL 214 and RDL 216, and RDL 224 is depicted as comprising two layers, RDL 218 and RDL 220, in practice the number of layers in RDL 222 and RDL 224 may vary. Persons with skill in the art may appreciate that the distinctions in the various dielectric or build-up layers attributed to RDL 222 and RDL 224 in this discussion have been introduced for illustrative purposes; in a cross-sectional image of the substrate 201, such as by a transmission electron microscope (TEM), the layers 212, 214, 216, 218, and 220 may be indistinguishable.

For illustrative purposes, the RDL 222 comprises interconnect structures 228 and the RDL 224 comprises interconnect structures 230. The interconnect structures 228 may be arranged within the RDL 214 and 216 to route electrical signals according to a wide variety of applications; in particular, the arrangement is not limited to the configuration of interconnect structures 228 depicted in FIG. 2. In some embodiments, the interconnect structures 228 may include conductive traces or metal lines (lines) and/or via contacts 228a and vias 228b. The conductive traces, via contacts, and vias can comprise an electrically conductive material such as a metal (e.g., copper, aluminum, nickel, cobalt, iron, tin, gold, silver, or combinations thereof). The lines of interconnect structures 228a may be arranged to route electrical signals along the surface of a plane that is substantially parallel with the surface 203 of the substrate 201. For example, the lines of interconnect structure 228a may route electrical signals in a direction in and out of the page and/or in a direction across the page. The vias 228b may be arranged to route electrical signals in a direction of a plane that is substantially perpendicular to the surface of the substrate 201. Likewise, the interconnect structures 230 may include conductive traces or lines and/or via contacts 230a and or vias 230b comprising an electrically conductive material such as a metal (e.g., copper, aluminum, nickel, cobalt, iron, tin, gold, silver, or combinations thereof). The lines of interconnect structures 230a may be arranged to route electrical signals in a direction that is substantially parallel with the surface 203 of the substrate 201. For example, the lines 230a may route electrical signals in a direction in and out of the page and/or in a direction across the page. The vias 230b may be arranged to route electrical signals in a direction of a plane that is substantially perpendicular to the surface of the substrate 201.

Local interconnect component 234 functions to communicatively couple chiplets 204 and 208. Substrate 201 may be a portion of a product that is either populated or unpopulated. In various populated embodiments, the components indicated in region 290, attached at the upper surface 203 of the substrate 201, may be present. For example, a populated panel substrate may be populated with respective die or chiplets (e.g., 204, 208), which may be attached via conductive die bumps 238 or any solder or hybrid bonding (the bonding of components through bonding (direct attachment) of interconnects and dielectric layers of the components). In some embodiments, a polymer can be used to bond copper conductive contacts (e.g., pads) on the die to copper conductive contacts (e.g., 226) of a panel substrate. In some embodiments, a polymer can also be used to bond solder conductive contacts on the die to solder conductive contacts on a panel substrate. In some embodiments, an inorganic material (e.g., silicon dioxide, silicon nitride) can be used to bond copper conductive contacts of components together. In some embodiments, dies are attached to the substrate 201 through direct attachment of bumps (e.g., microbumps) attached to both surfaces (e.g., die surface, panel surface). In some embodiments, the chiplets also have underfill applied (not shown) underneath the chiplets and above the surface of the substrate 201. A large form factor thermal management solution 236 comprising a cooling component such as a vapor chamber, heat pipe, heat sink, or liquid-cooled cold plate may be implemented. The thermal management solution is a large form factor solution in that it can be a panel-level thermal management solution (providing cooling to integrated circuit dies of a panel) or a multi-panel thermal management solution (providing cooling to integrated circuit dies of multiple panels). As part of a thermal management solution, a thermal conduction layer interface material (TIM) may be located over the die 204, 208. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader. FIG. 9 provides examples of panels with thermal management solutions.

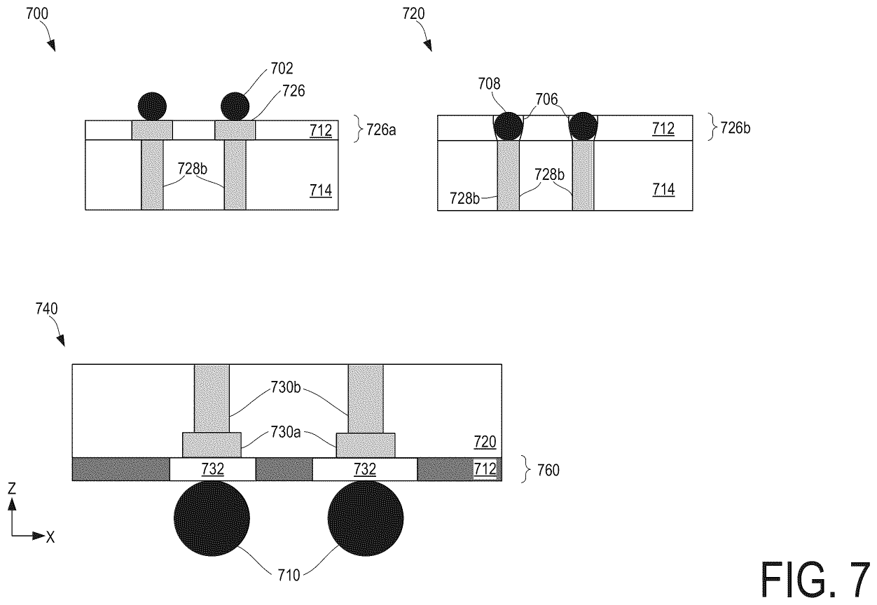

Turning now to FIG. 3, an embodiment of the provided panel architecture includes a glass reinforcement layer between dielectric layers or RDLs of the substrate. The simplified cross-sectional illustration of a portion 300 relates to cutout line A-A′ and includes a substrate 301. Substrate 301 comprises a glass reinforcement layer 350 sandwiched between dielectric layer or RDL 322 and dielectric layer or RDL 324. In various embodiments, an overall height of the substrate is unchanged (e.g., substantially 210, FIG. 2) and the RDL 322 and 324 are thinned or omitted to accommodate the glass reinforcement layer 350, which has a height/thickness 380 in a range of about 30 microns to 1.5 millimeters, +/−10%. By analogy with objects in FIG. 2, RDL 322 may comprise multiple build-up layers, dielectric layers, or redistribution layers, and RDL 324 may comprise multiple build-up layers, dielectric layers, or redistribution layers. Also, by analogy, solder resist or other dielectric material 312 may be patterned with a pinout for respective one or more chiplets that may be attached to the substrate of the panel. The pinout may comprise individual conductive contacts 326 arranged at a fine pitch, and upper surface contact layer 356 may also take the form of other embodiments (e.g., 726a, 726b), as described in connection with FIG. 7. Lower surface contact layer 360 may also take the form of other embodiments (e.g., 760), as described in connection with FIG. 7. Also as mentioned, vias/contacts/traces/pads 328, 330, 360, and 332 are analogous to counterparts 228, 230, 260, and 232. Local interconnect component 334 is analogous to local interconnect component 234. Region 302 is dedicated to a first die and region 306 is dedicated to a second die.

Glass reinforcement layer 350 may comprise glass, (as used herein, glass can be an alkali-free alkaline earth boro-aluminosicilate glass, such as a glass comprising aluminum, oxygen, boron, silicon, and an alkaline-earth metal (e.g., beryllium, magnesium, calcium, strontium, barium, radium, such as a glass comprising SiO₂, Al₂O₃, B₂O₃, and MgO), or a photosensitive glass (photomachineable or photostructurable glass). In some embodiments, a photosensitive glass can be a glass that belongs to the lithium-silicate family of glass (e.g., a glass comprising lithium, silicon, and oxygen) comprising metallic particles, such as gold, silver, or other suitable metallic particles. Glass reinforcement layer 350 may comprise multiple glass sheets (in the non-limiting example, three glass sheets, 350-1, 350-2, and 350-3, are illustrated).

Glass reinforcement layer 350 may contain some or all the interconnect structures to support the signal routing from the contacts 326 at the die surface (303) of the substrate 301 to the conductive pads 332. The interconnect structures can include vias 352 in the glass layer 350, which may be referred to as through-glass vias (TGVs). The interconnect structures, collectively, provide an electrically conductive path from a feature on a first surface 303 of a panel substrate 301 to other features on the first surface 303, and/or to the conductive pads 332. Individual glass sheets 350-1, 350-2, and 350-3 may have a respective dielectric layer (351-1, 351-2, 351-3) located on a lower surface thereof, to act as an adhesion layer to laminate the glass sheet over/on a layer 354 of solder resist or dielectric having conductive contacts 358 and traces therein. While one with skill in the art may appreciate that, in practice, “layer” and “sheet” may be used interchangeably, these concepts are employed here to aid in understanding the embodiment.

In various embodiments, a thickness 362 of the glass sheets 350-1, 350-2, 350-3 may be substantially in a range of 20-150 microns, wherein substantially means +/−5%. In some embodiments, the thickness of any of the glass sheets can be different from that of any other glass sheets in a glass layer. In various embodiments, the dielectric layers 351 may comprise Ajinomoto Build-up Film (ABF), an epoxy molding compound, any other dielectric layer referenced or described herein, or any other suitable dielectric material. In various embodiments, the dielectric layers 351 can be substantially 10 microns thick.

A local interconnect component 334 in the glass reinforcement layer 350 facilitates communication between two or more chiplets in a portion of a substrate, a panel, and/or a panel assembly 100. A local interconnect component 334 may comprise an interposer (or bridge), or one or more redistribution layers (RDLs). Local interconnect components 334 can be selectively located in a substrate. That is, in a panel comprising two dies that are connected by a local interconnect component (e.g., 334), the panel can further comprise adjacent dies that are not connected by local interconnect components.

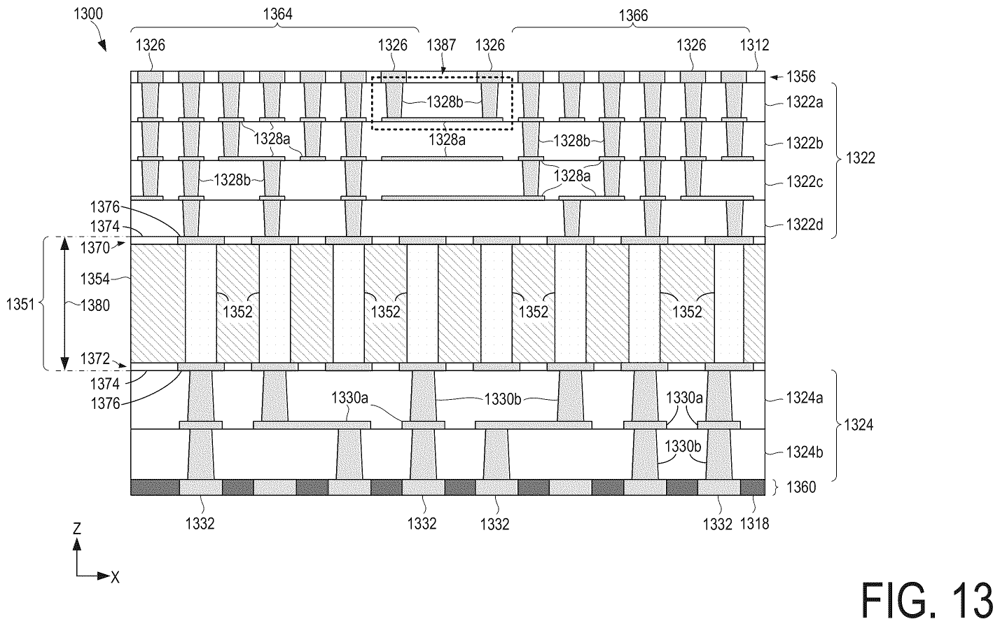

FIG. 4A illustrates a simplified cross-sectional illustration of a first example local interconnect component. FIG. 4A is a simplified cross-sectional illustration of a portion 400 of a panel substrate comprising RDL 422 and a first glass sheet 450 that is a part of a glass layer of the panel. The glass layer 450 can be a glass reinforcement layer (e.g., 350, 550, 650) or a glass layer that is part of the glass core in the embodiments in FIGS. 13-21. The RDL 422 comprises two constituent layers (sub-layers) 422a and 422b. A local interconnect component 434 (or bridge) is located in the glass sheet 450 and provides interconnections between a first die attached to conductive contacts 406 and a second die connected to conductive contacts 408 (first and second die not shown).

Bridge conductive contacts 476 are located on a surface 474 of the local interconnect component 434. In various embodiments, the bridge conductive contacts 476 comprise copper. Local interconnect component 434 comprises conductive traces 480a, 480b, 480c, and 480d located in first, second, third, and fourth dielectric layers 492, 494, 496, and 498, respectively. The dielectric layers 492, 494, 496, and 498 further comprise vias 478 providing connections between conductive traces in different dielectric layers or between a conductive trace and a bridge conductive contact 476.

Bridge vias 478 and bridge conductive traces 480 may comprise copper or another suitable conductive material and provide electrically conductive paths between the bridge conductive contacts 476. The dielectric layers 492, 494, 496, 498, and 422 can be a suitable nitride or oxide, such as silicon dioxide (SiO₂), carbon-doped silicon dioxide, fluorine-doped silicon dioxide, hydrogen-doped silicon dioxide, or silicon nitride.

The interconnect structures in the RDL 422 (conductive traces 428a and vias 428b) are analogous to interconnect structures 328a and 328b and provide electrically conductive paths from the bridge conductive contacts 476 to conductive contacts 406 for a first die or chiplet and to conductive contacts 408 for a second die or chiplet. Vias 452 provide a connection from RDL interconnect structures to the bridge conductive pads 476. In embodiments where the top surface 474 of the local interconnect component 434 is flush with a top surface of the top glass sheet within a glass layer (e.g., surface 483), vias 452 may not be present.

In some embodiments, a region located in one or more dielectric layers above a local interconnect component can comprise interconnect structures that provide an electrically conductive path between dies attached to a panel substrate. For example, a region 487 in the dielectric layer 422 comprises conductive traces 428c and vias 428d providing an electrically conductive path between one of the conductive contacts 406 and one of the conductive contacts 408. In other embodiments, the region above a local interconnect component does not contain routing that provides an electrically conductive path between adjacent dies. Together, conductive contacts and traces/vias 406, 428a, 428b, 428c, 428d, 452, 476, 478, 480a, and 480b, provide electrically conductive paths between the first and second dies, and thus allow the die to be communicatively coupled.

In the example, two of the vias 478 connect conductive trace 480b to 480c and 480c to bridge pad 480d, which in turn is connected to via 428e and conductive trace 428f located within the glass layer 450. Thus, the local interconnect component 434 can also provide electrically conductive paths between the first and second dies to conductive traces in the glass layer located below the local interconnect component 434.

FIG. 4B is a simplified cross-sectional illustration of a second example local interconnect component. Local interconnect component 435 comprises a through-silicon via (TSV) 452. TSV 452 provides an electrically conductive path from an interconnect structure (via 452) positioned adjacent to the top surface 474 of the local interconnect component 435 and an interconnect structure (via 454) positioned adjacent to a bottom surface 484 of the local interconnect component 435. In various embodiments, TSVs can comprise copper, tungsten, or another metal.

FIG. 4B further illustrates a trench capacitor 456 located in the local interconnect component 435. The trench capacitor 456 comprises a first terminal (one or more first capacitor conductive traces) 458, a second terminal (one or more second capacitor conductive traces) 458, and a capacitor dielectric 459 positioned between the first terminal 457 and the second terminal 458. The first and second terminals 457 and 458 comprise one or more conductive traces oriented substantially perpendicular to a top surface of the panel substrate (e.g., upper surface 203) in which the local interconnect component 435 is located. The capacitor dielectric 459 can comprise any of the dielectrics disclosed herein (e.g., doped or undoped silicon dioxide, silicon nitride) or any other suitable dielectric. The first and second terminals 457 and 458 are further connected to conductive traces 486 of the local interconnect component that allow for connection to the capacitor 456 by interconnect structures external to the local interconnect component 435 (e.g., via 452). In addition to trench capacitors, a local interconnect component can comprise other types of capacitors, such as planar capacitors.

FIGS. 4C and 4D are cross-sectional and top illustrations of a third example local interconnect component. Local interconnect component 437 comprises a magnetic inductor array (MIA) 475. MIA 475 comprises pads 477, vias 479, and conductive traces 481. The conductive traces 481 act as inductors and are surrounded by a ferromagnetic material 491. The conductive traces 481 can comprise copper or another suitable metal, the pads 477 can comprise nickel, palladium, and gold or another suitable metal or alloy, and the ferromagnetic material 491 can comprise iron or an iron alloy. In some embodiments, the ferromagnetic material 491 comprises iron or iron alloy microparticles in an epoxy matrix.

In addition to TSVs, capacitors, and inductors (e.g., MIAs), in other embodiments, the local interconnect component 434 can comprise other passive components, such as resistors and/or active components, such as transistors.

As mentioned above, a local interconnect component located in a panel substrate (such as local interconnect component 434 embedded within portion 400 of a panel substrate) can be implemented as a silicon interposer (interposer) or a local silicon interconnect (local interconnect). In some embodiments, the local interconnect component can be an Intel® Embedded Multi-Die Interconnect Bridge (EMIR). In some embodiments, the local interconnect component can be compliant with a Universal Chiplet Interconnect express (UCIe) standard.

Local interconnect components can be manufactured separately from a panel substrate, and then located in, integrated into, or embedded within, the panel substrate. The separate manufacture of a local interconnect component allows for the use of semiconductor manufacturing techniques to create the local interconnect component, thereby creating local interconnect components with internal features (e.g., vias, pads, conductive traces) with geometries (e.g., via width/space, conductive trace width/space/thickness) that can be smaller than the geometries of similar features external to the local interconnect component in a panel substrate.

A local interconnect component can be located in a panel substrate through the formation of a cavity in a panel substrate (e.g., formation of a cavity in a glass layer and/or one or more dielectric layers) at a point during panel manufacture, insertion of the local interconnect component within the panel substrate, and formation of the remainder of the panel substrate. A local interconnect component can be located in a glass layer or one or more RDLs. A local interconnect component can span more than one RDL. An upper surface of an RDL can be flush with an upper surface on an RDL, including an upper surface of an RDL that is part of an upper surface of a panel surface. As such, the phrase “located in” in the context of a local interconnect component located in a glass layer or one or more RDLs can refer to a local interconnect component that is entirely embedded (a glass layer or one or more RDLs are positioned adjacent to all sides of the local interconnect component) or partially embedded (a glass layer or one or more RDLs are positioned adjacent to less than all sides of the local interconnect component).

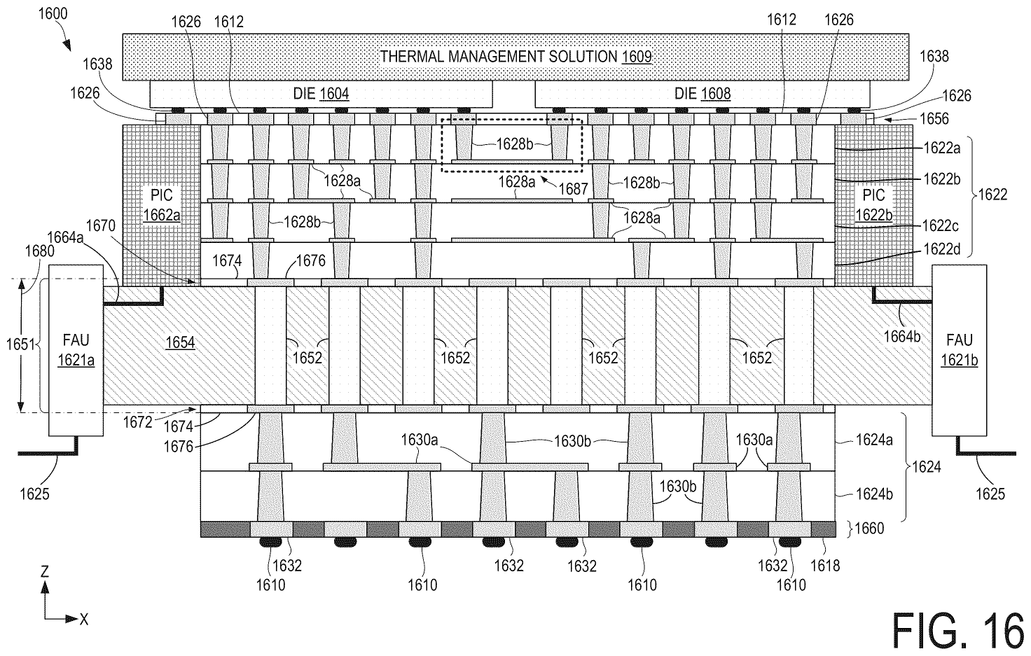

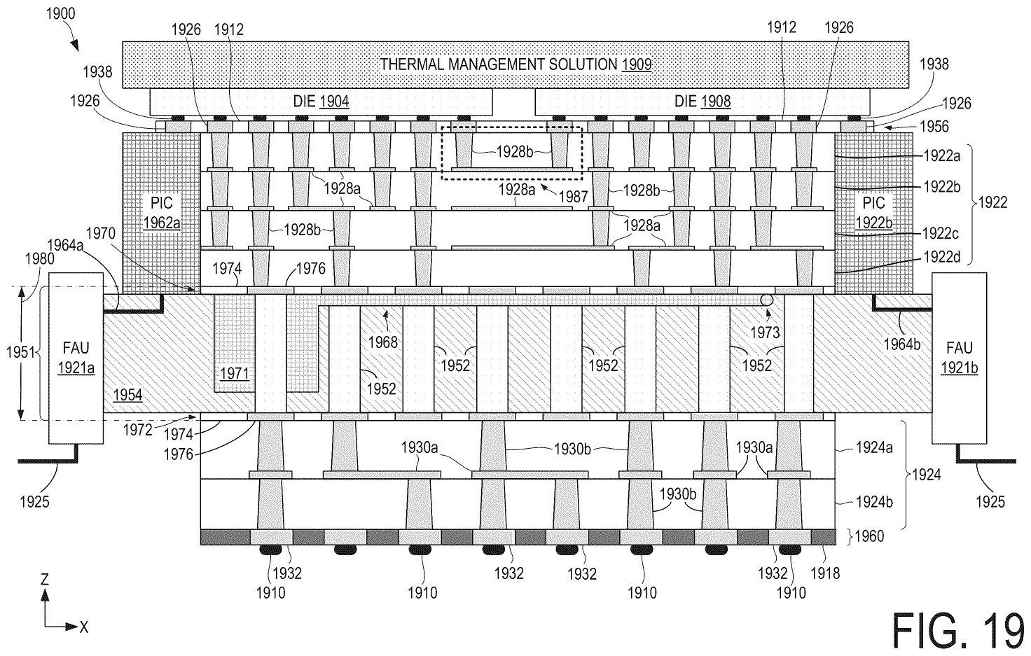

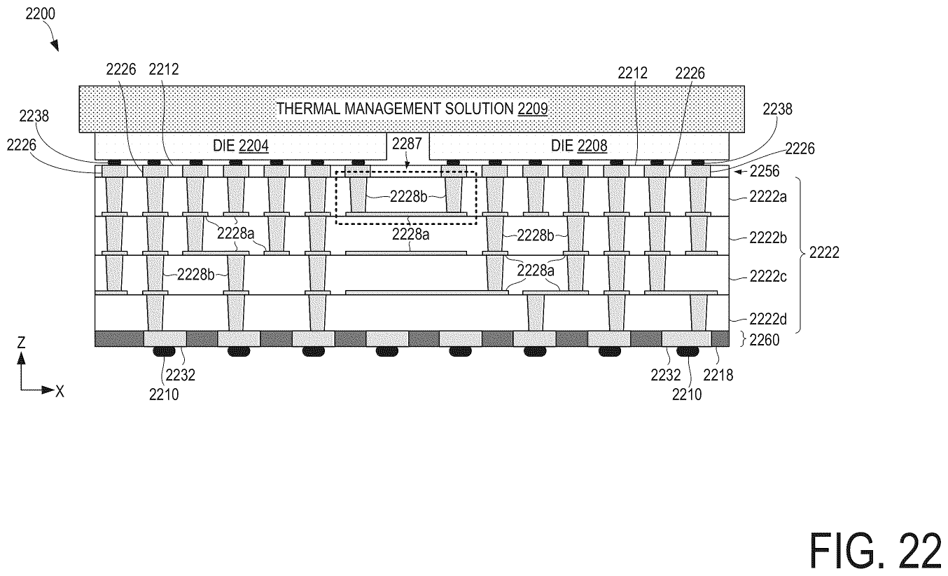

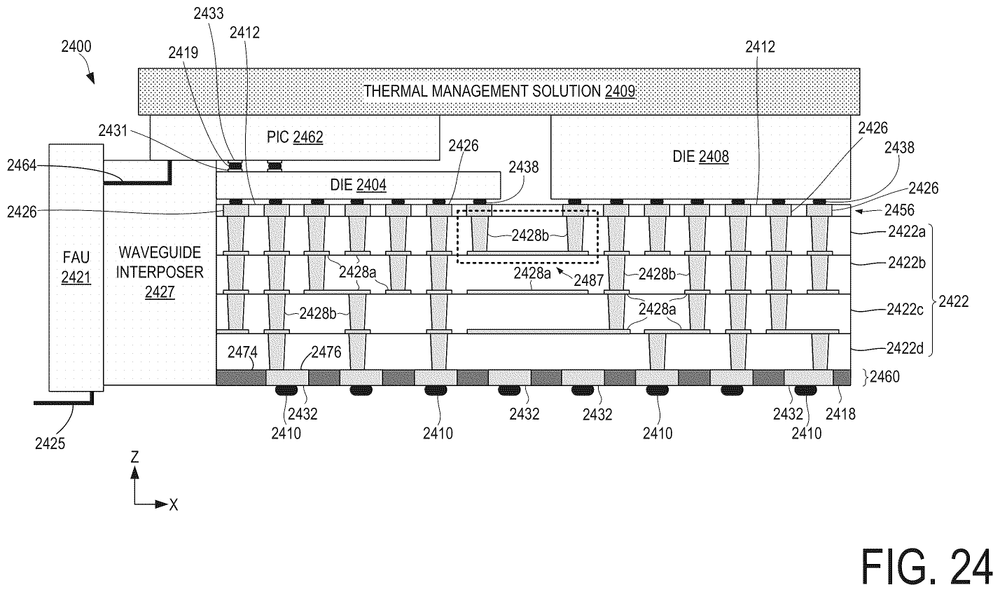

In some embodiments, a local interconnect providing electrically conductive paths between adjacent die in a panel can be provided by interconnect structures that are part of the one or more RDL layers that provide routing of die-level signals to package-level signals. That is, adjacent die in a panel can be interconnected without the use of a separately manufactured local interconnect component placed in a panel substrate during panel manufacture. Region 487 in FIG. 4A, region 1387 in FIG. 13, region 1687 in FIG. 16, region 1987 in FIG. 19, region 2287 in FIG. 22, and region 2487 in FIG. 24 illustrate such local interconnects.

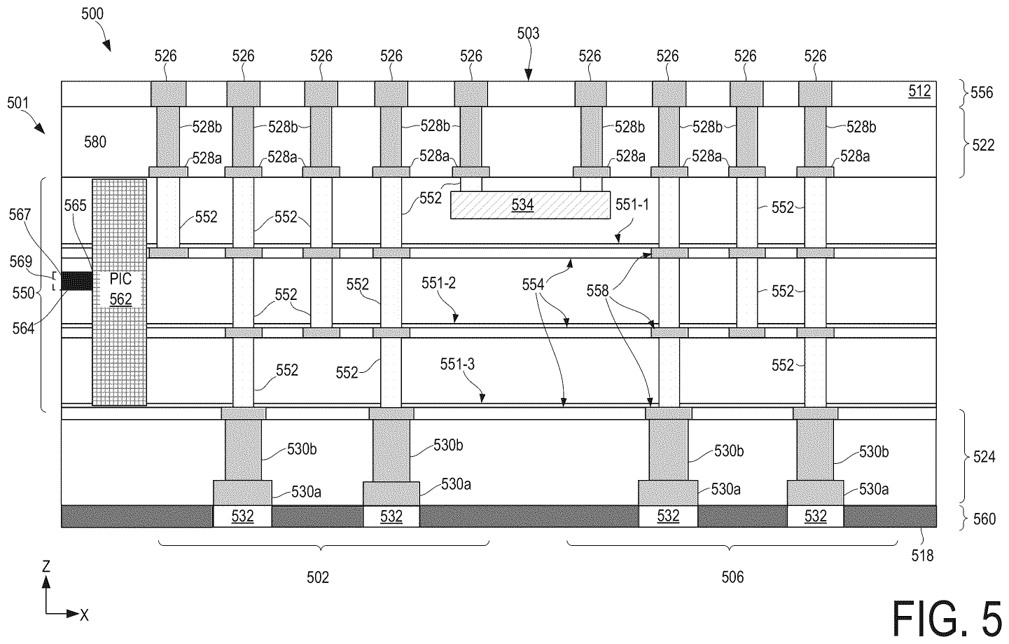

With reference to FIG. 5, in various embodiments, the panel assembly 100 may implement waveguide routing and/or a silicon photonics component, such as a photonic integrated circuit (PIC). The simplified cross-sectional illustration of a portion 500 relates to cutout line A-A′ and includes a substrate 501. FIG. 5 illustrates a photonic integrated circuit (PIC) 562 implemented in the panel architecture of portion 500 of a panel substrate 501, implemented directly in the glass reinforcement layer 550. The associated waveguide routing 564 of the PIC 562 and out of the substrate 501 can also be implemented directly in the substrate 501, also directly in the glass reinforcement layer 550.

In these embodiments, the waveguide routing 564 may be fabricated by laser direct writing in a glass sheet of the glass reinforcement layer 550. In an embodiment, a waveguide routing 564 is an enclosed path formed or etched in the glass reinforcement layer 550, having a first end 565 and a second end 567. The waveguide routing 564 is configured to passively allow light of a specific wavelength or a range of wavelengths to travel therethrough. That is, in operation, the waveguide routing 564 provides operable communication by receiving light from a first source (such as the PIC 562) at the first end 565, and passively transmitting the light to the second end 567, where it may exit the waveguide routing 564 (alternatively, the light may travel in the opposite direction through the waveguide routing). In some embodiments, as illustrated, the waveguide routing 564 has a first end 565 in operable communication with a PIC 562 and a second end 567 at a surface of the glass reinforcement layer. In various embodiments, as illustrated, the second end 567 may be at a vertically oriented surface, with respect to FIG. 5, and in other embodiments, the second end 567 may be at a laterally oriented surface, with respect to FIG. 5. In various embodiments, there may be an optional optical coupling component 569 added to the surface at the second end 567, for attaching an external component to the waveguide routing 564. Although indicated in FIG. 5 as a straight line, in practice, the waveguide routing 564 may be implemented as a pattern in two or three dimensions, having a uniform diameter and an overall path length that may include curves and/or loops, wherein the overall path length (generally from first end 565 to second end 567) reflects a specific application.

In some embodiments, the waveguide routing 564 can comprise a dielectric material that has a higher permittivity, and thus a higher index of refraction, than that of the material surrounding the waveguide routing (the glass reinforcement layer 550). In some embodiments, the waveguide comprises silicon and oxygen. In some embodiments, a waveguide can comprise a photonic-crystal fiber, a hollow tube with a reflective inner surface (e.g., polished metal or a multilayer film that guides light by Bragg reflection), or small prisms around a hollow pipe that reflects light via internal reflection.

Photonic integrated circuits implement one or more photonic functions and comprise one or more optical components, such as waveguides, lasers, electro-optical modulators, polarizers, photodetectors, and the like. PICs are often used in data communications (such as fiber-optic communication) and sensing applications. Examples of uses for PICs include wavelength division multiplexing (WDM), interferometers, wave modulators, optical transceivers, light detection and ranging (LiDAR) antennas, and the like.

A non-limiting example of an optical component that can be included in a PIC is a silicon micro-ring resonator (MRR), generally referred to herein as a ring resonator structure. The ring resonator structure is a passive structure generally including (i) a compact circular micro-ring structure comprising an optical silicon waveguide that is looped back on itself with a small bend radius to resonate at one or more frequencies referred to as a spectral response, or free spectral range (FSR), and (ii) a linear silicon waveguide located proximate to the micro-ring structure and communicating therewith.

In various embodiments, the micro-ring structure is substantially circular, and the silicon waveguide is substantially linear (i.e., +/−10%) from a circle and +/−10% from linear. In some embodiments, the micro-ring structure may have an oval shape or a shape of a racing track. In some embodiments, the silicon waveguide may include a curve in a region alongside the micro-ring structure, to enhance the coupling effect between the silicon waveguide and the micro-ring structure. In some embodiments of the ring resonator structure, the ring resonator structure further includes an optional second silicon waveguide that is also linear.

In some embodiments, the micro-ring structure may comprise silicon. In some embodiments, the micro-ring structure may comprise a lightly-doped P region, lightly-doped N region, highly-doped P+ region, highly-doped N+ region, intrinsic silicon and silicon dioxide (as a divider between different Si doping regimes when needed). An optics component, such as a PIC, can be embedded within a panel substrate through formation of a cavity in the panel substrate at a point during panel manufacture, insertion of the optics component within the panel substrate, and formation of the remainder of the panel substrate.

When the PIC 562 is implemented, the number of glass sheets (e.g., individual glass sheets 550-1, 550-2, and 550-3) may be informed by a thickness of the PIC 562. For example, for a PIC having a thickness in a range of 300 microns to 1 millimeter, the glass reinforcement layer 550 should equal the thickness of the PIC, therefore, an associated number of glass layers may be in a range of three to ten.

A non-limiting way to identify a PIC may include visually inspecting both the materials present in a cross-sectional view and the structure and shape of the materials to determine that a ring resonator structure has been implemented. Although, in various embodiments, the ring resonator structure may comprise the same materials as an electronic integrated circuit (e.g., a CMOS (complementary metal-oxide-semiconductor) component), the structure of the ring resonator structure, and its shape employ different doping profiles than a CMOS component. Various embodiments of the ring resonator structure may have a thickness (on a cross-sectional view) of about 220 nanometers.

As shown in FIG. 5, in various embodiments, an optional local interconnect component 534 may also be present in the glass reinforcement layer 550. The integration of local interconnect components (e.g., 534) and PICs (e.g., 562) into the glass reinforcement layer of a panel are independent of each other. That is, a panel can comprise one or more local interconnect components and/or one or more PICs.

The waveguide routing 564 may enable an embedded PIC 562 to communicate with a fiber array unit (FAU) connector located external to a panel. The FAU connector may be a top side connector, such as a grating coupler, or an edge connector, such as a micro-lens or V-groove. With reference back to FIG. 1, in various panel assembly 100 embodiments, an FAU may be implemented in a panel architecture, e.g., within panel 108 at location 124 (see, e.g., FIG. 9, FAU 910), or external to a panel, but within the panel assembly, e.g., at location 122. Any of the panels or panel assemblies here can have multiple PICs and multiple FAUs.

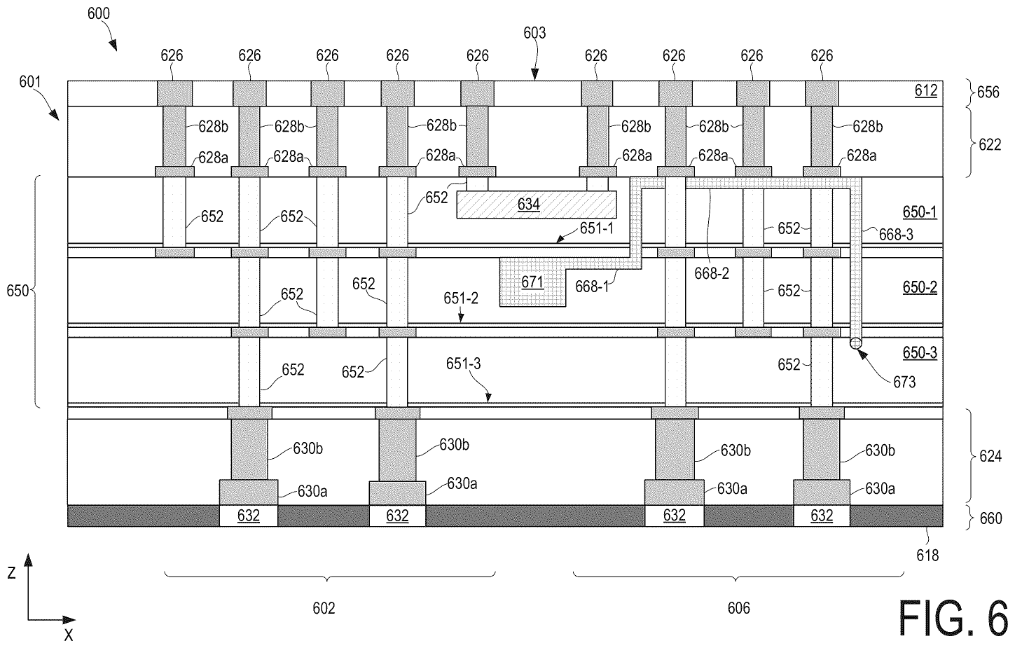

As illustrated in FIG. 6, embodiments of the panel architecture may employ cavities and/or micro-channels in the glass reinforcement layer. The simplified cross-sectional illustration of a portion 600 relates to cutout line A-A′ and includes a substrate 601. Micro-channels 668 can be added to the glass reinforcement layer 650 to assist in removing heat from the components of the panel. Micro-channels 668 are another example of an enclosed pathway formed in the glass reinforcement layer 650. Micro-channels 668 can comprise lateral portions 668-1 and 668-2 and a vertical portion 668-3. In some embodiments, micro-channel lateral portions are formed on the surface of a glass layer (or glass sheet) by, for example, etching or laser cutting, and micro-channel vertical portions are formed by, for example, drilling through a glass layer (or glass sheet). In some embodiments, micro-channel vertical portions can comprise a through-glass vias of an appropriate diameter to facilitate the flow of a liquid coolant. In other embodiments, lateral portions of the micro-channels 668 can be located in the interior of a glass layer. The micro-channel vertical portion 668-3 extends through more than one glass sheet (through 650-1 and 650-2 and into 650-3). In an embodiment, a micro-channel lateral portion (e.g., 668-2) can be located near a set of conductive contacts, where “near” means at a surface of a glass reinforcement layer located below the conductive contacts. One may appreciate that, although the illustration of FIG. 6 is in two dimensions, a three-dimensional characteristic of the design/configuration of the micro-channels 668 is indicated; for example, lateral portion 668-2 traverses in front of two TGVs 652 and behind one TGV 652.

Some embodiments have cavities added into the glass reinforcement layer 650 to act as a pool or a reservoir for a liquid coolant. A cavity, 671, when present, may reside in the glass reinforcement layer, and, similar to the micro-channels 668, the cavity 671 may be etched or laser cut into the surface of a glass sheet. In other embodiments, the cavity may be formed in the interior of the glass layer. In embodiments implementing a cavity 671 and micro-channels 668, the micro-channels 668 may be configured to use the flow of the liquid coolant in a cavity to extract heat from the glass reinforcement layer 650. Accordingly, the micro-channels 668 may have a diameter that is a function of a selected liquid coolant (e.g., water, alcohol, glycol), in that the diameter is selected to accommodate movement of the selected liquid coolant in the anticipated operating temperature of a die located near the micro-channels 668. The glass in the glass reinforcement layer 650 can provide a hermetic seal around the micro-channels 668 for the liquid coolant flowing closest to a respective die, enhancing cooling functionality for a die.

Substrate 601 illustrates an optional local interconnect component 634, implemented in the glass reinforcement layer 650, as described in connection with other embodiments. However, other embodiments of the substrate 601 and/or resulting panel do not necessarily comprise the optional local interconnect component 634. Said differently, a panel can comprise cavities 671 and/or micro-channels 668, without local interconnect components 634.

A panel can comprise one or more ports (e.g., at 673) to allow for connection to an external liquid-cooled thermal management solution to cool the panel, e.g., by controlling fluid flow into/out of micro-channels 668. In various embodiments, the liquid-cooled thermal management solution can comprise a heat exchanger to remove heat from heated liquid coolant exiting the panel, the liquid coolant having absorbed heat generated by the die on the panel, a pump to provide for the circulation of the coolant through the micro-channels, and conduits to connect the panel, heat exchanger, and pump. A liquid-cooled thermal management solution can cool multiple panels. Further, a liquid-cooled thermal management solution can be co-located in the same system as the panel cooled by the liquid-cooled thermal management solution or located external to the system in which the panel is located. For example, in a rack-scale solution, a liquid-cooling thermal management solution can cool panel components located in multiple systems located within a rack. Panels employing micro-channels and cavities may or may not have a large form factor thermal management solution attached to the top of the panel. That is, panels may provide for the removal of heat generated by dies within the panel by thermal management solutions located both below (cavities and/or micro-channels) and above (e.g., a thermal management solution such as a liquid-cooled, vapor chamber, heat fins) the dies.

In manufacturing, embodiments of the panel architecture can be populated and packaged using various techniques. In FIG. 7, embodiment 700 illustrates a solder resist or dielectric layer 712 having conductive pads 726 therein, to which solder balls 702 may be attached at a first or fine pitch, to have die or chiplets attached thereto. In embodiment 720, a solder resist or dielectric layer 712 is shown having pockets 706 etched therein, to which solder balls 708 are placed in advance of attaching a die or chiplet. Notably, the pockets 706 have a tapered wall, being wider at an upper opening and narrower where the pocket meets the conductive contacts. Similarly, the bottom surface of the panel architecture can have exposed second level interconnect (SLI) or conductive contacts 732 are arranged in a solder resist or dielectric layer 718 at a greater pitch than the pitch of the conductive contacts, or a BGA or land grid array (LGA) pitch. Solder balls 710 may be attached to the SLI or conductive contacts 732. The examples in FIG. 7 are non-limiting.

Moving to FIGS. 8-9, an example process flow for the panel architecture is provided. The illustrations in FIG. 8-9 relate to cutout B-B′, in that, chips (chiplets) 1-3 are part of a first panel (“panel 1” in FIG. 9, generally analogous to panel 106), and chips (chiplets) 4-5 are part of a second panel (“panel 2” in FIG. 9, generally analogous to panel 108). The process flow illustrated in FIGS. 8-9 can be used for the embodiments described above in connection with FIGS. 3, 5-6, and 21-25, accordingly, some intra-panel architecture features, such as local interconnect components, are indicated for chips 1-3 and separately for chips 4-5, although, to simplify the drawings, micro-channels and cavities are not depicted. The sequence of operations described in the process flow is non-limiting, operations may be performed in a different order, and operations may be added or subtracted without altering the final product. At a point in manufacturing and packaging, panel 1 and panel 2 will be singulated or cut (at 859) apart.

At 800, a glass carrier 806 is employed to build a plurality of panels thereon. The glass carrier 806 is used to provide a mechanically stiff surface for depositing the respective build-up layers or RDL and solder resist, performing etching, depositing copper or other conductive trace and pad materials, and building up the glass reinforcement layer 850, to achieve a panel substrate architecture as described herein. The glass carrier 806 can also provide a level of flatness that may not be achievable with other types of substrates, such as printed circuit boards comprising organic substrate materials. The flatness provided by a glass carrier can enable the formation of smaller feature sizes (e.g., via width/space, conductive contact width/space), thus enabling the formation of conductive contacts, vias, and other features with a fine pitch. The glass carrier 806 has an area that is at least the same size as the area of a single panel described herein and may be, for example, 510 mm×515 mm, or larger or smaller as required. The glass carrier 806 may be an alkali-free alkaline earth boro-aluminosicilate glass, such as a glass comprising aluminum, oxygen, boron, silicon, and an alkaline-earth metal (e.g., beryllium, magnesium, calcium, strontium, barium, radium), such as a glass comprising SiO₂, Al₂O₃, B₂O₃, and MgO, or a photosensitive glass. The glass carrier 806 may have a thickness in a range of 0.5 to 2 mm, +/1 10%.

On an upper surface 803 of the panel architecture (analogous with upper surface 203, 303, 503, and 603), conductive contacts 808 are arranged to attach respective chips or die at locations 802-1, 802-2, 802-3, 802-4, and 802-5. Conductive contacts 808 are arranged at a suitable pitch for the respective die to attach (e.g., “die pitch”), therefore, a pitch for conductive contacts at location 802-1 may be different from a pitch for conductive contacts 808 at location 802-2, and so on. In various embodiments, the conductive contacts 808 are attached at a fine pitch for a first level interconnect (FLI) with respective die.

Optional embedded structures, such as local interconnect components 804-1, 804-2, and 804-3 may be formed at this stage of packaging. Optional cavities 671 and micro-channels 668 may be etched at this stage. Additionally, optional waveguides may be etched, and photonics integrated circuits may be embedded at this stage (e.g., FIG. 9, PIC 906, waveguides 908). Although not depicted for clarity of illustrations, RDL interconnect structures may be implemented directly above local interconnect components.

At 835, respective integrated circuit dies, or chips may be attached to (i.e., assembled onto) the panel substrate, as illustrated. As described above, the chips (chip 1, chip 2, chip 3, chip 4, and chip 5) may implement different functionalities, have different heights, have different arrangements of pins (pinouts), have different lateral dimensions, and/or may take up different amounts of cross-sectional area within a panel. Different panels can the same or different numbers of chips. The assembly at 835 may be referred to as fine-pitch assembly is performed. At 835, any soldering technique or hybrid bonding technique may be employed. Various of the chips may be assembled onto the panel substrate using underfill 812; and although the underfill 812 is depicted as uniform, in practice, underfill for individual chips may be different (e.g., underfill under chip 1 may be different from underfill from chip 2, and so on). The embodiment at 835 may be referred to as a populated panel substrate.

At 855, the glass carrier 806 may be debonded or removed from the populated panel substrate, and the panel substrate may be cut into respective panels (e.g., the four panel quads described initially), as indicated by dashed line 859). At 855, solder balls 857 may be attached via a second level interconnect or conductive contacts 832 at the lower surface, and mechanical contact enabling, such as for LGA attaching, may be performed. Alternatively, solder balls 857 may be added before cutting the populated panel substrate into respective panels.

Depicted at 900, respective large form factor thermal solutions 960 and 962 may be added to the individual populated panel substrates (panel 1 and panel 2), and, in various embodiments, an underfill 964 and 966 can be added, respectively, under the large form factor thermal solutions 960 and 962. Co-packaged integrated circuit components, such as the FAU 910, may be added at 930.

Depending on the embodiment, an encapsulant 972 may be applied/overmolded over the panels, as is illustrated at 930 for panel 1. At 930, in a non-limiting example, the FAU 910 may be attached to PIC 906 via waveguide 908, becoming part of the panel 2. In other embodiments, co-packaged integrated circuit components may be located external to the panel, above the panel, or vertically stacked with the panel.

In some embodiments, at 930, a single packaged multi-die panel (e.g., panel 1) with the herein provided panel architecture is a complete HPC solution for an application. In other embodiments, multiple panels are assembled into a panel assembly, such as panel assembly 100 of FIG. 1. Embodiment 950 generally reflects cutout B-B′, illustrating panel 1 and panel 2 assembled onto a panel-level substrate 970. The panel-level substrate 970 can comprise one or more layers, with each layer comprising inorganic or organic dielectric materials (such as any of the dielectric materials disclosed or referenced herein), one or more conductive traces, and one or more vias. The substrate 970 can provide electrically conductive paths between panels. For example, substrate 970 comprises conductive traces 973 and vias 974 of two substrate layers providing conductive paths connection between conductive contacts 976 of panel 1 to conductive contacts 978 of panel 2. The resulting panel assembly at 950 may provide a complete HPC solution for an application, or the panel assembly from 950 may further be assembled with other components to provide a complete HPC solution.

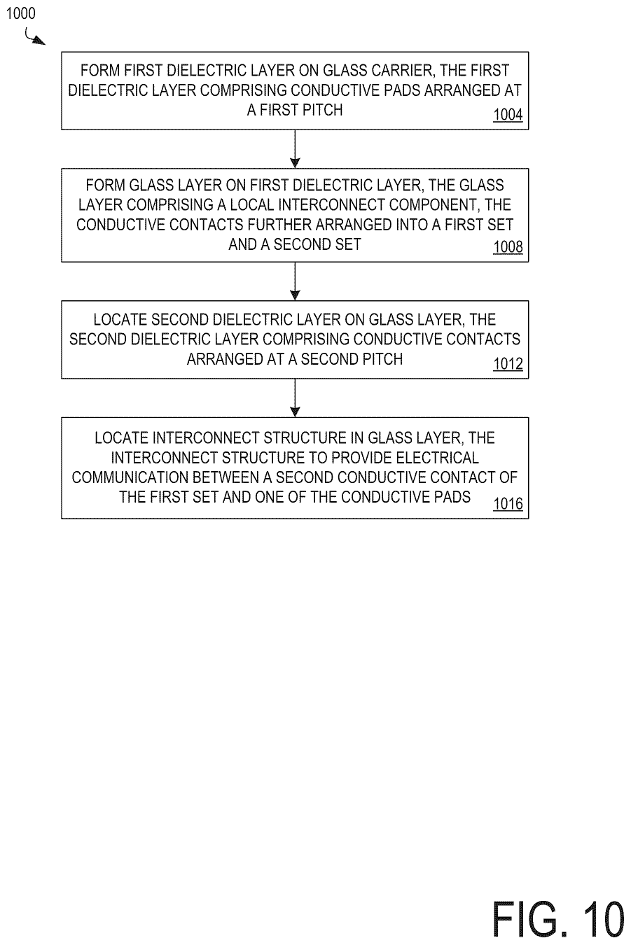

FIG. 10 is an example first method of forming a panel. At 1004 in a method 1000, a first dielectric layer is formed on a glass carrier, the glass carrier having a cross-sectional area of at least 250 millimeters×250 millimeters, the first dielectric layer comprising conductive pads arranged at a first pitch. At 1008, a glass layer is formed on the first dielectric layer, the glass layer comprising a local interconnect component. At 1012, a second dielectric layer is located on the glass layer, the second dielectric layer comprising conductive contacts arranged at a second pitch, the conductive contacts further arranged into a first set and a second set, the local interconnect component to provide electrical communication between a first conductive contact in the first set and a first conductive contact in the second set. At 106, an interconnect structure is located in the glass layer, the interconnect structure to provide electrical communication between a second conductive contact of the first set and one of the conductive pads.

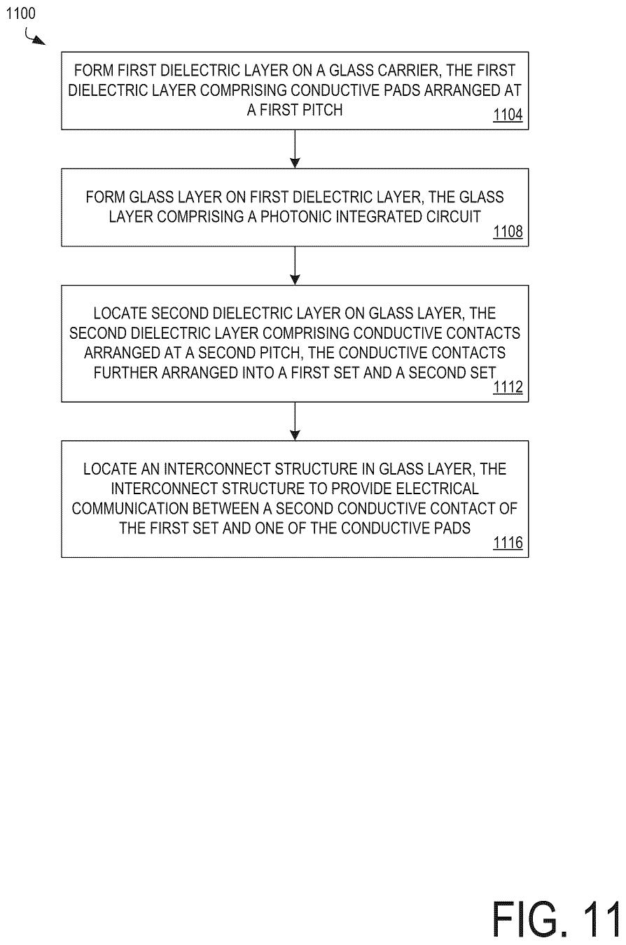

FIG. 11 is an example second method of forming a panel. At 1104 a first dielectric layer is formed on a glass carrier, the glass carrier having a cross-sectional area of at least 250 millimeters×250 millimeters, the first dielectric layer comprising conductive pads arranged at a first pitch. At 1108, a glass layer is formed on the first dielectric layer, the glass layer comprising a photonic integrated circuit (PIC). At 1112, a second dielectric layer is located on the glass layer, the second dielectric layer comprising conductive contacts arranged at a second pitch, the conductive contacts further arranged into a first set and a second set. The PIC is configured to be in electrical communication with a first conductive contact in the first set or the second set. At 1116, an interconnect structure is located in the glass layer, the interconnect structure to provide electrical communication between a second conductive contact of the first set and one of the conductive pads.

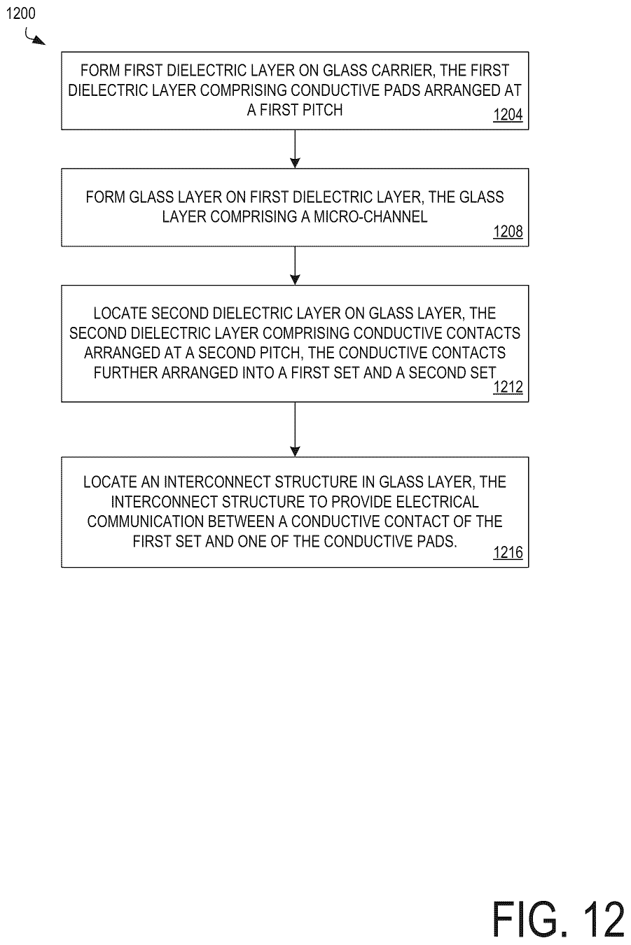

FIG. 12 is an example third method of forming a panel. At 1204, a first dielectric layer is formed on a glass carrier, the glass carrier having a cross-sectional area of at least 250 millimeters×250 millimeters, the first dielectric layer comprising conductive pads arranged at a first pitch. At 1208, a glass layer is formed on the first dielectric layer, the glass layer comprising a micro-channel. At 1212, a second dielectric layer is located on the glass layer, the second dielectric layer comprising conductive contacts arranged at a second pitch, the conductive contacts further arranged into a first set and a second set. The micro-channel is configured to have a portion near the first set. At 1216, an interconnect structure is located in the glass layer, the interconnect structure to provide electrical communication between a conductive contact of the first set and one of the conductive pads.

The sequence of elements in methods 1000, 1100, and 1200 are non-limiting. Operations of the methods may be performed in a different order and operations may be added or subtracted without altering the final product. For example, any of the methods 1000, 1100, and 1200 can further comprise attaching a first die to the first set; and attaching a second die to the second set, thereby creating a populated substrate. In a second example, any of the methods 1000, 1100, and 1200 can further comprise debonding the glass carrier from the populated substrate; and forming solder bumps on the conductive pads.

FIGS. 13-21 illustrate simplified cross-sectional views of various “core” panel embodiments in which the panel substrate comprises a glass core. The cross-sectional views relate to the cutout line A-A′ of FIG. 1. The dielectric layers are located on an upper surface of the glass core (between the integrated circuit dies and the glass core) or on upper and bottom surfaces of the glass core. The glass core provides similar functions (signal routing, mechanical stability during manufacture, flat surfaces upon which dielectric layers may be formed) and possesses similar properties (can be comprised of the same material, has a coefficient of expansion close to that of the integrated circuit dies attached to the panel) as the glass reinforcement layer of FIGS. 3, 5-6, but as the panel embodiments illustrated in FIG. 13-21 are not assembled on a glass carrier, the glass cores of FIGS. 13-21 can be thicker than the glass reinforcement layers of FIGS. 3, 5-6.

FIG. 13 is a simplified cross-sectional illustration of an example panel substrate portion comprising a glass core. The panel portion 1300 comprises a glass core 1351 positioned between a first set of dielectric layers (RDLs, build-up layers) 1322 (1322a, 1322b, 1322c, 1322d) and a second set of dielectric layers 1324 (1324a, 1324b). The first set of dielectric layers 1322 are stacked vertically and the second set of the dielectric layers 1324 are stacked vertically. That is, the individual first dielectric layers 1322 (e.g., 1322a) are positioned adjacent to another first dielectric layer 1322 (e.g., 1322b) and the individual second dielectric layers 1324 (e.g., 1324a) are positioned adjacent to another second dielectric layer 1324 (e.g., 1324b). The glass core 1351 comprises a layer of glass 1354, encapsulation layers 1370 and 1372, and through-glass vias (TGVs) 1352 located in the layer 1354. The glass core 1351 has a thickness 1380. The encapsulation layers 1370 and 1372 comprise dielectric layers 1374 in which TGV contacts 1376 are located.

An upper surface contact layer 1356 comprises a solder resist or other suitable dielectric material 1312 and conductive contacts 1326 arranged to correspond to the pinouts of chiplets to be attached to the panel portion 1300. The upper surface contact layer 1356 (and hence, the conductive contacts 1326) are located on a top dielectric layer (e.g., 1322a) of the first dielectric layers 1322. A set of conductive contacts 1326 are arranged at a fine pitch. A lower surface contact layer 1360 comprises a solder resist or other suitable dielectric material 1318 and conductive contacts 1332 are arranged to correspond to a desired panel-level pinout. The lower surface contact layer 1360 (and hence, the conductive contacts 1332) is located on a bottom dielectric layer (e.g., 1324b) of the second dielectric layers 1324. The set of the conductive contacts 1332 is arranged at a pitch that is greater than the fine pitch at which a set of the conductive contacts 1326 are arranged.

Dielectric layers 1322 comprise conductive traces 1328a and vias 1328b, and dielectric layers 1324 comprise conductive traces 1330a and vias 1330b. A local interconnect comprising vias 1328b and conductive traces 1328a included in region 1387 provides an electrically conductive path between a conductive contact 1326 belonging to a first set of conductive contacts 1364 to be attached to a first integrated circuit die and a conductive contact 1326 belonging to a second set of conductive contacts 1366 to be attached to a second integrated circuit die.

Vias 1328b and 1330b are shown as being tapered, with the narrower ends of the vias located closer to the glass core 1351 than the wider ends of the vias. These tapers reflect that dielectric layers 1322 and 1324 are built up from the glass core 1351 and that when individual dielectric layers 1322 and 1324 are etched to form via holes, they are etched toward the glass core 1351. Vias in the dielectric layers of the other panel embodiments comprising a glass core (e.g., vias 1428b, 1430b, 1528b, 1530b, 1628b, 1630b) are similarly tapered.

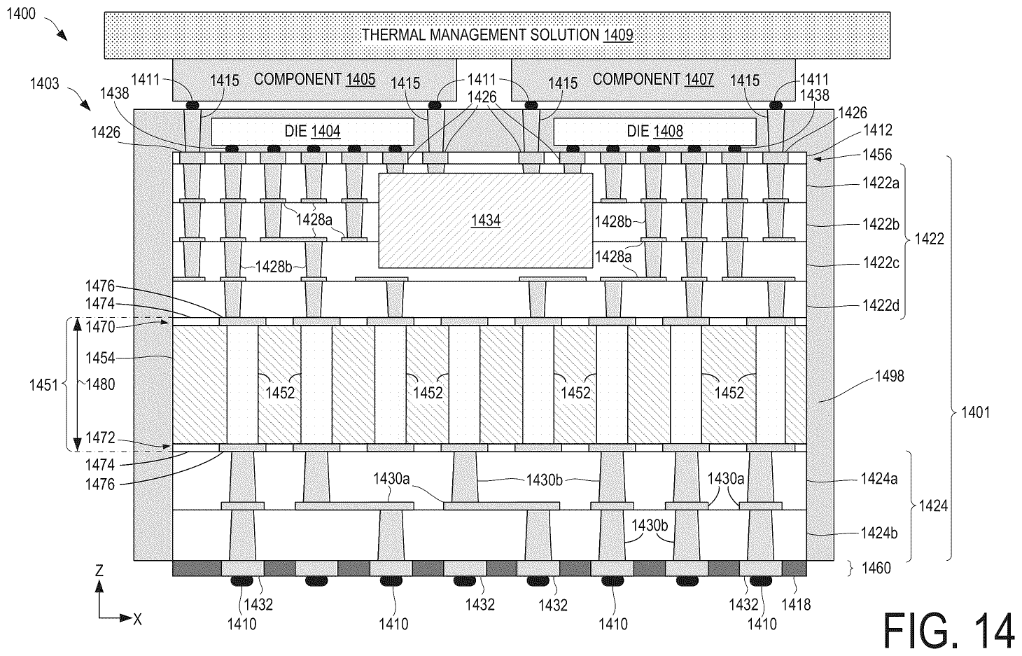

FIG. 14 is a simplified cross-sectional illustration of an example panel assembly comprising a panel comprising a glass core and a local interconnect component located in a set of dielectric layers of the panel. The panel assembly 1400 comprises a panel 1403, integrated circuit components 1405 and 1407 attached to the panel 1403, and a thermal management solution 1409. The panel 1403 comprises a glass core 1451 positioned between a first set of dielectric layers 1422 (1422a, 1422b, 1422c, 1422d) and a second set of dielectric layers 1424 (1424a, 1424b). The first set of dielectric layers 1422 and the second set of dielectric layers 1424 are stacked vertically. The glass core 1451 comprises a layer of glass 1454, encapsulation layers 1470 and 1472, and through-glass vias (TGVs) 1452 located in the glass layer 1454. The glass core 1451 has a thickness 1480. The encapsulation layers 1470 and 1472 comprise dielectric layers 1474 in which TGV contacts 1476 are located.

An upper surface contact layer 1456 comprises a solder resist or other suitable dielectric material 1412 and conductive contacts 1426 arranged to correspond to the pinouts of dies 1404 and 1408 directly attached to the panel 1403. The upper surface contact layer 1456 (and hence, the conductive contacts 1426) is located on a top dielectric layer (e.g., 1422a) of the first dielectric layers 1422. A set of the conductive contacts 1426 are arranged at a fine pitch. A lower surface contact layer 1460 comprises a solder resist or other suitable dielectric material 1418 and conductive contacts 1432 are arranged to correspond to a desired panel-level pinout. The lower surface contact layer 1460 (and hence, the conductive contacts 1432) is located on a bottom dielectric layer (e.g., 1424b) of the second dielectric layers 1424. The set of conductive contacts 1432 is arranged at a pitch that is greater than the fine pitch at which a set of the conductive contacts 1426 are arranged.

Dielectric layers 1422 comprise conductive traces 1428a and vias 1428b, and dielectric layers 1424 comprise conductive traces 1430a and vias 1430b. A local interconnect component 1434 provides electrically conductive paths between conductive contacts 1426 connected to the die 1404 and a first packaged integrated circuit component 1492 and conductive contacts 1426 connected to the die 1408 and a second packaged integrated circuit component 1407.

The integrated circuit dies 1404 and 1408 are attached to the panel substrate 1401 at conductive contacts 1426 via solder balls 1438. In other embodiments, the dies 1404 and 1408 can be attached to the panel substrate via other approaches, such as hybrid bonding. The panel 1403 further comprises solder balls 1410 attached to the panel substrate 1401 at conductive contacts 1432. In other embodiments, the panel 1403 does not comprise solder balls 1410 and the package can attach to other components, such as a printed circuit board, via conductive contacts 1432 that are pads. The packaged panel 1403 further comprises an encapsulant 1498 that enclosed the dies 1404 and 1408 and the panel substrate 1401.

The integrated circuit components 1405 and 1407 are attached to the panel 1403 via a package-on-package assembly technology in which solder balls 1411 of the integrated circuit components 1405 and 1407 are attached to the through-package vias 1415 extending through the encapsulant 1498 and attaching to conductive contacts 1426. Panel assembly 1400 illustrates just one example of how packages can be attached to a packaged panel. Integrated circuit components can be attached to a packaged panel via different approaches in other embodiments.

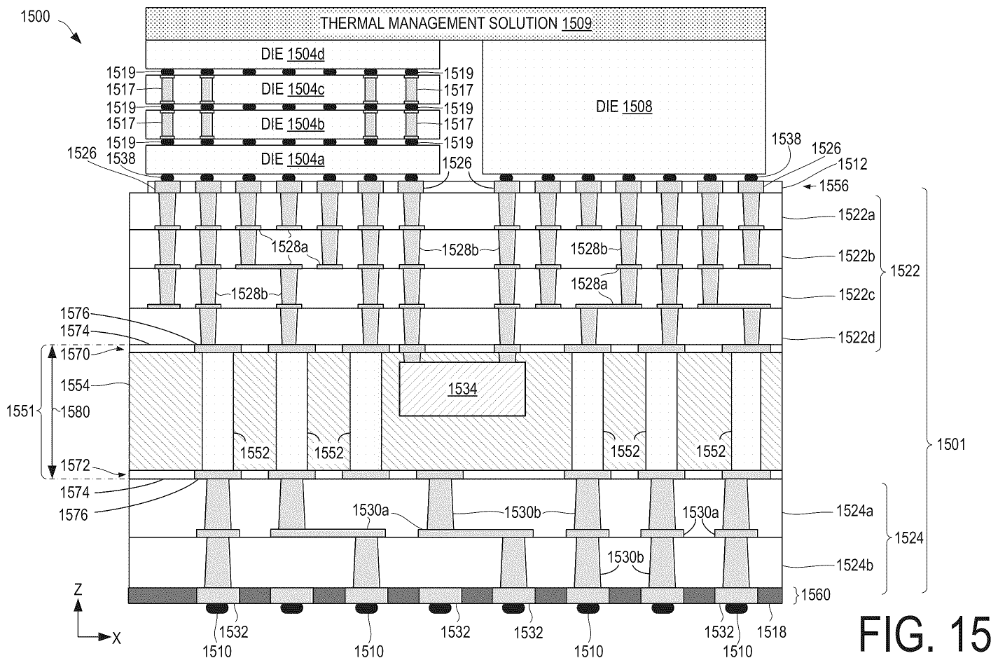

FIG. 15 is a simplified cross-sectional illustration of an example panel comprising a glass core with a local interconnect component located in the glass core. The panel 1500 comprises integrated circuit dies 1504a, 1504b, 1504c, 1504d, and 1508 attached to the panel either directly or indirectly, and a thermal management solution 1509. The panel 1500 comprises a glass core 1551 positioned between a first set of vertically stacked dielectric layers 1522 (1522a, 1522b, 1522c, 1522d) and a second set of vertically stacked dielectric layers 1524 (1524a, 1524b). The glass core 1551 comprises a layer of glass 1554, encapsulation layers 1570 and 1572, and through-glass vias (TGVs) 1552 located in the glass layer 1554. The glass core 1551 has a thickness 1580. The encapsulation layers 1570 and 1572 comprise dielectric layers 1574 in which TGV contacts 1576 are located.

An upper surface contact layer 1556 comprises a solder resist or other suitable dielectric material 1512 and conductive contacts 1526 arranged to correspond to the pinouts of dies 1504a and 1508 directly attached to the panel substrate 1501. The upper surface contact layer 1556 (and hence, the conductive contacts 1526) is located on a top dielectric layer (e.g., 1522a) of the first dielectric layers 1522. A set of the conductive contacts 1526 is arranged at a fine pitch. A lower surface contact layer 1560 comprises a solder resist or other suitable dielectric material 1518 and conductive contacts 1532 are arranged to correspond to a desired panel-level pinout. The lower surface contact layer 1560 (and hence, the conductive contacts 1532) is located on a bottom dielectric layer (e.g., 1524b) of the second dielectric layers 1524. The set of conductive contacts 1532 is arranged at a pitch that is greater than the fine pitch at which a set of the conductive contacts 1526 are arranged.

Dielectric layers 1522 comprise conductive traces 1528a and vias 1528b, and dielectric layers 1524 comprise conductive traces 1530a and vias 1530b. A local interconnect component 1534 located in the glass layer 1554 of the glass core 1551 provides an electrically conductive path between one of the conductive contacts 1526 connected to the die 1504a and one of the conductive contacts connected to the die 1508.

The integrated circuit dies 1504a and 1508 are attached to the panel substrate 1501 at conductive contacts 1526 via solder balls 1538. In other embodiments, the dies 1504a and 1508 can be attached to the panel substrate via other approaches, such as hybrid bonding. The panel 1500 further comprises solder balls 1510 attached to the panel substrate 1501 at conductive contacts 1532. In other embodiments, the panel 1500 does not comprise solder balls 1510 and the panel can attach to other components, such as a printed circuit board, via conductive contacts 1532 that are pads.

The integrated circuit dies 1504a, 1504b, 1504c, and 1504d are stacked vertically and connected by solder bumps (or microbumps) 1519 that connect to through-silicon vias (TSVs) 1517 that extend through dies 1504c and 1504d. TSVs can comprise copper, carbon nanotubes, graphene nanotubes, or another suitable material. The stacked die 1504a-d can implement various functionality, and in one embodiment, die 1504a can be a high bandwidth memory (HBM) controller die that controls HBM dies 1504b-d. In other embodiments, die 1504a can comprise TSVs 1517 that connect to conductive contacts 1526. Panel 1500 illustrates one example of how a panel can accommodate vertically stacked integrated circuit dies. Integrated circuit components can be attached panel via different approaches in other embodiments.

FIG. 16 is a simplified cross-sectional illustration of an example panel comprising a glass core and photonic integrated circuits. The panel 1600 comprises integrated circuit dies 1604 and 1608, a glass core 1651 positioned between a first set of vertically stacked dielectric layers 1622 (1622a, 1622b, 1622c, 1622d), a second set of vertically stacked dielectric layers 1624 (1624a, 1624b), photonics integrated chips 1622a and 1622b, and a thermal management solution 1609. The glass core 1651 comprises a layer of glass 1654, encapsulation layers 1670 and 1673, and through-glass vias (TGVs) 1652 located in the glass layer 1654. The glass core 1651 has a thickness 1680. The encapsulation layers 1670 and 1672 comprise dielectric layers 1674 in which TGV contacts 1676 are located.

An upper surface contact layer 1656 comprises a solder resist or other suitable dielectric material 1612 and conductive contacts 1626 arranged to correspond to the pinouts of dies 1604 and 1608 directly attached to the panel 1600. The upper surface contact layer 1656 (and hence, the conductive contacts 1626) is located on a top dielectric layer (e.g., 1622a) of the first dielectric layers 1622. A set of the conductive contacts 1626 is arranged at a fine pitch. A lower surface contact layer 1660 comprises a solder resist or other suitable dielectric material 1618 and conductive contacts 1632 are arranged to correspond to a desired panel-level pinout. The lower surface contact layer 1660 (and hence, the conductive contacts 1632) is located on a bottom dielectric layer (e.g., 1624b) of the second dielectric layers 1624. The set of conductive contacts 1632 are arranged at a pitch that is greater than the fine pitch at which a set of the conductive contacts 1626 are arranged.

Dielectric layers 1622 comprise conductive traces 1628a and vias 1628b, and dielectric layers 1624 comprise conductive traces 1630a and vias 1630b. A local interconnect comprising vias 1628b and conductive traces 1628a included in region 1687 provides an electrically conductive path between a conductive contact 1626 attached to die 1604 and a conductive contact 1626 attached to die 1608.

The integrated circuit dies 1604 and 1608 are attached to conductive contacts 1626 via solder balls 1638. In other embodiments, the dies 1604 and 1608 can be attached to the conductive contacts 1626 via other approaches, such as hybrid bonding. The panel 1600 further comprises solder balls 1610 attached to conductive contacts 1632. In other embodiments, the panel 1600 does not comprise solder balls 1610 and the package can attach to other components, such as a printed circuit board, via conductive contacts 1632 that are pads.

The panel 1600 comprises photonic integrated circuits (PICs) 1662a and 1662b. The PICs 1662a and 1662b are located on the glass layer 1654. PIC 1662a and 1662b are attached to conductive contacts 1626 associated with dies 1604 and 1608, respectively. The PICs are integrated into the panel 1600 during panel manufacture and are thus considered to be part of the panel 1600. Waveguides 1664a and 1664b are located in the glass layer 1654 and are also fabricated during panel manufacture and are thus also considered to be part of the panel 1600. Fiber array units 1621a and 1621b are attached to the panel 1600 with waveguide 1664a providing a path for optical communication for optical signals to be generated or received by the PIC 1662a or the FAU 1621a and waveguide 1664b providing a path for optical communication for optical signals to be generated or received by the PIC 1662b or the FAU 1621b.

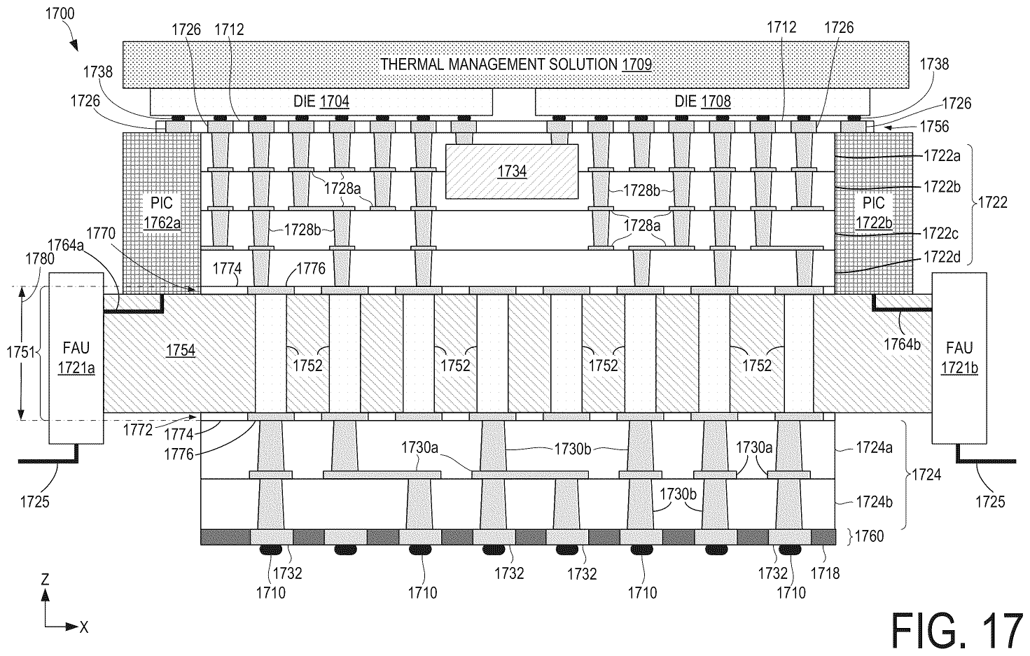

FIG. 17 is a simplified cross-sectional illustration of an example panel comprising a glass core, photonic integrated circuits, and local interconnect component. The panel 1700 comprises integrated circuit dies 1704 and 1708, a glass core 1751 positioned between a first set of vertically stacked dielectric layers 1722 (1722a, 1722b, 1722c, 1722d), a second set of vertically stacked dielectric layers 1724 (1724a, 1724b), and a thermal management solution 1709. The glass core 1751 comprises a layer of glass 1754, encapsulation layers 1770 and 1772, and through-glass vias (TGVs) 1752 located in the glass layer 1754. The glass core 1751 has a thickness 1780.

An upper surface contact layer 1756 comprises a solder resist or other suitable dielectric material 1712 and conductive contacts 1726 arranged to correspond to the pinouts of dies 1704 and 1708 directly attached to the panel 1700. The upper surface contact layer 1756 (and hence, the conductive contacts 1726) is located on a top dielectric layer (e.g., 1722a) of the first dielectric layers 1722. A set of the conductive contacts 1726 are arranged at a fine pitch. A lower surface contact layer 1760 comprises a solder resist or other suitable dielectric material 1718 and conductive contacts 1732 are arranged to correspond to a desired panel-level pinout. The lower surface contact layer 1760 (and hence, the conductive contacts 1732) are located on a bottom dielectric layer (e.g., 1724b) of the second dielectric layers 1724. The set of conductive contacts 1732 is arranged at a pitch that is greater than the fine pitch at which a set of the conductive contacts 1726 are arranged.

Dielectric layers 1722 comprise conductive traces 1728a and vias 1728b, and dielectric layers 1724 comprise conductive traces 1730a and vias 1730b. A local interconnect component 1734 provides an electrically conductive path between a conductive contact 1726 attached to the die 1704 and a conductive contact attached to the die 1708.

The integrated circuit dies 1704 and 1708 are attached to conductive contacts 1726 via solder balls 1738. In other embodiments, the dies 1704 and 1708 can be attached to the conductive contacts 1726 via other approaches, such as hybrid bonding. The panel 1700 further comprises solder balls 1710 attached to conductive contacts 1732. In other embodiments, the panel 1700 does not comprise solder balls 1710 and the package can attach to other components, such as a printed circuit board, via conductive contacts 1732 that are pads.

The panel 1700 comprises photonic integrated circuits (PICs) 1762a and 1762b. The PICs 1762a and 1762b are located on the glass layer 1754. PIC 1762a and 1762b are attached to conductive contacts 1726 associated with dies 1704 and 1708, respectively. The PICs 1762a and 1762b are integrated into the panel 1700 during panel manufacture and are thus considered to be part of the panel 1700. Waveguides 1764a and 1764b are located in the glass layer 1754 and are also fabricated during panel manufacture and are thus also considered to be part of the panel 1700. Fiber array units 1721a and 1721b are attached to the panel 1700 with waveguide 1764a providing a path for optical communication for optical signals to be generated or received by the PIC 1762a or the FAU 1721a and waveguide 1764b providing a path for optical communication for optical signals to be generated or received by the PIC 1762b or the FAU 1721b.

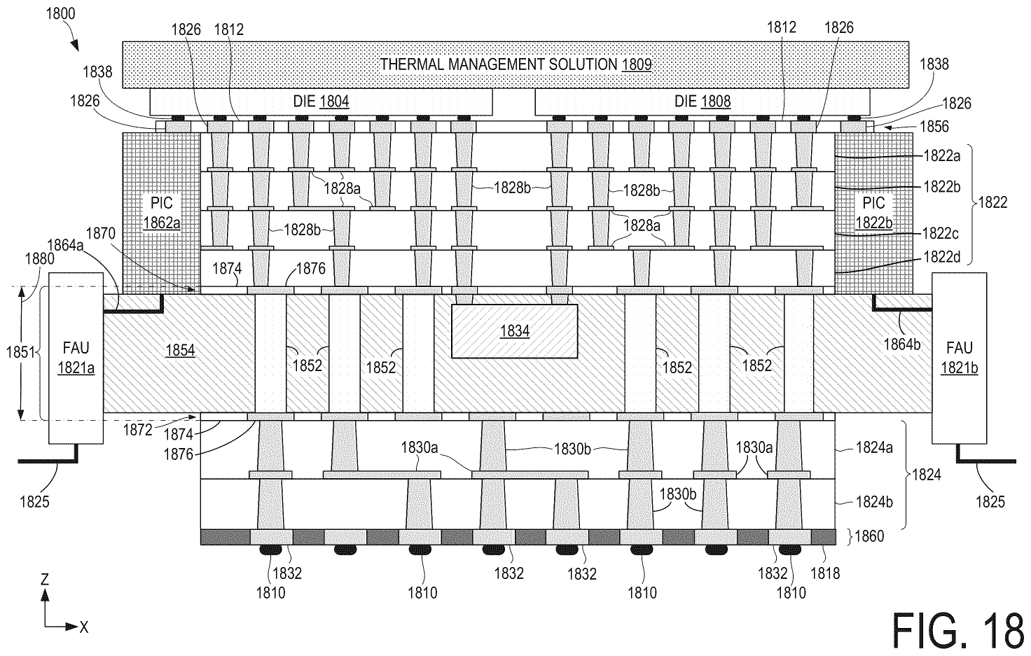

FIG. 18 is a simplified cross-sectional illustration of an example panel comprising a glass core, photonic integrated circuits, and local interconnect component located in the glass core. The panel 1800 comprises integrated circuit dies 1804 and 1808, a glass core 1851 positioned between a first set of vertically stacked dielectric layers 1822 (1822a, 1822b, 1822c, 1822d), a second set of vertically stacked dielectric layers 1824 (1824a, 1824b), and a thermal management solution 1809. The glass core 1851 comprises a layer of glass 1854, encapsulation layers 1870 and 1872, and through-glass vias (TGVs) 1852 located in the glass layer 1854. The glass core 1851 has a thickness 1880.

An upper surface contact layer 1856 comprises a solder resist or other suitable dielectric material 1812 and conductive contacts 1826 arranged to correspond to the pinouts of dies 1804 and 1808 directly attached to the panel 1800. The upper surface contact layer 1856 (and hence, the conductive contacts 1826) is located on a top dielectric layer (e.g., 1822a) of the first dielectric layers 1822. A set of the conductive contacts 1826 are arranged at a fine pitch. A lower surface contact layer 1860 comprises a solder resist or other suitable dielectric material 1818 and conductive contacts 1832 are arranged to correspond to a desired panel-level pinout. The lower surface contact layer 1860 (and hence, the conductive contacts 1832) are located on a bottom dielectric layer (e.g., 1824b) of the second dielectric layers 1824. The set of conductive contacts 1832 is arranged at a pitch that is greater than the fine pitch at which a set of the conductive contacts 1826 are arranged.

Dielectric layers 1822 comprise conductive traces 1828a and vias 1828b, and dielectric layers 1824 comprise conductive traces 1830a and vias 1830b. A local interconnect component 1834 located in the glass core 1851 provides an electrically conductive path between a conductive contact 1826 connected to the die 1804 and a conductive contact connected to the die 1808.

The integrated circuit dies 1804 and 1808 are attached to conductive contacts 1826 via solder balls 1838. In other embodiments, the dies 1804 and 1808 can be attached to the conductive contacts 1826 via other approaches, such as hybrid bonding. The panel 1800 further comprises solder balls 1810 attached to conductive contacts 1832. In other embodiments, the panel 1800 does not comprise solder balls 1810 and the package can attach to other components, such as a printed circuit board, via conductive contacts 1832 that are pads.

The panel 1800 comprises photonic integrated circuits (PICs) 1862a and 1862b. The PICs 1862a and 1862b are located on the glass layer 1854. PIC 1862a and 1862b are attached to conductive contacts 1826 associated with dies 1804 and 1808, respectively. The PICs are integrated into the panel 1800 during panel manufacture and are thus considered to be part of the panel 1800. Waveguides 1864a and 1864b are located in the glass layer 1854 and are also fabricated during panel manufacture and are thus also considered to be part of the panel 1800. Fiber array units 1821a and 1821b are attached to the panel 1800 with waveguide 1864a providing a path for optical communication for optical signals to be generated or received by the PIC 1862a or the FAU 1821a and waveguide 1864b providing a path for optical communication for optical signals to be generated or received by the PIC 1862b or the FAU 1821b.

FIG. 19 is a simplified cross-sectional illustration of an example panel comprising a glass core with micro-channels and photonic integrated circuits. The panel portion 1900 comprises a glass core 1951 positioned between a first set of dielectric layers (RDLs, build-up layers) 1922 (1922a, 1922b, 1922c, 1922d) and a second set of dielectric layers 1924 (1924a, 1924b). The first set of dielectric layers 1922 are stacked vertically and the second set of the dielectric layers 1924 are stacked vertically. The glass core 1951 comprises a layer of glass 1954, encapsulation layers 1970 and 1972, and through-glass vias (TGVs) 1952 located in the layer 1954. The glass core 1951 has a thickness 1980. The encapsulation layers 1970 and 1972 comprise dielectric layers 1974 in which TGV contacts 1976 are located.

An upper surface contact layer 1956 comprises a solder resist or other suitable dielectric material 1912 and conductive contacts 1926 arranged to correspond to the pinouts of dies 1904 and 1908 directly attached to the conductive contacts 1926. The upper surface contact layer 1956 (and hence, the conductive contacts 1926) is located on a top dielectric layer (e.g., 1922a) of the first dielectric layers 1922. A set of conductive contacts 1926 is arranged at a fine pitch. A lower surface contact layer 1960 comprises a solder resist or other suitable dielectric material 1918 and conductive contacts 1932 are arranged to correspond to a desired panel-level pinout. The lower surface contact layer 1960 (and hence, the conductive contacts 1932) is located on a bottom dielectric layer (e.g., 1924b) of the second dielectric layers 1924. The set of the conductive contacts 1932 is arranged at a pitch that is greater than the fine pitch at which a set of the conductive contacts 1926 are arranged.

Dielectric layers 1922 comprise conductive traces 1928a and vias 1928b, and dielectric layers 1924 comprise conductive traces 1930a and vias 1930b. A local interconnect comprising vias 1928b and conductive traces 1928a included in region 1987 provides an electrically conductive path between a conductive contact 1926 attached to the die 1904 and a conductive contact 1926 attached to the die 1908.

The integrated circuit dies 1904 and 1908 are attached to conductive contacts 1926 via solder balls 1938. In other embodiments, the dies 1904 and 1908 can be attached to the conductive contacts 1926 via other approaches, such as hybrid bonding. The panel 1900 further comprises solder balls 1910 attached to conductive contacts 1932. In other embodiments, the panel 1900 does not comprise solder balls 1910 and the package can attach to other components, such as a printed circuit board, via conductive contacts 1932 that are pads.

The panel 1900 comprises photonic integrated circuits (PICs) 1962a and 1962b. The PICs 1962a and 1962b are located on the glass layer 1954. PIC 1962a and 1962b are attached to conductive contacts 1926 associated with dies 1904 and 1908, respectively. The PICs are integrated into the panel 1900 during panel manufacture and are thus considered to be part of the panel 1900. Waveguides 1964a and 1964b are located in the glass layer 1954 and are also fabricated during panel manufacture and are thus also considered to be part of the panel 1900. Fiber array units 1921a and 1921b are attached to the panel 1900 with waveguide 1964a providing a path for optical communication for optical signals to be generated or received by the PIC 1962a or the FAU 1921a and waveguide 1964b providing a path for optical communication for optical signals to be generated or received by the PIC 1962b or the FAU 1921b.

As illustrated in FIG. 19, in some embodiments, a panel may comprise cavities and/or micro-channels in a glass core. Generally, the inclusion of micro-channels in the glass core of a panel assists in removing heat generated by integrated circuit dies attached to the panel or any heat-generating components located in the panel (such as active components located in a local interconnect component). Micro-channel 1968 is located in the glass layer 1954 and can be formed on the surface of the glass layer 1954 by, for example, etching or laser cutting. In other embodiments, the micro-channel 1968 can be located in the interior of the glass layer 1954. One may appreciate that, although the illustration of FIG. 19 is in two dimensions, a three-dimensional characteristic of the design/configuration of the micro-channel 1968 is indicated by the micro-channel 1968 being illustrated as traversing in front of several TGVs 1952 and behind other TGVs 1952.

Some panel embodiments with micro-channels can further comprise cavities in the glass core to act as a pool or a reservoir for a liquid coolant. The micro-channels may be configured to use the flow of the liquid coolant in a cavity to extract heat from a glass core. In the panel 1900, the glass core 1951 comprises a cavity 1971. The cavity 1971 may be etched or laser cut into the surface of the glass layer 1954. In other embodiments, the cavity may be formed in the interior of the glass layer. A port 1973 provides for connection to an external liquid-cooled thermal management solution to cool the panel 1900, e.g., by controlling fluid flow into/out of micro-channels 1968.

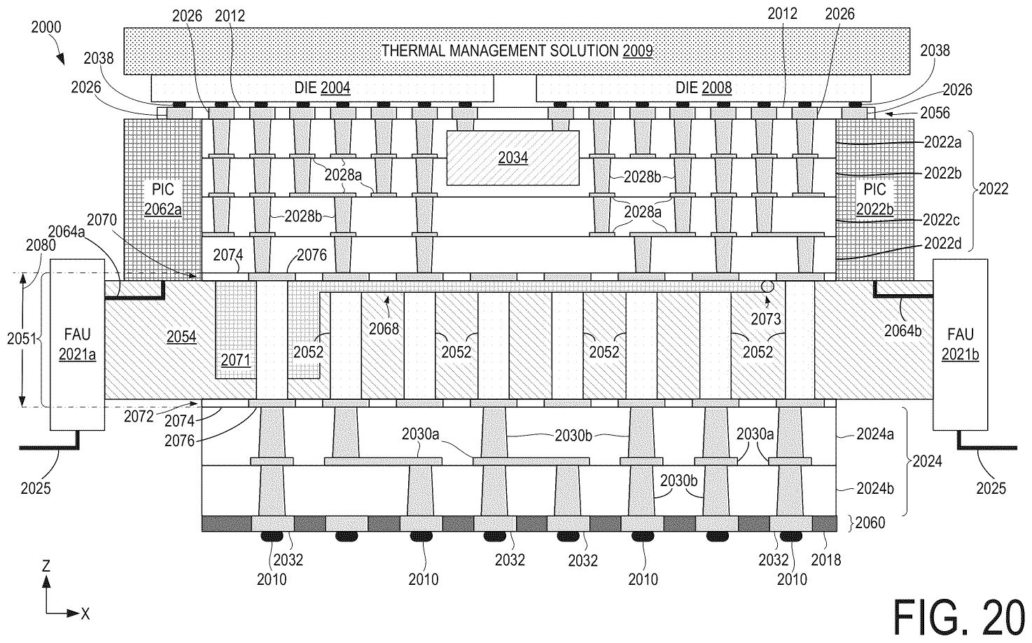

FIG. 20 is a simplified cross-sectional illustration of an example panel comprising a glass core with micro-channels, photonic integrated circuits, and a local interconnect component located in the dielectric layers. The panel 2000 comprises integrated circuit dies 2004 and 2008, a glass core 2051 positioned between a first set of vertically stacked dielectric layers 2022 (2022a, 2022b, 2022c, 2022d), a second set of vertically stacked dielectric layers 2024 (2024a, 2024b), and a thermal management solution 2009. The glass core 2051 comprises a layer of glass 2054, encapsulation layers 2070 and 2072, and through-glass vias (TGVs) 2052 located in the glass layer 2054. The glass core 2051 has a thickness 2080.

An upper surface contact layer 2056 comprises a solder resist or other suitable dielectric material 2012 and conductive contacts 2026 arranged to correspond to the pinouts of dies 2004 and 2008 directly attached to the panel 2000. The upper surface contact layer 2056 (and hence, the conductive contacts 2026) is located on a top dielectric layer (e.g., 2022a) of the first dielectric layers 2022. A set of the conductive contacts 2026 v arranged at a fine pitch. A lower surface contact layer 2060 comprises a solder resist or other suitable dielectric material 2018 and conductive contacts 2032 are arranged to correspond to a desired panel-level pinout. The lower surface contact layer 2060 (and hence, the conductive contacts 2032) is located on a bottom dielectric layer (e.g., 2024b) of the second dielectric layers 2024. The set of conductive contacts 2032 is arranged at a pitch that is greater than the fine pitch at which a set of the conductive contacts 2026 are arranged.

Dielectric layers 2022 comprise conductive traces 2028a and vias 2028b, and dielectric layers 2024 comprise conductive traces 2030a and vias 2030b. A local interconnect component 2034 provides an electrically conductive path between a conductive contact 2026 attached to the die 2004 and a conductive contact attached to the die 2008.

The integrated circuit dies 2004 and 2008 are attached to conductive contacts 2026 via solder balls 2038. In other embodiments, the dies 2004 and 2008 can be attached to the conductive contacts 2026 via other approaches, such as hybrid bonding. The panel 2000 further comprises solder balls 2010 attached to conductive contacts 2032. In other embodiments, the panel 2000 does not comprise solder balls 2010 and the package can attach to other components, such as a printed circuit board, via conductive contacts 2032 that are pads.

The panel 2000 comprises photonic integrated circuits (PICs) 2022a and 2022b. The PICs 2022a and 2022b are located on the glass layer 2054. PIC 2062a and 2062b are attached to conductive contacts 2026 associated with dies 2004 and 2008, respectively. The PICs 2062a and 2062b are integrated into the panel 2000 during panel manufacture and are thus considered to be part of the panel 2000. Waveguides 2064a and 2064b are located in the glass layer 2054 and are also fabricated during panel manufacture and are thus also considered to be part of the panel 2000. Fiber array units 2021a and 2021b are attached to the panel 2000 with waveguide 2064a providing a path for optical communication for optical signals to be generated or received by the PIC 2062a or the FAU 2021a and waveguide 2064b providing a path for optical communication for optical signals to be generated or received by the PIC 2062b or the FAU 2021b.

The glass core 2051 comprises a micro-channel 2068 located in the glass layer 2054. The micro-channel 2068 can be formed on the surface of the glass layer 2054 by, for example, etching or laser cutting. In other embodiments, the micro-channel 2068 can be located in the interior of the glass layer 2054. One may appreciate that, although the illustration of FIG. 20 is in two dimensions, a three-dimensional characteristic of the design/configuration of the micro-channel 2068 is indicated by the micro-channel 2068 being illustrated as traversing in front of several TGVs 2052 and behind other TGVs 2052.

The glass core 2051 further comprises a cavity 2071 that is connected to the micro-channel 2068. The cavity 2071 may be etched or laser cut into the surface of the glass layer 2054. In other embodiments, the cavity may be formed in the interior of the glass layer. A port 2073 provides for connection to an external liquid-cooled thermal management solution to cool the panel 2000, e.g., by controlling fluid flow into/out of micro-channels 2068.

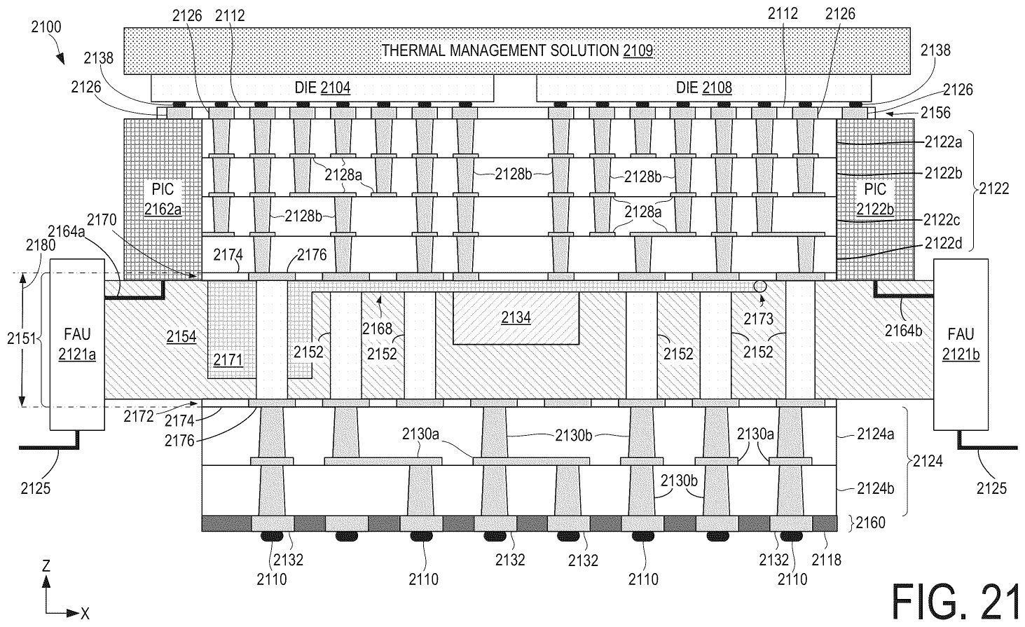

FIG. 21 is a simplified cross-sectional illustration of an example panel comprising a glass core with micro-channels, photonic integrated circuits, and a local interconnect component located in the glass core. The panel 2100 comprises integrated circuit dies 2104 and 2108, a glass core 2151 positioned between a first set of vertically stacked dielectric layers 2122 (2122a, 2122b, 2122c, 2122d), a second set of vertically stacked dielectric layers 2124 (2124a, 2124b), and a thermal management solution 2109. The glass core 2151 comprises a layer of glass 2154, encapsulation layers 2170 and 2172, and through-glass vias (TGVs) 2152 located in the glass layer 2154. The glass core 2151 has a thickness 2180.

An upper surface contact layer 2156 comprises a solder resist or other suitable dielectric material 2112 and conductive contacts 2126 arranged to correspond to the pinouts of dies 2104 and 2108 directly attached to the panel 2100. The upper surface contact layer 2156 (and hence, the conductive contacts 2126) is located on a top dielectric layer (e.g., 2122a) of the first dielectric layers 2122. A set of the conductive contacts 2126 are arranged at a fine pitch. A lower surface contact layer 2160 comprises a solder resist or other suitable dielectric material 2118 and conductive contacts 2132 are arranged to correspond to a desired panel-level pinout. The lower surface contact layer 2160 (and hence, the conductive contacts 2132) is located on a bottom dielectric layer (e.g., 2124b) of the second dielectric layers 2124. The set of conductive contacts 2132 is arranged at a pitch that is greater than the fine pitch at which a set of the conductive contacts 2126 are arranged.

Dielectric layers 2122 comprise conductive traces 2128a and vias 2128b, and dielectric layers 2124 comprise conductive traces 2130a and vias 2130b. A local interconnect component 2134 located in the glass core 2151 provides an electrically conductive path between a conductive contact 2126 connected to the die 2104 and a conductive contact connected to the die 2108.

The integrated circuit dies 2104 and 2108 are attached to conductive contacts 2126 via solder balls 2138. In other embodiments, the dies 2104 and 2108 can be attached to the conductive contacts 2126 via other approaches, such as hybrid bonding. The panel 2100 further comprises solder balls 2110 attached to conductive contacts 2132. In other embodiments, the panel 2100 does not comprise solder balls 2110 and the package can attach to other components, such as a printed circuit board, via conductive contacts 2132 that are pads.

The panel 2100 comprises photonic integrated circuits (PICs) 2162a and 2162b. The PICs 2162a and 2162b are located on the glass layer 2154. PIC 2162a and 2162b are attached to conductive contacts 2126 associated with dies 2104 and 2108, respectively. The PICs are integrated into the panel 2100 during panel manufacture and are thus considered to be part of the panel 2100. Waveguides 2164a and 2164b are located in the glass layer 2154 and are also fabricated during panel manufacture and are thus also considered to be part of the panel 2100. Fiber array units 2121a and 2121b are attached to the panel 2100 with waveguide 2164a providing a path for optical communication between the PIC 2162a and the FAU 2121a and waveguide 2164b providing a path for optical communication between the PIC 2162b and the FAU 2121b.

The panel 2100 comprises photonic integrated circuits (PICs) 2122a and 2122b. The PICs 2122a and 2122b are located on the glass core 2151. PIC 2162a and 2162b are attached to conductive contacts 2126 associated with dies 2104 and 2108, respectively. The PICs are integrated into the panel 2100 during panel manufacture and are thus considered to be part of the panel 2100. Waveguides 2164a and 2164b are located in the glass layer 2154 and are also fabricated during panel manufacture and are thus considered to be part of the panel 2100. Fiber array units 2121a and 2121b are attached to the panel 2100 with waveguide 2164a providing a path for optical communication for optical signals to be generated or received by the PIC 2162a or the FAU 2121a and waveguide 2164b providing a path for optical communication for optical signals to be generated or received by the PIC 2162b or the FAU 2121b.

The glass core 2151 comprises a micro-channel 2168 located in the glass layer 2154. The micro-channel 2168 can be formed on the surface of the glass layer 2154 by, for example, etching or laser cutting. In other embodiments, the micro-channel 2168 can be located in the interior of the glass layer 2154. One may appreciate that, although the illustration of FIG. 21 is in two dimensions, a three-dimensional characteristic of the design/configuration of the micro-channel 2168 is indicated by the micro-channel 2168 being illustrated as traversing in front of several TGVs 2152 and behind other TGVs 2152.

The glass core 2151 further comprises a cavity 2171 that is connected to the micro-channel 2168. The cavity 2171 may be etched or laser cut into the surface of the glass layer 2154. In other embodiments, the cavity may be formed in the interior of the glass layer. A port 2173 provides for connection to an external liquid-cooled thermal management solution to cool the panel 2100, e.g., by controlling fluid flow into/out of micro-channels 2168.

The “core” panels and panel assemblies illustrated in FIGS. 13-21 in which integrated circuit dies are attached to a panel substrate or a panel are merely illustrative. As discussed above, more integrated circuit dies can be attached to or incorporated in a panel or panel assembly than illustrated in FIGS. 13-21, and a die attached to a panel can have a lateral dimension, area, height, shape, and/or implement a functionality that is different than that of another die attached to or incorporated in the panel.

The glass core of the embodiments illustrated in FIGS. 13-21 (e.g., glass core 1351, 1451, 1551) can comprise any glass described or referenced herein or comprise the materials that any of the glasses described or referenced herein layers (e.g., glass reinforcement layers of FIGS. 3, 5-6) can comprise. The dielectric layers of the encapsulation layers in the glass core in the embodiments illustrated in FIGS. 13-21 (e.g., dielectric layers 1374, 1474, 1574) can comprise any dielectric material described or referenced herein. The TGVs in the glass core in the embodiments illustrated in FIGS. 13-21 (e.g., TGVs 1352, 1452, 1552) can comprise copper or any other suitable metal. In alternative embodiments, a glass core may not comprise TGV contacts (e.g., 1376, 1476, 1576) and vias in dielectric layers located on either side of the glass core (e.g., vias 1328b, 1330b, 1428b, 1430b, 1528b, 1530b) can attach directly to TGVs.

The upper surface contact layers illustrated in FIGS. 13-21 (e.g., 1326, 1426, 1526) can take the form of other upper surface contact layer embodiments, such as those described in connection with FIG. 7 (e.g., 726a, 726b). The lower surface contact layers illustrated in FIGS. 13-21 (e.g., 1360, 1460, 1560) can take the form of other lower surface contact layer embodiments, such as those described in connection with FIG. 7 (e.g., lower surface contact layer embodiment 760).

The thermal management solutions illustrated in FIGS. 14-21 (e.g., 1409, 1509, 1609) can comprise any cooling component described or referenced herein and be attached to integrated circuit components or integrated circuit dies via thermal interface materials.

The fiber array units illustrated in FIGS. 16-21 (e.g., 1621a, 1621b, 1721a, 1721b, 1821a, 1821b) can be attached to a panel during panel manufacture and can be part of an end panel product or be attached to a panel after panel manufacture. Any of the FAUs described or referenced herein can comprise fibers (e.g., 1625, 1725, 1825) that are part of an optical connection between panels in a system or between panels across different systems.

The micro-channels illustrated in FIGS. 19-21 (e.g., micro-channels 1968, 2068, 2168) in a glass core layer, the micro-channels can have a diameter that is a function of a selected liquid coolant (e.g., water, alcohol, glycol), in that the diameter is selected to accommodate movement of the selected liquid coolant in the anticipated operating temperature of a die located near the micro-channels. A glass core can provide a hermetic seal around micro-channels for the liquid coolant flowing closest to a respective die, enhancing cooling functionality for a die. Micro-channel ports (e.g., 1973, 2073, 2173) allow for connection of micro-channels to an external liquid-cooled thermal management solution to cool the panel, e.g., by controlling fluid flow into/out of micro-channels. In various embodiments, the liquid-cooled thermal management solution can comprise a heat exchanger to remove heat from heated liquid coolant exiting the panel, the liquid coolant having absorbed heat generated by the die on the panel, a pump to provide for the circulation of the coolant through the micro-channels, and conduits to connect the panel, heat exchanger, and pump. A liquid-cooled thermal management solution can cool multiple panels.

Further, a liquid-cooled thermal management solution (that comprises micro-channels in a glass core and/or a cooling component attached to one or more integrated circuit components and/or dies attached to a panel or panel assembly) can be co-located in the same system as the panel or panel assembly cooled by the liquid-cooled thermal management solution. In some embodiments, the thermal management solution is located external to the system. For example, in a rack-scale solution, a liquid-cooling thermal management solution can cool panels located in multiple systems within a rack. Panels employing micro-channels and cavities may or may not have a large form factor thermal management solution attached to the top of the panel. That is, panels may provide for the removal of heat generated by dies within the panel by thermal management solutions located both below (cavities and/or micro-channels) and above (e.g., a thermal management solution such as a liquid-cooled, vapor chamber, heat fins) the dies.

The “core” panel embodiments illustrated in FIGS. 13-21 include various panel features that can be integrated independently into a panel. That is, these panel features are independent of each other and can be mixed and matched to produce “core” panel permutations in addition to those illustrated in FIGS. 13-21. These panel features include local interconnects that are integrally formed with the dielectric layers of a panel and provide electrical communication between die in a panel, local interconnect components that are separately manufactured and placed within a panel (either in one or more dielectric layers or a glass core) during panel manufacture and provide electrical communication between die in a panel, PICs, waveguides, vertically stacked packaged or unpackaged dies, and micro-channels (and reservoirs) in the glass core.

FIGS. 22-25 illustrate simplified cross-sectional views of various “coreless” panel embodiments in which the panel comprises a set of dielectric layers upon which integrated circuit dies are attached but do not comprise a core (such as the glass cores of the “core” panel embodiments). The cross-sectional views relate to the cutout line A-A′ of FIG. 1. Rather than being formed on a core that becomes part of the panel, the dielectric layers in a coreless panel are formed on a glass carrier that provides mechanical stability during panel manufacture and a flat surface enabling the formation of panel features with a fine pitch. The glass carriers used during manufacture are not illustrated in FIGS. 22-25. As the coreless panel embodiments do not have a glass core or a glass reinforcement layer, they can be thinner than either of those types of panel embodiments.

FIG. 22 is a simplified cross-sectional illustration of an example coreless panel. The panel 2200 comprises integrated circuit dies 2204 and 2208 attached to a set of vertically stacked dielectric layers 2222, and a thermal management solution 2209. An upper surface contact layer 2256 comprises a solder resist or other suitable dielectric material 2212 and conductive contacts 2226 arranged to correspond to the pinouts of dies 2204 and 2208 directly attached to the panel 2200. The upper surface contact layer 2256 (and hence, the conductive contacts 2226) is located on a top dielectric layer (e.g., 2222a) of the dielectric layers 2222. A set of conductive contacts 2226 are arranged at a fine pitch. A lower surface contact layer 2260 comprises a solder resist or other suitable dielectric material 2218 and conductive contacts 2232 are arranged to correspond to a desired panel-level pinout. The lower surface contact layer 2260 (and hence, the conductive contacts 2232) is located on a bottom dielectric layer (e.g., 2222d) of the dielectric layers 2222. The set of the conductive contacts 2232 is arranged at a pitch that is greater than the fine pitch at which a set of the conductive contacts 2226 are arranged.

Dielectric layers 2222 comprise conductive traces 2228a and vias 2228b. A local interconnect comprising vias 2228b and conductive traces 2228a included in region 2287 provides an electrically conductive path between a conductive contact 2226 attached to integrated circuit die 2204 and a conductive contact 2226 attached to second integrated circuit die 2208.

The integrated circuit dies 2204 and 2208 are attached to conductive contacts 2226 via solder balls 2238. In other embodiments, the dies 2204 and 2208 can be attached to the conductive contacts 2226 via other approaches, such as hybrid bonding. The panel 2200 further comprises solder balls 2210 attached to conductive contacts 2232. In other embodiments, the panel 2200 does not comprise solder balls 2210 and the package can attach to other components, such as a printed circuit board, via conductive contacts 2232 that are pads.

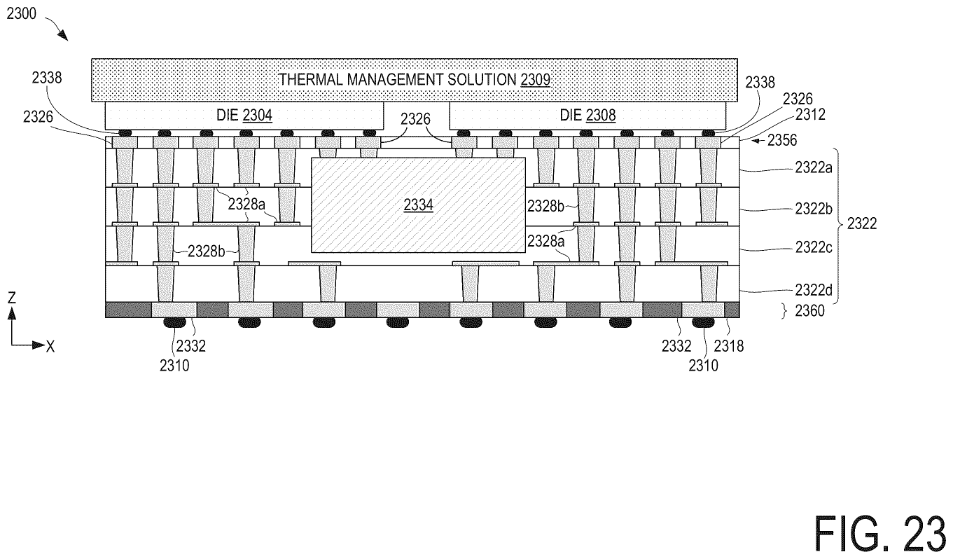

FIG. 23 is a simplified cross-sectional illustration of an example coreless panel comprising a local interconnect component. The panel 2300 comprises integrated circuit dies 2304 and 2308 attached to a set of vertically stacked dielectric layers 2322, and a thermal management solution 2309. An upper surface contact layer 2356 comprises a solder resist or other suitable dielectric material 2312 and conductive contacts 2326 arranged to correspond to the pinouts of dies 2304 and 2308 directly attached to the conductive contacts 2326. The upper surface contact layer 2356 (and hence, the conductive contacts 2326) is located on a top dielectric layer (e.g., 2322a) of the first dielectric layers 2322. A set of the conductive contacts 2326 are arranged at a fine pitch. A lower surface contact layer 2360 comprises a solder resist or other suitable dielectric material 2318 and conductive contacts 2332 are arranged to correspond to a desired panel-level pinout. The lower surface contact layer 2360 (and hence, the conductive contacts 2332) are located on a bottom dielectric layer (e.g., 2322b) of the dielectric layers 2322. The set of conductive contacts 2332 is arranged at a pitch that is greater than the fine pitch at which a set of the conductive contacts 2326 are arranged.

Dielectric layers 2322 comprise conductive traces 2328a and vias 2328b. A local interconnect component 2334 provides electrically conductive paths between conductive contacts 2326 attached to the die 2304 and conductive contacts attached to the die 2308.

The integrated circuit dies 2304 and 2308 are attached to conductive contacts 2326 via solder balls 2338. In other embodiments, the dies 2304 and 2308 can be attached to the conductive contacts 2326 via other approaches, such as hybrid bonding. The panel 2300 further comprises solder balls 2310 attached to the conductive contacts 2332. In other embodiments, the panel 2300 does not comprise solder balls 2310 and the package can attach to other components, such as a printed circuit board via conductive contacts 2332 that are pads.

FIG. 24 is a simplified cross-sectional illustration of an example coreless panel comprising a photonics integrated circuit. The panel 2400 comprises integrated circuit dies 2404 and 2408 attached to a set of vertically stacked dielectric layers 2422 (1622a, 2422b, 2422c, 2422d), a photonics integrated circuit 2462, a waveguide interposer 2427, and a thermal management solution 2409.

An upper surface contact layer 2456 comprises a solder resist or other suitable dielectric material 2412 and conductive contacts 2426 arranged to correspond to the pinouts of dies 2404 and 2408 directly attached to the conductive contacts 2526. The upper surface contact layer 2456 (and hence, the conductive contacts 2426) is located on a top dielectric layer (e.g., 2422a) of the dielectric layers 2422. A set of the conductive contacts 2426 are arranged at a fine pitch. A lower surface contact layer 2460 comprises a solder resist or other suitable dielectric material 2418 and conductive contacts 2432 are arranged to correspond to a desired panel-level pinout. The lower surface contact layer 2460 (and hence, the conductive contacts 2432) is located on a bottom dielectric layer (e.g., 2422d) of the dielectric layers 2422. The set of conductive contacts 2432 is arranged at a pitch that is greater than the fine pitch at which a set of the conductive contacts 2426 are arranged.

Dielectric layers 2422 comprise conductive traces 2428a and vias 2428b. A local interconnect comprising vias 2428b and conductive traces 2428a included in region 2487 provides an electrically conductive path between a conductive contact 2426 attached to die 2404 and a conductive contact 2426 attached to die 2408.

The dies 2404 and 2408 are attached to conductive contacts 2426 via solder balls 2438. In other embodiments, the dies 2404 and 2408 can be attached to the conductive contacts 2426 via other approaches, such as hybrid bonding. The panel 2400 further comprises solder balls 2410 attached to conductive contacts 2432. In other embodiments, the panel 2400 does not comprise solder balls 2410 and the package can attach to other components, such as a printed circuit board, via conductive contacts 2432 that are pads.

Die 2404 is attached to PIC 2462 by solder balls 2419 that are attached to pads 2431 and 2433 belonging to the die 2404 and PIC 2462, respectively. Die 2404 can implement one or more functions, including analog functions implemented with electronic components (such as transistors). In some embodiments, the die 2404 can control behavior of the PIC and/or act as an interface between the PIC 2462 and other panel components (e.g., die 2408). In the context of communicating with a PIC, the die 2404 can be referred to as an electronic integrated chip (EIC) and the PIC 2462 and die 2404 can together be referred to as a PIC-EIC pair.

The waveguide interposer 2427 comprises a waveguide 2464 that provides a path for optical communication for optical signals to be generated or received by the PIC 2462 or the FAU 2421. The waveguide interposer 2427 can be formed as part of the panel 2400 during panel assembly.

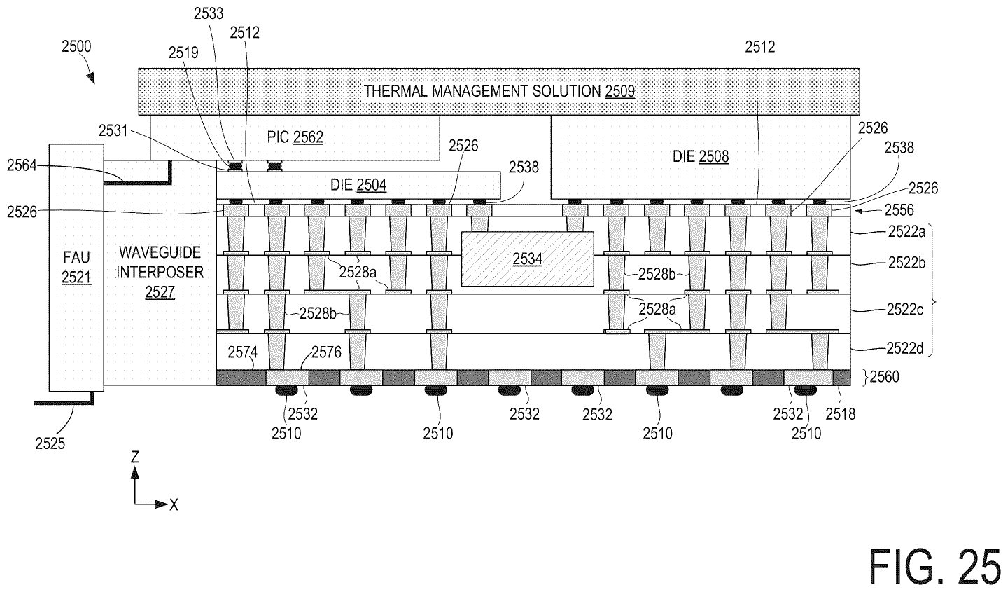

FIG. 25 is a simplified cross-sectional illustration of an example coreless panel comprising a photonics integrated circuit and a local interconnect component. The panel 2500 comprises integrated circuit dies 2504 and 2508 attached to a set of vertically stacked dielectric layers 2522 (2522a, 2522b, 2522c, 2522d), a photonics integrated circuit 2562, a waveguide interposer 2527, and a thermal management solution 2509.

An upper surface contact layer 2556 comprises a solder resist or other suitable dielectric material 2512 and conductive contacts 2526 arranged to correspond to the pinouts of dies 2504 and 2508 directly attached to the conductive contacts 2526. The upper surface contact layer 2556 (and hence, the conductive contacts 2526) is located on a top dielectric layer (e.g., 2522a) of the dielectric layers 2522. A set of the conductive contacts 2526 are arranged at a fine pitch. A lower surface contact layer 2560 comprises a solder resist or other suitable dielectric material 2518 and conductive contacts 2532 are arranged to correspond to a desired panel-level pinout. The lower surface contact layer 2560 (and hence, the conductive contacts 2532) is located on a bottom dielectric layer (e.g., 2522d) of the dielectric layers 2522. The set of conductive contacts 2532 is arranged at a pitch that is greater than the fine pitch at which a set of the conductive contacts 2526 are arranged.

Dielectric layers 2522 comprise conductive traces 2528a and vias 2528b. A local interconnect component comprising vias 2528b and conductive traces 2528a included in region 2562 provides an electrically conductive path between a conductive contact 2526 attached to die 2504 and a conductive contact 2526 attached to die 2508.

The dies 2504 and 2508 are attached to conductive contacts 2526 via solder balls 2538. In other embodiments, the dies 2504 and 2508 can be attached to the conductive contacts 2526 via other approaches, such as hybrid bonding. The panel 2500 further comprises solder balls 2510 attached to conductive contacts 2532. In other embodiments, the panel 2500 does not comprise solder balls 2510 and the package can attach to other components, such as a printed circuit board, via conductive contacts 2532 that are pads.

Die 2504 is attached to PIC 2562 by solder balls 2519 that are attached to pads 2531 and 2533 belonging to the die 2504 and PIC 2562, respectively. Die 2504 can implement one or more functions, including analog functions, implemented with electronic components (such as transistors). In some embodiments, the die 2504 can control behavior of the PIC and/or act as an interface between the PIC 2562 and other panel components (e.g., die 2508). In the context of communicating with a PIC, the 2504 can be referred to as an electronic integrated chip (EIC) and the PIC 2562 and die 2504 can together be referred to as a PIC-EIC pair.

The waveguide interposer 2527 comprises a waveguide 2564 that provides a path for optical communication for optical signals to be generated or received by the PIC 2462 or the FAU 2421. The waveguide interposer 2527 can be formed as part of the panel 2500 during panel assembly.

The “coreless” panels and panel portions illustrated in FIGS. 22-25 are merely illustrative. Again, as previously discussed, more integrated circuit dies can be attached to a panel than illustrated in FIGS. 22-25, and a die attached to or incorporated in a panel can have a lateral dimension, area, shape, height, and/or implement a functionality that is different than that of another die attached to or incorporated in the panel.

The upper surface contact layers illustrated in FIGS. 22-25 (e.g., 2226, 2326, 2426, 2526) can take the form of other upper surface contact layer embodiments, such as those described in connection with FIG. 7 (e.g., 726a, 726b). The lower surface contact layers illustrated in FIGS. 22-25 (e.g., 2260, 2360, 2460) illustrated in FIGS. 22-25 can take the form of other lower surface contact layer embodiments, such as those described in connection with FIG. 7 (e.g., lower surface contact layer embodiment 760).

The thermal management solutions illustrated in FIGS. 22-25 (e.g., 2209, 2309, 2409, 2509) can comprise any cooling component described or referenced herein and be attached to integrated circuit components or integrated circuit dies via thermal interface materials.

The fiber array units illustrated in FIGS. 24-25 (e.g., 2421, 2521) can be attached to a panel during panel manufacture and can be part of an end panel product or be attached to a panel after panel manufacture. Any of the FAUs described or referenced herein can comprise fibers (e.g., 2425, 2525) that are part of an optical connection between panels in a system or between panels across different systems.

The waveguide interposers illustrated in FIGS. 24-25 (e.g., 2427, 2527) can comprise any glass described or referenced herein or comprise the materials that any of the glasses described or referenced herein layers (e.g., glass reinforcement layers of FIGS. 3, 5-6) can comprise.

The coreless panel embodiments illustrated in FIGS. 22-25 include various panel features that can be integrated independently into a panel. The panel features illustrated in FIGS. 22-25, along with various other panel features described herein are independent of each other and can be mixed and matched to produce coreless panel permutations in addition to those illustrated in FIGS. 22-25. These panel features include local interconnects that are integrally formed with the dielectric layers of a panel and provide electrical communication between dies in a panel, local interconnect components that are separately manufactured and placed within a panel during panel manufacture and provide electrical communication between die in a panel, PICs and waveguide interposers, and vertically stacked packaged or unpackaged dies.

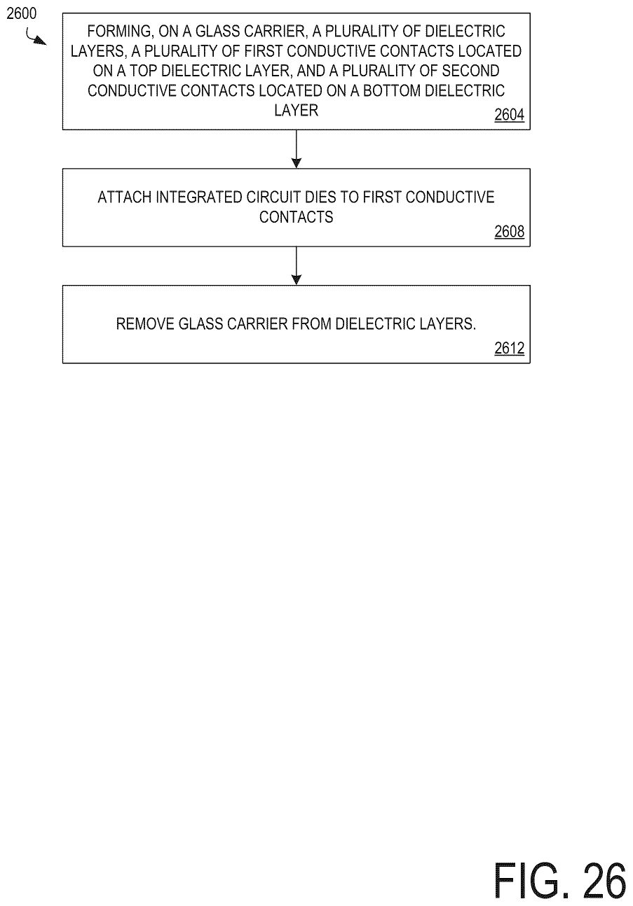

FIG. 26 is a fourth example method of forming a panel. At 2604 in the method 2600, the following are formed on a glass carrier: a plurality of dielectric layers, individual of the dielectric layers comprising one or more conductive traces and one or more vias; a plurality of first conductive contacts on a top dielectric layer of the dielectric layers; and a plurality of second conductive contacts located on a bottom dielectric layer of the dielectric layers, the first conductive contacts arranged at a first pitch that is less than 100 nm, the second conductive contacts arranged at a second pitch that is greater than the first pitch. At 2608, one or more integrated circuit dies are attached to the first conductive contacts. At 2612, the glass carrier is removed from the dielectric layers.

The sequence of elements in method 2600 is non-limiting. Operations of the method 2600 may be performed in a different order and operations may be added or subtracted without altering the final product. For example, method 2600 can further comprise etching one or more of the dielectric layers to create a cavity; and locating a bridge in the cavity, the bridge comprising one or more conductive traces and one or more vias.

Various non-limiting embodiments of panel architectures and methods for making the same have been described. The disclosed panel embodiments may enable high performance computing (e.g., zettascale computing) applications using panels that have dimensions exceeding those possible by wafer-level integration. The provided embodiments enable system-level heterogeneous integration of compute, I/O, memory, power management integrated circuit components and dies (which may include vertical stacking of integrated circuit components and dies), and thermal cooling solutions.

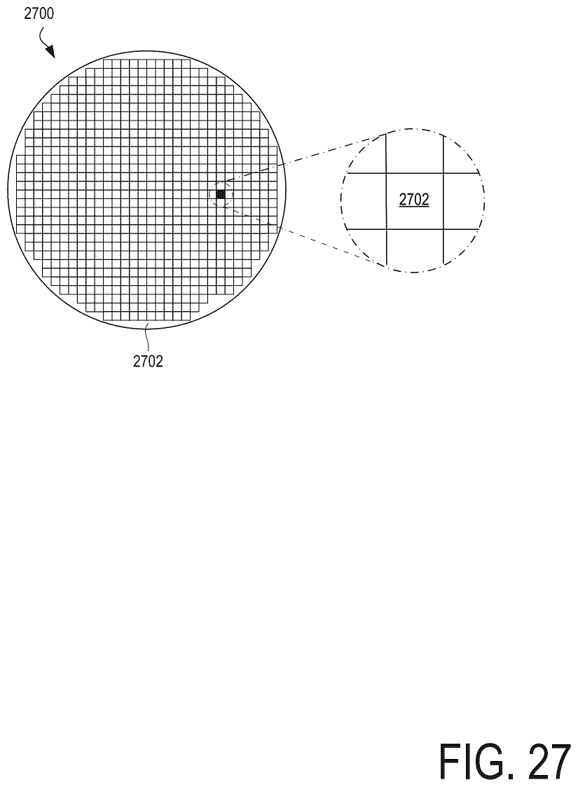

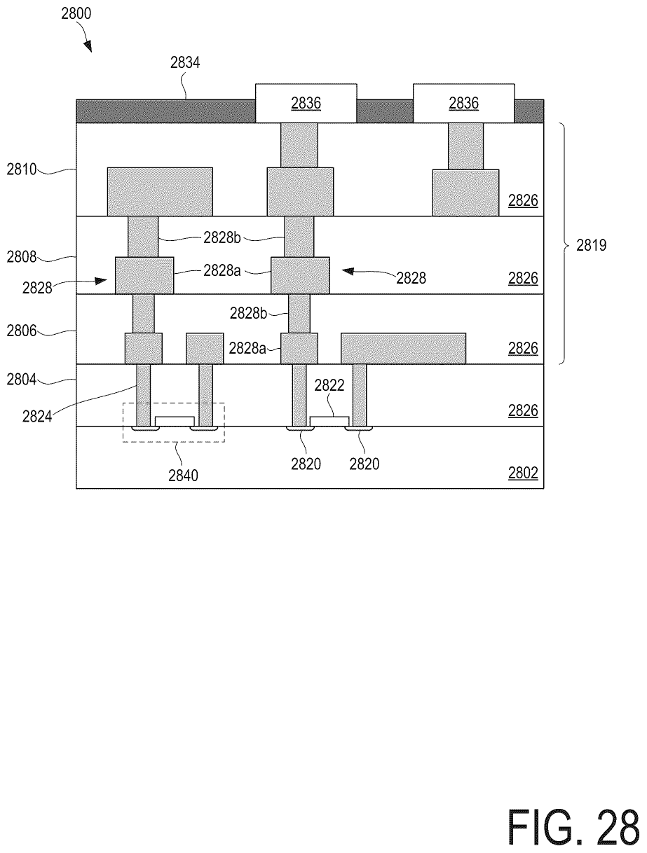

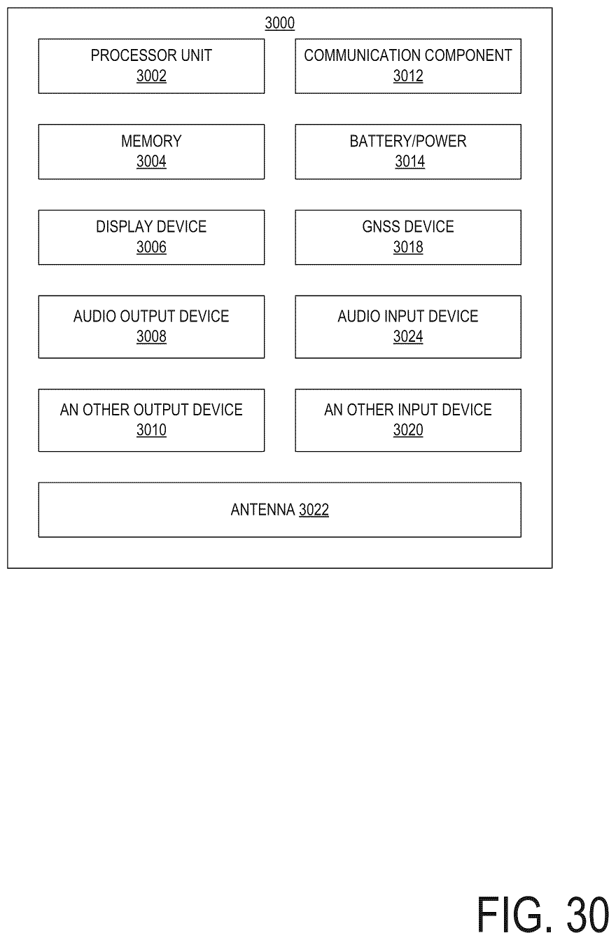

FIG. 27 is a top view of a wafer 2700 and dies 2702 that may be included in any of the embodiments disclosed herein. The wafer 2700 may be composed of semiconductor material and may include one or more dies 2702 formed on a surface of the wafer 2700. After the fabrication of the integrated circuit components on the wafer 2700 is complete, the wafer 2700 may undergo a singulation process in which the dies 2702 are separated from one another to provide discrete “chips” or destined for a packaged integrated circuit component. The individual dies 2702, comprising an integrated circuit component, may include one or more transistors (e.g., some of the transistors 2840 of FIG. 28, discussed below), supporting circuitry to route electrical signals to the transistors, passive components (e.g., signal traces, resistors, capacitors, or inductors), and/or any other integrated circuit components. In some embodiments, the wafer 2700 or the die 2702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 2702. For example, a memory array formed by multiple memory devices may be formed on a same die 2702 as a processor unit (e.g., the processor unit 3002 of FIG. 30) or other logic that is configured to store information in the memory devices or execute instructions stored in the memory array. In some embodiments, a die 2702 may be attached to a wafer 2700 that includes other die, and the wafer 2700 is subsequently singulated, this manufacturing procedure is referred to as a die-to-wafer assembly technique.

FIG. 28 is a cross-sectional side view of an integrated circuit 2800 that may be included in any of the embodiments disclosed herein. One or more of the integrated circuits 2800 may be included in one or more dies 2702 (FIG. 27). The integrated circuit 2800 may be formed on a die substrate 2802 (e.g., the wafer 2700 of FIG. 27) and may be included in a die (e.g., the die 2702 of FIG. 27).

The die substrate 2802 may be a semiconductor substrate composed of semiconductor material systems including, for example, n-type or p-type materials systems (or a combination of both). The die substrate 2802 may include, for example, a crystalline substrate formed using a bulk silicon or a silicon-on-insulator (SOI) substructure. In some embodiments, the die substrate 2802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 2802. Although a few examples of materials from which the die substrate 2802 may be formed are described here, any material that may serve as a foundation for an integrated circuit 2800 may be used. The die substrate 2802 may be part of a singulated die (e.g., the dies 2702 of FIG. 27) or a wafer (e.g., the wafer 2700 of FIG. 27).

The integrated circuit 2800 may include one or more device layers 2804 disposed on the die substrate 2802. The device layer 2804 may include features of one or more transistors 2840 (e.g., metal oxide semiconductor field-effect transistors (MOSFETs)) formed on the die substrate 2802. The transistors 2840 may include, for example, one or more source and/or drain (S/D) regions 2820, a gate 2822 to control current flow between the S/D regions 2820, and one or more S/D contacts 2824 to route electrical signals to/from the S/D regions 2820.

The gate 2822 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 2840 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 2840 along the source-channel-drain direction, the gate electrode may comprise a U-shaped structure that includes a bottom portion substantially parallel to the surface of the die substrate 2802 and two sidewall portions that are substantially perpendicular to the top surface of the die substrate 2802. In other embodiments, at least one of the metal layers that form the gate electrode may simply be a planar layer that is substantially parallel to the top surface of the die substrate 2802 and does not include sidewall portions substantially perpendicular to the top surface of the die substrate 2802. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching process steps. In some embodiments, a plurality of spacer pairs may be used; for instance, two pairs, three pairs, or four pairs of sidewall spacers may be formed on opposing sides of the gate stack.

The S/D regions 2820 may be formed within the die substrate 2802 adjacent to the gate 2822 of individual transistors 2840. The S/D regions 2820 may be formed using an implantation/diffusion process or an etching/deposition process, for example. In the former process, dopants such as boron, aluminum, antimony, phosphorous, or arsenic may be ion-implanted into the die substrate 2802 to form the S/D regions 2820. An annealing process that activates the dopants and causes them to diffuse farther into the die substrate 2802 may follow the ion-implantation process. In the latter process, the die substrate 2802 may first be etched to form recesses at the locations of the S/D regions 2820. An epitaxial deposition process may then be conducted to fill the recesses with material that is used to fabricate the S/D regions 2820. In some implementations, the S/D regions 2820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 2820 may be formed using one or more alternate semiconductor materials such as germanium or a group III-V material or alloy. In further embodiments, one or more layers of metal and/or metal alloys may be used to form the S/D regions 2820.

Electrical signals, such as power and/or input/output (I/O) signals, may be routed to and/or from the devices (e.g., transistors 2840) of the device layer 2804 through one or more interconnect layers disposed on the device layer 2804 (illustrated in FIG. 28 as interconnect layers 2806-2810). For example, electrically conductive features of the device layer 2804 (e.g., the gate 2822 and the S/D contacts 2824) may be electrically coupled with the interconnect structures 2828 of the interconnect layers 2806-2810. The one or more interconnect layers 2806-2810 may form a metallization stack (also referred to as an “ILD stack”) 2819 of the integrated circuit 2800.

The interconnect structures 2828 may be arranged within the interconnect layers 2806-2810 to route electrical signals according to a wide variety of designs; in particular, the arrangement is not limited to the particular configuration of interconnect structures 2828 depicted in FIG. 28. Although a particular number of interconnect layers 2806-2810 is depicted in FIG. 28, embodiments of the present disclosure include integrated circuits having more or fewer interconnect layers than depicted.

In some embodiments, the interconnect structures 2828 may include lines 2828a and/or vias 2828b filled with an electrically conductive material such as a metal. The lines 2828a may be arranged to route electrical signals in a direction of a plane that is substantially parallel with a surface of the die substrate 2802 upon which the device layer 2804 is formed. For example, the lines 2828a may route electrical signals in a direction in and out of the page and/or in a direction across the page. The vias 2828b may be arranged to route electrical signals in a direction of a plane that is substantially perpendicular to the surface of the die substrate 2802 upon which the device layer 2804 is formed. In some embodiments, the vias 2828b may electrically couple lines 2828a of different interconnect layers 2806-2810 together.

The interconnect layers 2806-2810 may include a dielectric material 2826 disposed between the interconnect structures 2828, as shown in FIG. 28. In some embodiments, dielectric material 2826 disposed between the interconnect structures 2828 in different ones of the interconnect layers 2806-2810 may have different compositions; in other embodiments, the composition of the dielectric material 2826 between different interconnect layers 2806-2810 may be the same. The device layer 2804 may include a dielectric material 2826 disposed between the transistors 2840 and a bottom layer of the metallization stack as well. The dielectric material 2826 included in the device layer 2804 may have a different composition than the dielectric material 2826 included in the interconnect layers 2806-2810; in other embodiments, the composition of the dielectric material 2826 in the device layer 2804 may be the same as a dielectric material 2826 included in any one of the interconnect layers 2806-2810.

A first interconnect layer 2806 (referred to as Metal 1 or “M1”) may be formed directly on the device layer 2804. In some embodiments, the first interconnect layer 2806 may include lines 2828a and/or vias 2828b, as shown. The lines 2828a of the first interconnect layer 2806 may be coupled with contacts (e.g., the S/D contacts 2824) of the device layer 2804. The vias 2828b of the first interconnect layer 2806 may be coupled with the lines 2828a of a second interconnect layer 2808.

The second interconnect layer 2808 (referred to as Metal 2 or “M2”) may be formed directly on the first interconnect layer 2806. In some embodiments, the second interconnect layer 2808 may include via 2828b to couple the lines 2828 of the second interconnect layer 2808 with the lines 2828a of a third interconnect layer 2810. Although the lines 2828a and the vias 2828b are structurally delineated with a line within individual interconnect layers for the sake of clarity, the lines 2828a and the vias 2828b may be structurally and/or materially contiguous (e.g., simultaneously filled during a dual-damascene process) in some embodiments.

The third interconnect layer 2810 (referred to as Metal 3 or “M3”) (and additional interconnect layers, as desired) may be formed in succession on the second interconnect layer 2808 according to similar techniques and configurations described in connection with the second interconnect layer 2808 or the first interconnect layer 2806. In some embodiments, the interconnect layers that are “higher up” in the metallization stack 2819 in the integrated circuit 2800 (i.e., farther away from the device layer 2804) may be thicker that the interconnect layers that are lower in the metallization stack 2819, with lines 2828a and vias 2828b in the higher interconnect layers being thicker than those in the lower interconnect layers.

The integrated circuit 2800 may include a solder resist material 2834 (e.g., polyimide or similar material) and one or more conductive contacts 2836 formed on the interconnect layers 2806-2810. In FIG. 28, the conductive contacts 2836 are illustrated as taking the form of bond pads. The conductive contacts 2836 may be electrically coupled with the interconnect structures 2828 and configured to route the electrical signals of the transistor(s) 2840 to external devices. For example, solder bonds may be formed on the one or more conductive contacts 2836 to mechanically and/or electrically couple an integrated circuit die including the integrated circuit 2800 with another component (e.g., a printed circuit board). The integrated circuit 2800 may include additional or alternate structures to route the electrical signals from the interconnect layers 2806-2810; for example, the conductive contacts 2836 may include other analogous features (e.g., posts) that route the electrical signals to external components.

In some embodiments in which the integrated circuit 2800 is a double-sided die, the integrated circuit 2800 may include another metallization stack (not shown) on the opposite side of the device layer(s) 2804. This metallization stack may include multiple interconnect layers as discussed above with reference to the interconnect layers 2806-2810, to provide electrically conductive paths (e.g., including conductive lines and vias) between the device layer(s) 2804 and additional conductive contacts (not shown) on the opposite side of the integrated circuit 2800 from the conductive contacts 2836.

In other embodiments in which the integrated circuit 2800 is a double-sided die, the integrated circuit 2800 may include one or more through silicon vias (TSVs) through the die substrate 2802; these TSVs may make contact with the device layer(s) 2804, and may provide electrically conductive paths between the device layer(s) 2804 and additional conductive contacts (not shown) on the opposite side of the integrated circuit 2800 from the conductive contacts 2836. In some embodiments, TSVs extending through the substrate can be used for routing power and ground signals from conductive contacts on the opposite side of the integrated circuit 2800 from the conductive contacts 2836 to the transistors 2840 and any other components integrated into the die 2800, and the metallization stack 2819 can be used to route I/O signals from the conductive contacts 2836 to transistors 2840 and any other components integrated into the die 2800.

Multiple integrated circuits 2800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

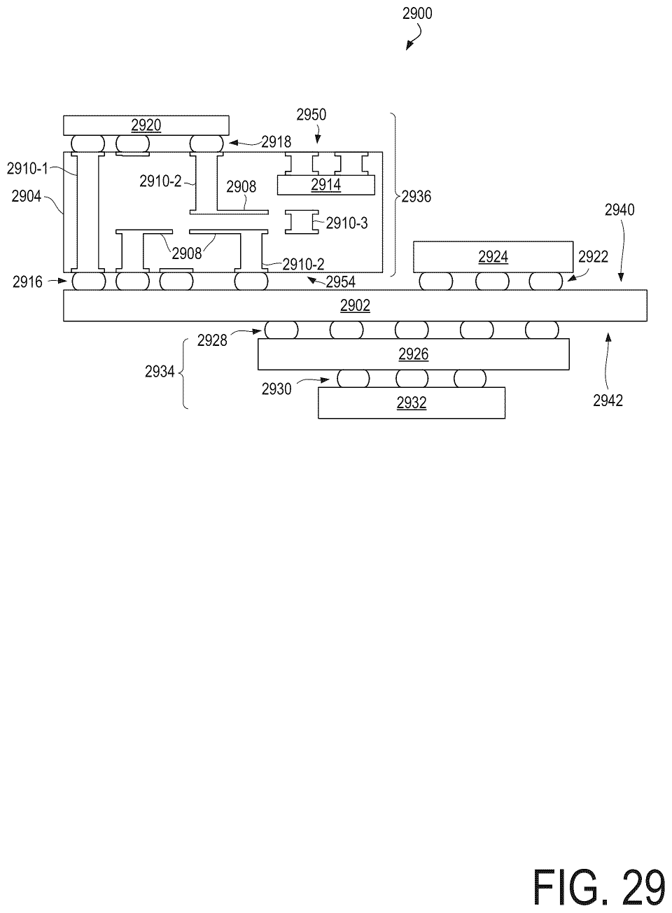

FIG. 29 is a cross-sectional side view of a microelectronic assembly 2900 that may include any of the embodiments disclosed herein. The microelectronic assembly 2900 includes multiple integrated circuit components disposed on a circuit board 2902 (which may be a motherboard, system board, mainboard, etc.). The microelectronic assembly 2900 may include components disposed on a first face 2940 of the circuit board 2902 and an opposing second face 2942 of the circuit board 2902; generally, components may be disposed on one or both faces 2940 and 2942.

In some embodiments, the circuit board 2902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 2902. In other embodiments, the circuit board 2902 may be a non-PCB substrate. The microelectronic assembly 2900 illustrated in FIG. 29 includes a package-on-interposer structure 2936 coupled to the first face 2940 of the circuit board 2902 by coupling components 2916. The coupling components 2916 may electrically and mechanically couple the package-on-interposer structure 2936 to the circuit board 2902, and may include solder balls (as shown in FIG. 29), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 2936 may include an integrated circuit component 2920 coupled to an interposer 2904 by coupling components 2918. The coupling components 2918 may take any suitable form for the application, such as the forms discussed above with reference to the coupling components 2916. Although a single integrated circuit component 2920 is shown in FIG. 29, multiple integrated circuit components may be coupled to the interposer 2904; indeed, additional interposers may be coupled to the interposer 2904. The interposer 2904 may provide an intervening substrate used to bridge the circuit board 2902 and the integrated circuit component 2920.

The integrated circuit component 2920 may be a packaged or unpackaged integrated circuit component that includes one or more integrated circuit dies (e.g., the die 2702 of FIG. 27, the integrated circuit 2800 of FIG. 28) and/or one or more other suitable components.

The unpackaged integrated circuit component 2920 comprises solder bumps attached to contacts on the die. The solder bumps allow the die to be directly attached to the interposer 2904. In embodiments where the integrated circuit component 2920 comprises multiple integrated circuit dies, the dies can be of the same type (a homogeneous multi-die integrated circuit component) or of two or more different types (a heterogeneous multi-die integrated circuit component). In addition to comprising one or more processor units, the integrated circuit component 2920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof. A packaged multi-die integrated circuit component can be referred to as a multi-chip package (MCP) or multi-chip module (MCM).

The interposer 2904 may spread connections to a wider pitch or reroute a connection to a different connection. For example, the interposer 2904 may couple the integrated circuit component 2920 to a set of ball grid array (BGA) conductive contacts of the coupling components 2916 for coupling to the circuit board 2902. In the embodiment illustrated in FIG. 29, the integrated circuit component 2920 and the circuit board 2902 are attached to opposing sides of the interposer 2904; in other embodiments, the integrated circuit component 2920 and the circuit board 2902 may be attached to a same side of the interposer 2904. In some embodiments, three or more components may be interconnected by way of the interposer 2904.

In some embodiments, the interposer 2904 may be formed as a PCB, including multiple metal layers separated from one another by layers of dielectric material and interconnected by electrically conductive vias. In some embodiments, the interposer 2904 may be formed of an epoxy resin, a fiberglass-reinforced epoxy resin, an epoxy resin with inorganic fillers, a ceramic material, or a polymer material such as polyimide. In some embodiments, the interposer 2904 may be formed of alternate rigid or flexible materials that may include the same materials described above for use in a semiconductor substrate, such as silicon, germanium, and other group III-V and group IV materials. The interposer 2904 may include metal interconnects 2908 and vias 2910, including but not limited to through hole vias 2910-1 (that extend from a first face 2950 of the interposer 2904 to a second face 2954 of the interposer 2904), blind vias 2910-2 (that extend from the first or second faces 2950 or 2954 of the interposer 2904 to an internal metal layer), and buried vias 2910-3 (that connect internal metal layers).

In some embodiments, the interposer 2904 can comprise a silicon interposer. Through silicon vias (TSV) extending through the silicon interposer can connect connections on a first face of a silicon interposer to an opposing second face of the silicon interposer. In some embodiments, an interposer 2904 comprising a silicon interposer can further comprise one or more routing layers to route connections on a first face of the interposer 2904 to an opposing second face of the interposer 2904.

The interposer 2904 may further include embedded devices 2914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2904. The package-on-interposer structure 2936 may take the form of any of the package-on-interposer structures known in the art. In embodiments where the interposer is a non-printed circuit board

The integrated circuit assembly 2900 may include an integrated circuit component 2924 coupled to the first face 2940 of the circuit board 2902 by coupling components 2922. The coupling components 2922 may take the form of any of the embodiments discussed above with reference to the coupling components 2916, and the integrated circuit component 2924 may take the form of any of the embodiments discussed above with reference to the integrated circuit component 2920.

The integrated circuit assembly 2900 illustrated in FIG. 29 includes a package-on-package structure 2934 coupled to the second face 2942 of the circuit board 2902 by coupling components 2928. The package-on-package structure 2934 may include an integrated circuit component 2926 and an integrated circuit component 2932 coupled together by coupling components 2930 such that the integrated circuit component 2926 is disposed between the circuit board 2902 and the integrated circuit component 2932. The coupling components 2928 and 2930 may take the form of any of the embodiments of the coupling components 2916 discussed above, and the integrated circuit components 2926 and 2932 may take the form of any of the embodiments of the integrated circuit component 2920 discussed above. The package-on-package structure 2934 may be configured in accordance with any of the package-on-package structures known in the art.

FIG. 30 is a block diagram of an example electrical device 3000 that may include one or more of the embodiments disclosed herein. For example, any suitable ones of the components of the electrical device 3000 may include one or more of the microelectronic assemblies 2900, integrated circuit components 2920, integrated circuits 2800, integrated circuit dies 2702, or structures disclosed herein. A number of components are illustrated in FIG. 30 as included in the electrical device 3000, but any one or more of these components may be omitted or duplicated, as suitable for the application. In some embodiments, some or all the components included in the electrical device 3000 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 3000 may not include one or more of the components illustrated in FIG. 30, but the electrical device 3000 may include interface circuitry for coupling to the one or more components. For example, the electrical device 3000 may not include a display device 3006, but may include display device interface circuitry (e.g., a connector and driver circuitry) to which a display device 3006 may be coupled. In another set of examples, the electrical device 3000 may not include an audio input device 3024 or an audio output device 3008, but may include audio input or output device interface circuitry (e.g., connectors and supporting circuitry) to which an audio input device 3024 or audio output device 3008 may be coupled.

The electrical device 3000 may include one or more processor units 3002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 3002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 3000 may include a memory 3004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 3004 may include memory that is located on the same integrated circuit die as the processor unit 3002. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 3000 can comprise one or more processor units 3002 that are heterogeneous or asymmetric to another processor unit 3002 in the electrical device 3000. There can be a variety of differences between the processor units 3002 in a system in terms of a spectrum of metrics of merit including architectural, microarchitectural, thermal, power consumption characteristics, and the like. These differences can effectively manifest themselves as asymmetry and heterogeneity among the processor units 3002 in the electrical device 3000.

In some embodiments, the electrical device 3000 may include a communication component 3012 (e.g., one or more communication components). For example, the communication component 3012 can manage wireless communications for the transfer of data to and from the electrical device 3000. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 3012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 3012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 3012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 3012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 3012 may operate in accordance with other wireless protocols in other embodiments. The electrical device 3000 may include an antenna 3022 to facilitate wireless communications and/or to receive other wireless communications (such as AM or FM radio transmissions).

In some embodiments, the communication component 3012 may manage wired communications, such as electrical, optical, or any other suitable communication protocols (e.g., IEEE 802.3 Ethernet standards). As noted above, the communication component 3012 may include multiple communication components. For instance, a first communication component 3012 may be dedicated to shorter-range wireless communications such as Wi-Fi or Bluetooth, and a second communication component 3012 may be dedicated to longer-range wireless communications such as global positioning system (GPS), EDGE, GPRS, CDMA, WiMAX, LTE, EV-DO, or others. In some embodiments, a first communication component 3012 may be dedicated to wireless communications, and a second communication component 3012 may be dedicated to wired communications.

The electrical device 3000 may include battery/power circuitry 3014. The battery/power circuitry 3014 may include one or more energy storage devices (e.g., batteries or capacitors) and/or circuitry for coupling components of the electrical device 3000 to an energy source separate from the electrical device 3000 (e.g., AC line power).

The electrical device 3000 may include a display device 3006 (or corresponding interface circuitry, as discussed above). The display device 3006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 3000 may include an audio output device 3008 (or corresponding interface circuitry, as discussed above). The audio output device 3008 may include any embedded or wired or wirelessly connected external device that generates an audible indicator, such speakers, headsets, or earbuds.

The electrical device 3000 may include an audio input device 3024 (or corresponding interface circuitry, as discussed above). The audio input device 3024 may include any embedded or wired or wirelessly connected device that generates a signal representative of a sound, such as microphones, microphone arrays, or digital instruments (e.g., instruments having a musical instrument digital interface (MIDI) output). The electrical device 3000 may include a Global Navigation Satellite System (GNSS) device 3018 (or corresponding interface circuitry, as discussed above), such as a Global Positioning System (GPS) device. The GNSS device 3018 may be in communication with a satellite-based system and may determine a geolocation of the electrical device 3000 based on information received from one or more GNSS satellites, as known in the art.

The electrical device 3000 may include another output device 3010 (or corresponding interface circuitry, as discussed above). Examples of the other output device 3010 may include an audio codec, a video codec, a printer, a wired or wireless transmitter for providing information to other devices, or an additional storage device.

The electrical device 3000 may include another input device 3020 (or corresponding interface circuitry, as discussed above). Examples of the other input device 3020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 3000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 3000 may be any other electronic device that processes data. In some embodiments, the electrical device 3000 may comprise multiple discrete physical components. Given the range of devices that the electrical device 3000 can be manifested as in various embodiments, in some embodiments, the electrical device 3000 can be referred to as a computing device or a computing system.

Thus, embodiments of an improved via structure for use with the embedded component have been provided. The provided embodiments advantageously enable the use of finer pitch architectures and high-density input/output (I/O) designs in multi-chip packaging.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

Example A1 includes: a first dielectric layer comprising conductive pads arranged at a first pitch; a second dielectric layer located above the first dielectric layer, the second dielectric layer comprising conductive contacts arranged into a first set and a second set, the first set of conductive contacts further arranged at a second pitch; a glass layer located between the first dielectric layer and the second dielectric layer; a local interconnect component located in the glass layer, the local interconnect component to provide electrical communication between a first conductive contact in the first set and a first conductive contact in the second set; and an electrically conductive path between a second conductive contact of the first set to one of the conductive pads, the electrically conductive path comprising an interconnect structure.

Example A2 includes the subject matter of Example A1, wherein the interconnect structure is a first interconnect structure located in the first dielectric layer or second dielectric layer, and wherein the electrically conductive path further comprises a second interconnect structure located in the glass layer and coupled to the first interconnect structure.

Example A3 includes the subject matter of Example A1, wherein the interconnect structure is a first interconnect structure located in the first dielectric layer, wherein the electrically conductive path further comprises a second interconnect structure located in the glass layer and a third interconnect structure located in the second dielectric layer, and wherein the second interconnect structure is configured to couple the first interconnect structure to the third interconnect structure.

Example A4 includes the subject matter of any one of Examples A1-A3, wherein the interconnect structure comprises a conductive trace and a via.

Example A5 includes the subject matter of Example A1, wherein the first dielectric layer comprises more than one sub-layers, individual sub-layers comprising a respective conductive trace and via.

Example A6 includes the subject matter of Example A1, wherein the second dielectric layer comprises more than one sub-layers, individual sub-layers comprising a respective conductive trace and a via.

Example A7 includes the subject matter of Example A1, wherein the glass layer comprises a glass sheet.

Example A8 includes the subject matter of Example A1, wherein the glass layer comprises more than one glass sheet.

Example A9 includes the subject matter of Example A1, wherein the glass layer comprises more than one glass sheets, and respective glass sheets have a thickness in a range of 100-150 microns.

Example A10 includes the subject matter of Example A1, wherein the glass layer has a thickness substantially in a range of 300 microns to 1 millimeter.

Example A11 includes the subject matter of Example A1, wherein the glass layer comprises a glass sheet, and the glass sheet has a dielectric layer located adjacent thereto.

Example A12 includes the subject matter of Example A1, wherein the glass layer comprises a glass sheet having a dielectric layer located adjacent thereto, and the dielectric layer comprises Ajinomoto Build-up Film (ABF).

Example A13 includes the subject matter of Example A1, wherein the glass layer comprises a glass sheet having a dielectric layer located adjacent thereto, and the dielectric layer is substantially 10 microns thick.

Example A14 includes the subject matter of Example A1, wherein the glass layer comprises silicon and oxygen.

Example A15 includes the subject matter of Example A14, wherein the glass layer comprises further comprises aluminum, boron, or an alkaline-earth metal.

Example A16 includes the subject matter of Example A1, wherein the local interconnect component comprises silicon.

Example A17 includes the subject matter of Example A1, wherein the local interconnect component is a redistribution layer.

Example A18 includes the subject matter of any one of Examples A1-A17, further comprising: a first die attached to the first set of conductive contacts; and a second die attached to the second set of conductive contacts.

Example A19 includes the subject matter of any one of Examples A1-A17, further comprising: a first die attached to the first set of conductive contacts; a second die attached to the second set of conductive contacts; and wherein the first die has a first functionality, the second die has a second functionality, the second functionality being different than the first functionality.

Example A20 includes the subject matter of any one of Examples A1-A17, further comprising a first die attached to the first set of conductive contacts; a second die attached to the second set of conductive contacts; and wherein the first die has a different thickness than the second die.

Example A21 includes the subject matter of any one of Examples A18-A20, further comprising an encapsulant located over the first die and second die.

Example A22 includes the subject matter of Example A21, wherein the apparatus is a panel, and further comprising a cooling component located on the panel.

Example A23 includes the subject matter of Example A22, wherein the cooling component includes a heat exchanger.

Example A24 includes the subject matter of Example A21 or Example A22, wherein the apparatus is a first panel, and further comprising a second panel in electrical communication with the first panel.

Example A25 includes the subject matter of Example A24, further comprising: a substrate; the first panel and the second panel being attached to the substrate.

Example A26 includes the subject matter of Example A25, further comprising an electronic component attached to the substrate, the electronic component located external to the first panel and the second panel.

Example A27 includes the subject matter of Example A26, and further comprising: a housing enclosing the panel; and a heat pump connected to the heat exchanger on the panel via conduits.

Example A28 includes the subject matter of any one of Examples A25-A29, further comprising a power management system electronically coupled to the panel.

Example A29 is a method, comprising: forming a first dielectric layer on a glass carrier, the glass carrier having an area of at least 250 millimeters×250 millimeters, the first dielectric layer comprising conductive pads arranged at a first pitch, the first pitch being 100 microns or less; forming a glass layer on the first dielectric layer, the glass layer comprising a local interconnect component; locating a second dielectric layer on the glass layer, the second dielectric layer comprising conductive contacts arranged at a second pitch, the conductive contacts further arranged into a first set and a second set; the local interconnect component to provide electrical communication between a first conductive contact in the first set and a first conductive contact in the second set; and locating an interconnect structure in the glass layer, the interconnect structure to provide electrical communication between a second conductive contact of the first set and one of the conductive pads.

Example A30 includes the subject matter of Example A29, further comprising: attaching a first die to the first set; and attaching a second die to the second set, thereby creating a populated substrate.

Example A31 includes the subject matter of Example A30, further comprising: debonding the glass carrier from the populated substrate; and forming solder bumps on the conductive pads.

Example A32 includes the subject matter of Example A31, further comprising singulating the populated substrate to thereby create a first panel and a second panel.

Example A33 includes the subject matter of Example A32, further comprising attaching a thermal solution to the first panel or the second panel.

Example A34 is an apparatus, comprising: a first dielectric layer comprising conductive pads arranged at a first pitch; a second dielectric layer located above the first dielectric layer, the second dielectric layer comprising conductive contacts arranged into a first set and a second set, the first set of the conductive contacts being arranged at a second pitch that is smaller than the first pitch; a glass layer located between the first dielectric layer and the second dielectric layer, the glass layer comprising a through-glass via; a photonic integrated circuit (PIC) located in the glass layer and in electrical communication with a first conductive contact from the first set; and an electrically conductive path between a second conductive contact from the first set to one of the conductive pads, the electrically conductive path comprising an interconnect structure located in the first dielectric layer or the second dielectric layer.

Example A35 includes the subject matter of Example A34, wherein the PIC comprises a silicon micro-ring resonator.

Example A36 includes the subject matter of Example A34, further comprising waveguides associated with the PIC located in the glass layer.

Example A37 includes the subject matter of any one of Examples A34-A36, wherein the interconnect structure comprises a conductive trace and a via.

Example A38 includes the subject matter of Example A34, wherein the interconnect structure is a first interconnect structure located in the first dielectric layer or second dielectric layer, and wherein the electrically conductive path further comprises a second interconnect structure located in the glass layer and coupled to the first interconnect structure.

Example A39 includes the subject matter of Example A34, wherein the interconnect structure is a first interconnect structure located in the first dielectric layer, wherein the electrically conductive path further comprises a second interconnect structure located in the glass layer and a third interconnect structure located in the second dielectric layer, and wherein the second interconnect structure is configured to couple the first interconnect structure to the third interconnect structure.

Example A40 includes the subject matter of any one of Examples A38-A39, wherein the first dielectric layer comprises more than one sub-layers, individual sub-layers comprising a respective conductive trace and a via.

Example A41 includes the subject matter of any one of Examples A38-A40, wherein the second dielectric layer comprises more than one sub-layers, individual sub-layers comprising a respective conductive trace and a via.

Example A42 includes the subject matter of any one of Examples A34-A41, wherein the glass layer comprises a glass sheet.

Example A43 includes the subject matter of any one of Examples A34-A41, wherein the glass layer comprises more than one glass sheet.

Example A44 includes the subject matter of any one of Examples A34-A41, wherein the glass layer comprises more than one glass sheets, and respective glass sheets have a thickness in a range of 100-150 microns.

Example A45 includes the subject matter of any one of Examples A34-A41, wherein the glass layer has a thickness substantially in a range of 300 microns to 1 millimeter.

Example A46 includes the subject matter of Example A34, wherein the glass layer comprises a glass sheet, and the glass sheet has a dielectric layer located adjacent thereto.

Example A47 includes the subject matter of Example A34, wherein the glass layer comprises a glass sheet having a dielectric layer located adjacent thereto, and the dielectric layer comprises Ajinomoto Build-up Film (ABF).

Example A48 includes the subject matter of Example A34, wherein the glass layer comprises a glass sheet having a dielectric layer located adjacent thereto, and the dielectric layer is substantially 10 microns thick.

Example A49 includes the subject matter of Example A34, wherein the glass layer comprises silicon and oxygen.

Example A50 includes the subject matter of Example A34, wherein the glass layer comprises further comprises aluminum, boron, or an alkaline-earth metal.

Example A51 includes the subject matter of any one of Examples A34-A50, further comprising a local interconnect component located in the glass layer, the local interconnect component to provide electrical communication between a third conductive contact located in the first set to a fourth conductive located in the second set.

Example A52 includes the subject matter of any one of Examples A34-A51, further comprising a first die attached to the first set of conductive contacts and a second die attached to the second set of conductive contacts.

Example A53 includes the subject matter of any one of Examples A34-A51, further comprising: a first die attached to the first set of conductive contacts; a second die attached to the second set of conductive contacts; and wherein the first die has a first functionality, the second die has a second functionality, the second functionality being different than the first functionality.

Example A54 includes the subject matter of any one of Examples A34-A51, further comprising a first die attached to the first set of conductive contacts; a second die attached to the second set of conductive contacts; and wherein the first die has a different thickness than the second die.

Example A55 includes the subject matter of any one of Examples A52-A54, further comprising an encapsulant located over the first die and second die.

Example A56 includes the subject matter of Example A55, wherein the apparatus is a panel, and further comprising a cooling component located on the panel.

Example A57 includes the subject matter of Example A56, wherein the cooling component includes a heat exchanger.

Example A58 includes the subject matter of any one of Examples A56-A57, wherein the apparatus is a first panel, and further comprising a second panel in electrical communication with the first panel.

Example A59 includes the subject matter of Example A58, further comprising: a substrate; the first panel and the second panel being attached to the substrate.

Example A60 includes the subject matter of Example A59, further comprising an electronic component attached to the substrate, the electronic component located external to the first panel and the second panel.

Example A61 includes the subject matter of Example A58, and further comprising: a housing enclosing the first panel; and a heat pump connected to the heat exchanger on the panel via conduits.

Example A62 includes the subject matter of Example A58, further comprising a power management system electronically coupled to the panel.

Example A63 is a method, comprising: forming a first dielectric layer on a glass carrier, the glass carrier having a cross-sectional area of at least 250 millimeters×250 millimeters, the first dielectric layer comprising conductive pads arranged at a first pitch, the first pitch being 100 microns or less; forming a glass layer on the first dielectric layer, the glass layer comprising a photonic integrated circuit (PIC); locating a second dielectric layer on the glass layer, the second dielectric layer comprising conductive contacts arranged at a second pitch, the conductive contacts further arranged into a first set and a second set; the PIC configured to be in electrical communication with a first conductive contact in the first set or the second set; and locating an interconnect structure in the glass layer, the interconnect structure to provide electrical communication between a second conductive contact of the first set and one of the conductive pads.

Example A64 includes the subject matter of Example A63, further comprising: attaching a first die to the first set; and attaching a second die to the second set, thereby creating a populated substrate.

Example A65 includes the subject matter of Example A64, further comprising: debonding the glass carrier from the populated substrate; and forming solder bumps on the conductive pads.

Example A66 includes the subject matter of Example A65, further comprising singulating the populated substrate to thereby create a first panel and a second panel.

Example A67 includes the subject matter of Example A66, further comprising attaching a thermal solution to the first panel or the second panel.

Example A68 is an apparatus, comprising: a first dielectric layer comprising conductive pads arranged at a first pitch; a second dielectric layer located above the first dielectric layer, the second dielectric layer comprising conductive contacts arranged at a second pitch, the conductive contacts further arranged into a first set and a second set; a glass layer located in between the first dielectric layer and the second dielectric layer; a micro-channel located in the glass layer, the micro-channel configured to accommodate a flow of a liquid coolant; and an electrically conductive path between a second conductive contact from the first set or the second set to one of the conductive pads, the electrically conductive path comprising an interconnect structure located in the first dielectric layer, the second dielectric layer, or glass layer.

Example A69 includes the subject matter of Example A68, wherein the micro-channel has a lateral portion near the first set of conductive contacts.

Example A70 includes the subject matter of Example A68, further comprising a cavity located in the glass layer.

Example A71 includes the subject matter of Example A68, wherein the interconnect structure comprises a conductive trace and a via.

Example A72 includes the subject matter of Example A71, wherein the interconnect structure is located in the first dielectric layer.

Example A73 includes the subject matter of Example A72, wherein the interconnect structure is a first interconnect structure, and further comprising a second interconnect structure located in the second dielectric layer, the second interconnect structure coupled to the first interconnect structure via a through-glass via in the glass layer.

Example A74 includes the subject matter of Example A68, wherein the first dielectric layer comprises more than one sub-layers, individual sub-layers comprising a respective conductive trace and via.

Example A75 includes the subject matter of Example A68, wherein the second dielectric layer comprises more than one sub-layers, individual sub-layers comprising a respective conductive trace and via.

Example A76 includes the subject matter of Example A68, wherein the glass layer comprises a glass sheet.

Example A77 includes the subject matter of Example A68, wherein the glass layer comprises more than one glass sheet.

Example A78 includes the subject matter of Example A68, wherein the glass layer comprises more than one glass sheets, and respective glass sheets have a thickness in a range of 100-150 microns.

Example A79 includes the subject matter of Example A68, wherein the glass layer has a thickness substantially in a range of 300 microns to 1 millimeter.

Example A80 includes the subject matter of Example A68, wherein the glass layer comprises a glass sheet, and the glass sheet has a dielectric layer located adjacent thereto.

Example A81 includes the subject matter of Example A68, wherein the glass layer comprises a glass sheet having a dielectric layer located adjacent thereto, and the dielectric layer comprises Ajinomoto Build-up Film (ABF).

Example A82 includes the subject matter of Example A68, wherein the glass layer comprises a glass sheet having a dielectric layer located adjacent thereto, and the dielectric layer is substantially 10 microns thick.

Example A83 includes the subject matter of Example A68, wherein the glass layer comprises silicon and oxygen.

Example A84 includes the subject matter of Example A83, wherein the glass layer comprises further comprises aluminum, boron, or an alkaline-earth metal.

Example A85 includes the subject matter of any one of Examples A68-A84, further comprising a first die attached to the first set of conductive contacts and a second die attached to the second set of conductive contacts.

Example A86 includes the subject matter of any one of Examples A68-A84, further comprising: a first die attached to the first set of conductive contacts; a second die attached to the second set of conductive contacts; and wherein the first die has a first functionality, the second die has a second functionality, the second functionality being different than the first functionality.

Example A87 includes the subject matter of any one of Examples A68-A84, further comprising a first die attached to the first set of conductive contacts; a second die attached to the second set of conductive contacts; and wherein the first die has a different thickness than the second die.

Example A88 includes the subject matter of any one of Examples A65-A87, further comprising an encapsulant located over the first die and second die.

Example A89 includes the subject matter of Example A88, wherein the apparatus is a panel, and further comprising a cooling component located on the panel.

Example A90 includes the subject matter of Example A89, wherein the cooling component includes a heat exchanger.

Example A91 includes the subject matter of any one of Examples A89-A90, wherein the apparatus is a first panel, and further comprising a second panel in electrical communication with the first panel.

Example A92 includes the subject matter of Example A91, further comprising: a substrate; the first panel and the second panel being attached to the substrate.

Example A93 includes the subject matter of Example A92, further comprising an electronic component attached to the substrate, the electronic component located external to the first panel and the second panel.

Example A94 includes the subject matter of Example A93, and further comprising: a housing enclosing the panel; and a heat pump connected to the heat exchanger on the panel via conduits.

Example A95 includes the subject matter of Example A94, further comprising a power management system electronically coupled to the panel.

Example A96 is a method, comprising: forming a first dielectric layer on a glass carrier, the glass carrier having a cross-sectional area of at least 250 millimeters×250 millimeters, the first dielectric layer comprising conductive pads arranged at a first pitch, the first pitch being 100 microns or less; forming a glass layer on the first dielectric layer, the glass layer comprising a micro-channel; locating a second dielectric layer on the glass layer, the second dielectric layer comprising conductive contacts arranged at a second pitch, the conductive contacts further arranged into a first set and a second set; the micro-channel configured to have a portion near the first set; and locating an interconnect structure in the glass layer, the interconnect structure to provide electrical communication between a conductive contact of the first set and one of the conductive pads.

Example A97 includes the subject matter of Example A96, further comprising: attaching a first die to the first set; and attaching a second die to the second set, thereby creating a populated substrate.

Example A98 includes the subject matter of Example A97, further comprising: debonding the glass carrier from the populated substrate; and forming solder bumps on the conductive pads.

Example A99 includes the subject matter of Example A98, further comprising singulating the populated substrate to thereby create a first panel and a second panel.

Example A100 includes the subject matter of Example A99, further comprising attaching a thermal solution to the first panel or the second panel.

Example B1 is an apparatus, comprising: one or more first dielectric layers, individual of the first dielectric layers positioned adjacent to another first dielectric layer; a plurality of first conductive contacts located on a top dielectric layer of the first dielectric layers, the plurality of first conductive contacts comprising a first set of first conductive contacts arranged at a first pitch and a second set of first conductive contacts; one or more second dielectric layers, individual second dielectric layers positioned adjacent to another second dielectric layer, individual of the first dielectric layers and individual of the second dielectric layers comprising one or more conductive traces and one or more vias; a plurality of second conductive contacts located on a bottom dielectric layer of the second dielectric layers, the second conductive contacts arranged at a second pitch, the second pitch greater than the first pitch; and a glass core comprising a layer of glass, the glass core positioned between the one or more first dielectric layers and the one or more second dielectric layers, the glass core comprising a through-glass via.

Example B2 comprises the subject matter of Example B1, further comprising an electrically conductive path from a conductive contact of the first set of the first conductive contacts to a conductive contact of the second set of the first conductive contacts, the electrically conductive path comprising a conductive trace of one of the first dielectric layers and a via of one of the first dielectric layers.

Example B3 comprises the subject matter of Example B1, further comprising an electrically conductive path from one of the first conductive contacts to one of the second conductive contacts, the electrically conductive path comprising at least one conductive trace of one of the first dielectric layers, at least one via of one of the first dielectric layers, the through-glass via of the glass core, at least one conductive trace of one of the second dielectric layers, and at least one via of one of the second dielectric layers.

Example B4 is an apparatus, comprising: one or more first dielectric layers, individual first dielectric layers positioned adjacent to another first dielectric layer; a plurality of first conductive contacts located on a top dielectric layer of the first dielectric layers, the plurality of first conductive contacts comprising a first set of first conductive contacts arranged at a first pitch and a second set of first conductive contacts; one or more second dielectric layers, individual second dielectric layers positioned adjacent to another second dielectric layer, individual first dielectric layers and individual second dielectric layers comprising one or more conductive traces and one or more vias; a plurality of second conductive contacts located on a bottom dielectric layer of the second dielectric layers, the second conductive contacts arranged at a second pitch, the second pitch greater than the first pitch; a glass core comprising a layer of glass, the glass core positioned between the first dielectric layers and the second dielectric layers, the glass core comprising a through-glass via; and a bridge located in the first dielectric layers or the glass core, the bridge comprising one or more conductive traces and one or more vias, the bridge comprising silicon.

Example B5 comprises the subject matter of Example B4, further comprising an electrically conductive path from a conductive contact of the first set of the first conductive contacts to a conductive contact of the second set of the first conductive contacts, the electrically conductive path comprising a conductive trace of the bridge and a via of the bridge.

Example B6 comprises the subject matter of Example B4, further comprising an electrically conductive path from a first conductive contact to a second conductive contact, the electrically conductive path comprising at least one conductive trace of one of the first dielectric layers, at least one via of one of the first dielectric layers, the through-glass via of the glass core, at least one conductive trace of one of the second dielectric layers, and at least one via of one of the second dielectric layers.

Example B7 comprises the subject matter of Example B4-B6, wherein the bridge spans two or more first dielectric layers.

Example B8 comprises the subject matter of Example B4-B7, wherein the bridge further comprises one or more through-silicon vias.

Example B9 comprises the apparatus of any one of Examples B4-B6, wherein the bridge is located in the glass core.

Example B10 comprises the subject matter of Example B4-B9, wherein the bridge comprises a trench capacitor, the trench capacitor comprising a first capacitor conductive trace, a second capacitor conductive trace, and a capacitor dielectric positioned between the first capacitor conductive trace and the second capacitor conductive trace, the first capacitor conductive trace and the second capacitor conductive trace oriented substantially perpendicular to a surface of the top dielectric layer of the first dielectric layers.

Example B11 comprises the subject matter of Example B4-B10, wherein the bridge further comprises multiple conductive traces, individual of the conductive traces of the bridge surrounded by a ferromagnetic material comprising iron.

Example B12 comprises the subject matter of Example B4-B11, wherein the bridge further comprises transistor.

Example B13 comprises the subject matter of Example apparatus of any one of Examples B1-B12, wherein the first pitch is less than about 1 micron.

Example B14 comprises the subject matter of Example apparatus of any one of Examples B1-B12, wherein the first pitch is less than about 0.5 microns.

Example B15 comprises the subject matter of Example apparatus of any one of Examples B1-B14, wherein the glass core further comprises a waveguide.

Example B16 comprises the subject matter of Example B15, wherein the waveguide is located in the layer of glass, the waveguide comprising a dielectric material having a permittivity greater than a permittivity of the glass.

Example B17 comprises the subject matter of Example B15, wherein the waveguide comprises silicon and oxygen.

Example B18 comprises the subject matter of Example B15, wherein the apparatus further comprises a photonic integrated circuit, the waveguide to provide a path for optical communication for optical signals to be generated or received by the photonic integrated circuit.

Example B19 comprises the subject matter of Example B15, wherein the apparatus further comprises a fiber array unit, the waveguide to provide a path for optical communication for optical signals to be generated or received by the fiber array unit.

Example B20 comprises the subject matter of any one of Examples B1-B19, wherein individual of the vias are tapered, individual of the vias comprising a narrower end and a wider end, the narrower end positioned closer to the glass core than the wider end.

Example B21 comprises the subject matter of Example B1-B20, wherein the glass comprises aluminum, oxygen, boron, silicon, and an alkaline-earth metal.

Example B22 comprises the subject matter of Example B1-B20, wherein the glass comprises silicon, lithium, oxygen, and a metal.

Example B23 comprises the subject matter of Example apparatus of any one of Example B22, wherein the metal is gold or silver.

Example B24 comprises the subject matter of Example B1-B23, wherein the glass core comprises one or more micro-channels.

Example B25 comprises the subject matter of Example B24, wherein the one or more micro-channels comprise one or more lateral portions and one or more vertical portions.

Example B26 comprises the subject matter of Example B25, wherein the through-glass via is a first through-glass via, the one or more vertical portions of the micro-channels comprising a second through-glass via.

Example B27 comprises the subject matter of Example B25, wherein the glass core further comprises a reservoir connected to at least one of the micro-channels.

Example B28 comprises the subject matter of Example B24-B27, the apparatus further comprising a heat exchanger, a pump, and one or more conduits to connect one of the micro-channels to the heat exchanger and/or the pump.

Example B29 comprises the subject matter of Example B1-B28, further comprising a plurality of integrated circuit dies, individual of the integrated circuit dies attached to one or more of the first conductive contacts.

Example B30 comprises the subject matter of Example B29, wherein a lateral dimension of a first one of the integrated circuit dies is different than a lateral dimension of a second one of the integrated circuit dies.

Example B31 comprises the subject matter of Example B29, wherein a thickness of a first one of the integrated circuit dies is different than a thickness of a second one of integrated circuit dies.

Example B32 comprises the subject matter of Example B29, wherein a functionality implemented by a first one of the integrated circuit dies is different than a functionality implemented by a second one of integrated circuit dies.

Example B33 comprises the subject matter of Example B29, wherein one of the integrated circuit dies comprises a plurality of third conductive contacts attached to the first set of first conductive contacts via solder balls.

Example B34 comprises the subject matter of Example B29, wherein one of the integrated circuit dies comprises a plurality of third conductive contacts directly attached to the first set of first conductive contacts.

Example B35 comprises the subject matter of Example B34, wherein the third conductive contacts and the first set of first conductive contacts comprise copper.

Example B36 comprises the subject matter of Example B29, wherein the one of the integrated circuit dies comprises a bottom dielectric layer directly attached to the top dielectric layer of the first dielectric layers.

Example B37 comprises the subject matter of Example B29, wherein a first integrated circuit die of the integrated circuit dies comprises a first surface and a second surface opposite the first surface, the first integrated circuit die attached to the first conductive contacts at the first surface of the first integrated circuit die, the apparatus further comprising an additional integrated circuit die, the additional integrated circuit die attached to the second surface of the first integrated circuit die.

Example B38 comprises the subject matter of Example B29, further comprising: an encapsulant encapsulating the integrated circuit dies, the encapsulant comprising a through-package via; and a packaged integrated circuit component comprising an integrated circuit component attached to the through-package via, the through-package via attached to one of the first conductive contacts.

Example B39 comprises the subject matter of Example B1-B38, wherein the glass core has a lateral dimension of at least 250 mm.

Example B40 comprises the subject matter of Example B1-B38, wherein the glass core has a lateral dimension of at least 400 mm.

Example B41 comprises the subject matter of Example B1-B40, wherein the glass core has a rectangular shape.

Example B42 comprises the subject matter of Example B1-B40, wherein the glass core has a non-circular shape.

Example B43 comprises the subject matter of Example B29-B42, further comprising a cooling component located on one or more of the integrated circuit dies, the cooling component comprising a liquid-cooled cold plate, a vapor chamber, or a heat sink.

Example B44 comprises the subject matter of Example B1-B43 further comprising a housing, the housing containing the first dielectric layers and the second dielectric layers.

Example B45 comprises the subject matter of Example B1-B44 further comprising a power management component.

Example B46 is an apparatus comprising: a plurality of first dielectric layers, individual first dielectric layers positioned adjacent to another first dielectric layer; a plurality of first conductive contacts located on a top dielectric layer of the first dielectric layers, the plurality of first conductive contacts comprising a first set of first conductive contacts arranged at a first pitch and a second set of first conductive contacts; a plurality of second dielectric layers, individual second dielectric layers positioned adjacent to another second dielectric layer, individual of the first dielectric layers and individual of the second dielectric layers comprising one or more first conductive traces and one or more first vias; a plurality of second conductive contacts located on a bottom dielectric layer of the second dielectric layers, the second conductive contacts arranged at a second pitch, the second pitch greater than the first pitch; a first glass core comprising a layer of glass, the first glass core positioned between the one or more first dielectric layers and the one or more second dielectric layers, the first glass core comprising a first through-glass via; a plurality of first integrated circuit dies, individual of the first integrated circuit dies attached to one or more of the first conductive contacts; a plurality of third dielectric layers; a plurality of third conductive contacts located on a top dielectric layer of the third dielectric layers; the plurality of third conductive contacts comprising a first set of third conductive contacts and a second set of third conductive contacts; a plurality of fourth dielectric layers, individual of the third dielectric layers and individual of the fourth dielectric layers comprising one or more second conductive traces and one or more second vias; a plurality of fourth conductive contacts located on a surface of a bottom dielectric layer of the fourth dielectric layers; a second glass core comprising a layer of the glass, the second glass core located between the third dielectric layers and the fourth dielectric layers, the second glass core comprising a second through-glass via; a plurality of second integrated circuit dies, individual of the second integrated circuit dies attached to one or more of the third conductive contacts; and a substrate comprising one or more fifth dielectric layers, individual of the fifth dielectric layers comprising one or more conductive traces and one or more vias, an electrically conductive path from one of the second conductive contacts to one or the fourth conductive contacts comprising a conductive trace of one of the fifth dielectric layers and a via of one of the fifth dielectric layers.

Example B47 comprises the subject matter of Example B46, wherein the electrically conductive path is a first electrically conductive path, further comprising a second electrically conductive path from one of the conductive contacts of the first set of the first conductive contacts to one of the conductive contacts of the second set of the first conductive contacts, the second electrically conductive path comprising a conductive trace of one of the first dielectric layers and a via of one of the first dielectric layers.

Example B48 comprises the subject matter of Example B46, wherein the electrically conductive path is a first electrically conductive path, the apparatus further comprising a second electrically conductive path from a first conductive contact to a second conductive contact, the second electrically conductive path comprising at least one conductive trace of the first dielectric layers, at least one via of the first dielectric layers, the first through-glass via of the first glass core, a conductive trace of one of the second dielectric layers, and at least one via of one of the second dielectric layers.

Example B49 is an apparatus comprising: a plurality of first dielectric layers, individual first dielectric layers positioned adjacent to another first dielectric layer; a plurality of first conductive contacts located on a top dielectric layer of the first dielectric layers, the plurality of first conductive contacts comprising a first set of first conductive contacts arranged at a first pitch and a second set of first conductive contacts; a plurality of second dielectric layers, individual second dielectric layers positioned adjacent to another second dielectric layer, individual first dielectric layers and individual second dielectric layers comprising one or more first conductive traces and one or more first vias; a plurality of second conductive contacts located on a bottom dielectric layer of the second dielectric layers, the second conductive contacts arranged at a second pitch, the second pitch greater than the first pitch; a first glass core comprising a layer of glass, the first glass core positioned between the first dielectric layers and the second dielectric layers, the first glass core comprising a first through-glass via; a first bridge located in the first dielectric layers or the first glass core, the first bridge comprising one or more conductive traces and one or more vias, the first bridge comprising silicon; a plurality of first integrated circuit dies, individual of the first integrated circuit dies attached to one or more of the first conductive contacts; a plurality of third dielectric layers; a plurality of third conductive contacts located on a top dielectric layer of the third dielectric layers; the plurality of third conductive contacts comprising a first set of third conductive contacts and a second set of third conductive contacts; a plurality of fourth dielectric layers, individual of the third dielectric layers and individual of the fourth dielectric layers comprising one or more second conductive traces and one or more second vias; a plurality of fourth conductive contacts located on a bottom dielectric layer of the fourth dielectric layers; a second glass core comprising a layer of the glass, the second glass core located between the third dielectric layers and the fourth dielectric layers, the second glass core comprising a second through-glass via; and a second bridge located in the third dielectric layers or the second glass core comprising one or more conductive traces and one or more vias, the second bridge comprising silicon; a plurality of second integrated circuit dies, individual of the second integrated circuit dies attached to one or more of the third conductive contacts; and a substrate comprising one or more fifth dielectric layers, individual of the fifth dielectric layers comprising one or more conductive traces and one or more vias, an electrically conductive path from one of the second conductive contacts to one of the fourth conductive contacts comprising one of the conductive traces of the substrate and one of the vias of the substrate.

Example B50 comprises the subject matter of Example B49, wherein the electrically conductive path is a first electrically conductive path, the apparatus further comprising a second electrically conductive path from one of the conductive contacts of the first set of the first conductive contacts to one of the conductive contacts of the second set of the first conductive contacts, the second electrically conductive path comprising a conductive trace of the first bridge and a via of the first bridge.

Example B51 comprises the subject matter of Example B49, wherein the electrically conductive path is a first electrically conductive path, the apparatus further comprising a second electrically conductive path from a first conductive contact to a second conductive contact, the second electrically conductive path comprising at least one conductive trace of the first dielectric layers, at least one via of the first dielectric layers, the first through-glass via of the first glass core, a conductive trace of one of the second dielectric layers, and at least one via of one of the second dielectric layers.

Example B52 comprises the subject matter of Example B46-B51, wherein the number of the first integrated circuit dies is different than the number of the second integrated circuit dies.

Example B53 comprises the subject matter of Example B46-B51, wherein a functionality implemented by the plurality of the first integrated circuit dies is different than a functionality implemented by the plurality of the second integrated circuit dies.

Example B54 comprises the subject matter of Example B46-B51, further comprising a cooling component located on one or more of the first integrated circuit dies and one or more of the second integrated circuit dies, the cooling component comprising a liquid-cooled cold plate, a vapor chamber, or a heat sink.

Example B55 comprises the subject matter of Example B54, wherein the cooling component comprises a liquid-cooled cold plate, the apparatus further comprising a heat exchanger, a pump, and one or more conduits connecting the cooling component to the heat exchanger and/or the pump.

Example B56 comprises the subject matter of Example B46-B55, further comprising a housing, the housing containing the first dielectric layers, the second dielectric layers, and the first integrated circuit dies.

Example B57 comprises the subject matter of Example B46-B56, further comprising a power management component.

Example C1 is an apparatus comprising: a plurality of dielectric layers stacked vertically, individual of the dielectric layers comprising one or more conductive traces and one or more vias; a plurality of first conductive contacts located on a top dielectric layer of the dielectric layers, the plurality of first conductive contacts comprising a first set of first conductive contacts arranged at a first pitch and a second set of first conductive contacts; and a plurality of second conductive contacts located on a bottom dielectric layer of the dielectric layers; the second conductive contacts arranged at a second pitch, the second pitch greater than the first pitch, wherein the first pitch is less than about 1 micron and individual of the dielectric layers have a lateral dimension greater than about 250 mm.

Example C2 comprises the subject matter of Example C1, further comprising an electrically conductive path from one of the conductive contacts of the first set of the first conductive contacts to one of the conductive contacts of the second set of the first conductive contacts, the electrically conductive path comprising a conductive trace of the dielectric layers and a via of the dielectric layers.

Example C3 comprises the subject matter of Example C1, further comprising an electrically conductive path from a first conductive contact to a second conductive contact, the electrically conductive path comprising a conductive trace of the dielectric layers and a via of the dielectric layers.

Example C4 is an apparatus, comprising: a plurality of dielectric layers stacked vertically, individual of the dielectric layers comprising one or more conductive traces and one or more vias; a plurality of first conductive contacts located on a top dielectric layer of the dielectric layers, the plurality of first conductive contacts comprising a first set of first conductive contacts arranged at a first pitch and a second set of first conductive contacts; a plurality of second conductive contacts arranged on a bottom dielectric layer of the dielectric layers; the second conductive contacts arranged at a second pitch, the second pitch greater than the first pitch; and a bridge located in the one or more dielectric layers, the bridge comprising one or more conductive traces and one or more vias, the bridge comprising silicon.

Example C5 comprises the subject matter of Example C4, further comprising an electrically conductive path from one of the conductive contacts of the first set of the first conductive contacts to one of the conductive contacts of the second set of the first conductive contacts, the electrically conductive path comprising a conductive trace of the bridge and a via of the bridge.

Example C6 comprises the subject matter of Example C4, further comprising an electrically conductive path from a first conductive contact to a second conductive contact, the electrically conductive path comprising a conductive trace of the dielectric layers and a via of one of the dielectric layers.

Example C7 comprises the subject matter of any one of Examples C4-C6, wherein bridge spans two or more dielectric layers.

Example C8 comprises the subject matter of any one of Examples C4-C7, wherein the bridge comprises one or more through-silicon vias.

Example C9 comprises the subject matter of any one of Examples C4-C8, wherein the bridge comprises a trench capacitor, the trench capacitor comprising a first capacitor conductive trace, a second capacitor conductive trace, and a capacitor dielectric positioned between the first capacitor conductive trace and the second capacitor conductive trace, the first capacitor conductive trace and the second conductive trace oriented substantially perpendicular to a surface of the top dielectric layer of the dielectric layers.

Example C10 comprises the subject matter of any one of Examples C4-C9, wherein the bridge further comprises multiple conductive traces, individual of the conductive traces surrounded by a ferromagnetic layer comprising iron.

Example C11 comprises the subject matter of any one of Examples C4-C10, wherein the bridge comprises a field effect transistor.

Example C12 comprises the subject matter of any one of Examples C1-C10, wherein a thickness of the dielectric layers is in the range of 0.5-200 microns.

Example C13 comprises the subject matter of any one of Examples C1-C12, wherein the first pitch is less than about 1 micron.

Example C14 comprises the subject matter of any one of Examples C1-C12, wherein the first pitch is less than about 0.5 microns.

Example C15 comprises the subject matter of any one of Examples C1-C14, further comprising: a photonic integrated circuit; and an interposer comprising a glass and a waveguide to provide a communication path for optical signals to be generated or received by the photonic integrated circuit.

Example C16 comprises the subject matter of Example C15, wherein the waveguide is located in the glass, the waveguide comprising a dielectric material having a permittivity greater than a permittivity of the glass.

Example C17 comprises the subject matter of Example C15, wherein the waveguide comprises silicon and oxygen.

Example C18 comprises the subject matter of Example C15, further comprising an electronic integrated circuit comprising a first set of electronic integrated circuit conductive contacts located on a first surface of the electronic integrated circuit and a second set of electronic integrated circuit conductive contacts located on a second surface of the electronic integrated circuit that is opposite the first surface, the first set of electronic integrated circuit conductive contacts attached to one or more of the first conductive contacts, the photonic integrated circuit comprising one or more photonic integrated circuit conductive contacts, the photonic integrated circuit conductive contacts attached to the second set of electronic integrated circuit conductive contacts.

Example C19 comprises the subject matter of Example C15, wherein the photonic integrated circuit comprises one or more photonic integrated circuit conductive contacts, the photonic integrated circuit conductive contacts attached to one or more of the first conductive contacts.

Example C20 comprises the subject matter of any one of Examples C15-C19, wherein the apparatus further comprises a fiber array unit, the waveguide further to provide a communication path for optical signals to be generated or received by the fiber array unit.

Example C21 comprises the subject matter of any one of Examples C15-C20, wherein the glass comprises aluminum, oxygen, boron, silicon, and an alkaline-earth metal.

Example C22 comprises the subject matter of any one of Examples C1-C21, wherein the glass comprises silicon, lithium, oxygen, and a metal.

Example C23 comprises the subject matter of any one of Example C22, wherein the metal is gold or silver.

Example C24 comprises the subject matter of any one of Examples C1-C23, further comprising a plurality of integrated circuit dies, individual of the dies attached to one or more of the first conductive contacts.

Example C25 comprises the subject matter of Example C24, wherein a lateral dimension of a first one of the integrated circuit dies is different than a lateral dimension of a second one of the integrated circuit dies.

Example C26 comprises the subject matter of Example C24, wherein a thickness of a first one of the integrated circuit dies is different than a thickness of a second one of integrated circuit dies.

Example C27 comprises the subject matter of Example C24, wherein a functionality implemented by a first one of the integrated circuit dies is different than a functionality implemented by a second one of integrated circuit dies.

Example C28 comprises the subject matter of Example C24, wherein one of the integrated circuit dies comprises a plurality of third integrated circuit die conductive contacts attached to the first set of conductive contacts via solder balls.

Example C29 comprises the subject matter of Example C23, wherein one of the integrated circuit dies comprises a plurality of third conductive contacts directly attached to the first set of first conductive contacts.

Example C30 comprises the subject matter of Example C29, wherein the plurality of third integrated circuit dies conductive contacts and the first set of conductive contacts comprise copper.

Example C31 comprises the subject matter of Example C24, wherein the one of the integrated circuit dies comprises a bottom dielectric layer directly attached to the surface of the top layer of the dielectric layers.

Example C32 comprises the subject matter of Example C24, wherein one of the integrated circuit dies comprises a first surface and a second surface opposite the first surface, the one of the integrated circuit dies attached to the first conductive contacts at the first surface of the one of the integrated circuit dies, the apparatus further comprising an additional integrated circuit die, the additional integrated circuit die attached to the second surface of the integrated circuit dies.

Example C33 comprises the subject matter of Example C24, further comprising: an encapsulant encapsulating the integrated circuit dies, the encapsulant comprising a thru-package via; and a packaged integrated circuit component comprising an integrated circuit component conductive contact attached to the thru-package via, the thru-package via attached to one of the first conductive contacts.

Example C34 comprises the subject matter of any one of Examples C1-C33, wherein individual of the dielectric layers have a lateral dimension of at least 250 mm.

Example C35 comprises the subject matter of any one of Examples C1-C33, wherein individual of the dielectric layers have a lateral dimension of at least 400 mm.

Example C36 comprises the subject matter of any one of Examples C1-C35, wherein individual of the dielectric layers have a rectangular shape.

Example C37 comprises the subject matter of any one of Examples C1-C35, wherein individual of the dielectric layers have a non-circular shape.

Example C38 comprises the subject matter of any one of Examples C24-C37, further comprising a cooling component located on one or more of the integrated circuit dies, the cooling component comprising a liquid-cooled cold plate, a vapor chamber, or a heat sink.

Example C39 comprises the subject matter of Example C38, wherein the cooling component comprises a liquid-cooled cold plate, the apparatus further comprising a heat exchanger, a pump, and one or more conduits connecting the cooling component to the heat exchanger and/or the pump.

Example C40 comprises the subject matter of any one of Examples C1-C39 further comprising a housing, the housing containing the dielectric layers.

Example C41 comprises the subject matter of any one of Examples C1-C40 further comprising a power distribution component.

Example C42 is an apparatus comprising: a plurality of first dielectric layers arranged in a stack, individual of the first dielectric layers comprising one or more first conductive traces and one or more first vias; a plurality of first conductive contacts located on a surface of a top dielectric layer of the first dielectric layers; the plurality of first conductive contacts comprising a first set of first conductive contacts arranged at a first pitch and a second set of first conductive contacts; a plurality of second conductive contacts arranged of a surface of a bottom dielectric layer of the first dielectric layers; the second conductive contacts arranged at a second pitch, the second pitch larger than the first pitch; a plurality of first integrated circuit dies, individual of the first integrated circuit dies attached to one or more of the first conductive contacts; a plurality of second dielectric layers arranged in a stack, individual of the second dielectric layers comprising one or more second conductive traces and one or more second vias; a plurality of third conductive contacts located on a surface of a top dielectric layer of the second dielectric layers; the plurality of third conductive contacts comprising a first set of third conductive contacts and a second set of third conductive contacts; a plurality of fourth conductive contacts located on a surface of a bottom dielectric layer of the second dielectric layers; a plurality of second integrated circuit dies, individual of the second integrated circuit dies attached to one or more of the third conductive contacts; and a substrate comprising one or more third dielectric layers, individual of the third dielectric layers comprising one or more conductive traces and one or more vias, an electrically conductive path from one of the second conductive contacts to one of the fourth conductive contacts comprising a conductive trace of the substrate and a via of the substrate.

Example C43 comprises the subject matter of Example C42, wherein the conductive path is a first electrically conductive path, further comprising a second electrically conductive path from one of the conductive contacts of the first set of the first conductive contacts to one of the conductive contacts of the second set of the first conductive contacts, the second electrically conductive path comprising a conductive trace of the first dielectric layers and a via of the first dielectric layers.

Example C44 comprises the subject matter of Example C42, wherein the electrically conductive path is a first electrically conductive path, the apparatus further comprising a second electrically conductive path from a first conductive contact to a second conductive contact, the second electrically conductive path comprising a conductive trace of the first dielectric layers and a via of the first dielectric layers.

Example C45 comprises the subject matter of An apparatus comprising: one or more first dielectric layers stacked vertically, individual of the first dielectric layers comprising one or more first conductive traces and one or more first vias; a plurality of first conductive contacts located on a top dielectric layer of the first dielectric layers, the plurality of first conductive contacts comprising a first set of first conductive contacts arranged at a first pitch and a second set of first conductive contacts; a plurality of second conductive contacts arranged on a bottom dielectric layer of the first dielectric layers; the second conductive contacts arranged at a second pitch, the second pitch larger than the first pitch; a first bridge located in the one or more first dielectric layers, the first bridge comprising one or more conductive traces and one or more vias, the bridge comprising silicon; a plurality of first integrated circuit dies, individual of the first integrated circuit dies attached to one or more of the first conductive contacts; one or more second dielectric layers stacked vertically, individual of the second dielectric layers comprising one or more second conductive traces and one or more second vias; a plurality of third conductive contacts located on a top dielectric layer of the second dielectric layers; the plurality of third conductive contacts comprising a first set of third conductive contacts and a second set of third conductive contacts; a plurality of fourth conductive contacts arranged on a bottom dielectric layer of the second dielectric layers; a second bridge located in the second dielectric layers, the second bridge comprising one or more conductive traces and one or more vias, the bridge comprising silicon; and a plurality of second integrated circuit dies, individual of the second integrated circuit dies attached to the one or more of the third conductive contacts; and a substrate comprising one or more third dielectric layers, individual of the third dielectric layers comprising one or more conductive traces and one or more vias, a substrate electrically conductive path from one of the second conductive contacts to one of the fourth conductive contacts comprising one of the conductive traces of the substrate and one of the vias of the substrate.

Example C46 comprises the subject matter of Example C45, wherein the electrically conductive path is a first electrically conductive path, the apparatus further comprising a second electrically conductive path from one of the conductive contacts of the first set of the first conductive contacts to one of the conductive contacts of the second set of the first conductive contacts, the second electrically conductive path comprising a conductive trace of the bridge and a via of the bridge.

Example C47 comprises the subject matter of Example C45, wherein the electrically conductive path is a first electrically conductive path, the apparatus further comprising a second electrically conductive path from a first conductive contact to a second conductive contact, the second electrically conductive path comprising a conductive trace of the first dielectric layers and a via of the first dielectric layers.

Example C48 comprises the subject matter of any one of Examples C42-C47, wherein the number of the first integrated circuit dies is different than the number of the second integrated circuit dies.

Example C49 comprises the subject matter of any one of Examples C42-C47, wherein the functionality implemented by the plurality of the first integrated circuit dies is different than the functionality implemented by the plurality of the second integrated circuit dies.

Example C50 comprises the subject matter of any one of Examples C42-C49, further comprising a cooling component located on one or more of the first integrated circuit dies and one or more of the second integrated circuit dies, the cooling component comprising a liquid-cooled cold plate, a vapor chamber, or a heat sink.

Example C51 comprises the subject matter of Example C50, wherein the cooling component comprises a liquid-cooled cold plate, the apparatus further comprising a heat exchanger, a pump, and one or more conduits connecting the cooling component to the heat exchanger and/or the pump.

Example C52 comprises the subject matter of any one of Examples C42-C51, further comprising a housing, the housing containing the first dielectric layers, the second dielectric layers, and the first integrated circuit dies.

Example C53 comprises the subject matter of any one of Examples C42-C52, further comprising a power distribution component.

Example C54 comprises the subject matter of A method comprising: forming, on a glass carrier: a plurality of dielectric layers, individual of the dielectric layers comprising one or more conductive traces and one or more vias; a plurality of first conductive contacts on a top dielectric layer of the dielectric layers; and a plurality of second conductive contacts located on a bottom dielectric layer of the dielectric layers, the first conductive contacts arranged at a first pitch that is less than 1 micron, the second conductive contacts arranged at a second pitch that is greater than the first pitch; attaching one or more integrated circuit dies to the first conductive contacts; and removing the glass carrier from the dielectric layers.

Example C55 comprises the subject matter of Example C54, further comprising: etching one or more of the dielectric layers to create a cavity; and locating a bridge in the cavity, the bridge comprising one or more conductive traces and one or more vias.

Example C56 comprises the subject matter of Example C55, wherein the first conductive contacts comprise a first set of first conductive contacts and a second set of first conductive contacts, an electrically conductive path from a conductive contact from the first set of first conductive contacts to a conductive contact of the second set of the first conductive contacts comprising a conductive trace of the bridge and a via of the bridge.

Example C57 comprises the subject matter of Example C54, wherein the glass carrier and individual of the dielectric layers have a lateral dimension of at least 250 mm.

Example C58 comprises the subject matter of Example C54, wherein the glass carrier and individual of the dielectric layers have a lateral dimension of at least 400 mm.

1. An apparatus comprising:
a plurality of dielectric layers stacked vertically, individual of the dielectric layers comprising one or more conductive traces and one or more vias;
a plurality of first conductive contacts located on a top dielectric layer of the dielectric layers, the plurality of first conductive contacts comprising a first set of first conductive contacts arranged at a first pitch and a second set of first conductive contacts; and
a plurality of second conductive contacts located on a bottom dielectric layer of the dielectric layers; the second conductive contacts arranged at a second pitch, the second pitch greater than the first pitch, wherein the first pitch is less than about 1 micron and individual of the dielectric layers have a lateral dimension greater than about 250 mm.

2. The apparatus of claim 1, further comprising an electrically conductive path from one of the conductive contacts of the first set of the first conductive contacts to one of the conductive contacts of the second set of the first conductive contacts, the electrically conductive path comprising a conductive trace of the dielectric layers and a via of the dielectric layers.

3. The apparatus of claim 1, further comprising an electrically conductive path from a first conductive contact to a second conductive contact, the electrically conductive path comprising a conductive trace of the dielectric layers and a via of the dielectric layers.

4. The apparatus of claim 1, wherein the first pitch is less than about 0.5 microns.

5. The apparatus of claim 1, further comprising:
a photonic integrated circuit; and
an interposer comprising a glass and a waveguide to provide a communication path for optical signals to be generated or received by the photonic integrated circuit.

6. The apparatus of claim 5, further comprising an electronic integrated circuit comprising a first set of electronic integrated circuit conductive contacts located on a first surface of the electronic integrated circuit and a second set of electronic integrated circuit conductive contacts located on a second surface of the electronic integrated circuit that is opposite the first surface, the first set of electronic integrated circuit conductive contacts attached to one or more of the first conductive contacts, the photonic integrated circuit comprising one or more photonic integrated circuit conductive contacts, the photonic integrated circuit conductive contacts attached to the second set of electronic integrated circuit conductive contacts.

7. The apparatus of claim 1, wherein the glass comprises aluminum, oxygen, boron, silicon, and an alkaline-earth metal.

8. The apparatus of claim 1, further comprising a plurality of integrated circuit dies, individual of the dies attached to one or more of the first conductive contacts.

9. The apparatus of claim 8, wherein a lateral dimension of a first one of the integrated circuit dies is different than a lateral dimension of a second one of the integrated circuit dies.

10. The apparatus of claim 9, further comprising a cooling component located on one or more of the integrated circuit dies, the cooling component comprising a liquid-cooled cold plate, a vapor chamber, or a heat sink.

11. The apparatus of claim 1, wherein individual of the dielectric layers have a lateral dimension of at least 250 mm.

12. An apparatus, comprising:
a plurality of dielectric layers stacked vertically, individual of the dielectric layers comprising one or more conductive traces and one or more vias;
a plurality of first conductive contacts located on a top dielectric layer of the dielectric layers, the plurality of first conductive contacts comprising a first set of first conductive contacts arranged at a first pitch and a second set of first conductive contacts;
a plurality of second conductive contacts arranged on a bottom dielectric layer of the dielectric layers; the second conductive contacts arranged at a second pitch, the second pitch greater than the first pitch; and
a bridge located in the one or more dielectric layers, the bridge comprising one or more conductive traces and one or more vias, the bridge comprising silicon.

13. The apparatus of claim 12, further comprising an electrically conductive path from one of the conductive contacts of the first set of the first conductive contacts to one of the conductive contacts of the second set of the first conductive contacts, the electrically conductive path comprising a conductive trace of the bridge and a via of the bridge.

14. The apparatus of claim 12, further comprising an electrically conductive path from a first conductive contact to a second conductive contact, the electrically conductive path comprising a conductive trace of the dielectric layers and a via of one of the dielectric layers.

15. The apparatus of claim 12, wherein bridge spans two or more dielectric layers.

16. The apparatus of claim 12, wherein the first pitch is less than about 0.5 microns.

17. The apparatus of claim 12, further comprising:
a photonic integrated circuit; and
an interposer comprising a glass and a waveguide to provide a communication path for optical signals to be generated or received by the photonic integrated circuit.

18. The apparatus of claim 17, wherein the glass comprises aluminum, oxygen, boron, silicon, and an alkaline-earth metal.

19. The apparatus of claim 12, further comprising a plurality of integrated circuit dies, individual of the dies attached to one or more of the first conductive contacts.

20. The apparatus of claim 19, wherein a thickness of a first one of the integrated circuit dies is different than a thickness of a second one of integrated circuit dies.

21. The apparatus of claim 19, further comprising a cooling component located on one or more of the integrated circuit dies, the cooling component comprising a liquid-cooled cold plate, a vapor chamber, or a heat sink.

22. The apparatus of claim 19, further comprising a housing, the housing containing the dielectric layers.

23. An apparatus comprising:
one or more first dielectric layers stacked vertically, individual of the first dielectric layers comprising one or more first conductive traces and one or more first vias;
a plurality of first conductive contacts located on a top dielectric layer of the first dielectric layers, the plurality of first conductive contacts comprising a first set of first conductive contacts arranged at a first pitch and a second set of first conductive contacts;
a plurality of second conductive contacts arranged on a bottom dielectric layer of the first dielectric layers; the second conductive contacts arranged at a second pitch, the second pitch larger than the first pitch;
a first bridge located in the one or more first dielectric layers, the first bridge comprising one or more conductive traces and one or more vias, the bridge comprising silicon;
a plurality of first integrated circuit dies, individual of the first integrated circuit dies attached to one or more of the first conductive contacts;
one or more second dielectric layers stacked vertically, individual of the second dielectric layers comprising one or more second conductive traces and one or more second vias;
a plurality of third conductive contacts located on a top dielectric layer of the second dielectric layers; the plurality of third conductive contacts comprising a first set of third conductive contacts and a second set of third conductive contacts;
a plurality of fourth conductive contacts arranged on a bottom dielectric layer of the second dielectric layers;
a second bridge located in the second dielectric layers, the second bridge comprising one or more conductive traces and one or more vias, the bridge comprising silicon; and
a plurality of second integrated circuit dies, individual of the second integrated circuit dies attached to the one or more of the third conductive contacts; and
a substrate comprising one or more third dielectric layers, individual of the third dielectric layers comprising one or more conductive traces and one or more vias, a substrate electrically conductive path from one of the second conductive contacts to one of the fourth conductive contacts comprising one of the conductive traces of the substrate and one of the vias of the substrate.

24. The apparatus of claim 23, wherein the electrically conductive path is a first electrically conductive path, the apparatus further comprising a second electrically conductive path from one of the conductive contacts of the first set of the first conductive contacts to one of the conductive contacts of the second set of the first conductive contacts, the second electrically conductive path comprising a conductive trace of the bridge and a via of the bridge.

25. The apparatus of claim 23, wherein the electrically conductive path is a first electrically conductive path, the apparatus further comprising a second electrically conductive path from a first conductive contact to a second conductive contact, the second electrically conductive path comprising a conductive trace of the first dielectric layers and a via of the first dielectric layers.
